(19) United States
(12) Patent Application Publication
(10) Pub. No.: US 2025/0212387 A1
(43) Pub. Date: Jun. 26, 2025

(54) SEMICONDUCTOR DEVICE AND METHOD FOR MANUFACTURING THE SEMICONDUCTOR DEVICE

(71) Applicant: Semiconductor Energy Laboratory Co., Ltd., Atsugi-shi, Kanagawa-ken (JP)

(72) Inventors: Ryota HODO, Atsugi (JP); Toshiya ENDO, Atsugi (JP); Masaru NAKANO, Isehara (JP); Hiromi SAWAI, Atsugi (JP); Shunpei YAMAZAKI, Setagaya (JP)

(21) Appl. No.: 18/848,954

(22) PCT Filed: Mar. 13, 2023
(86) PCT No.: PCT/IB2023/052379

§ 371 Date: Sep. 20, 2024

(30) Foreign Application Priority Data
Mar. 25, 2022 (JP) 2022-050549
Mar. 25, 2022 (JP) 2022-050551

(51) Int. Cl. H10B 12/00

(52) U.S. Cl. CPC H10B 12/31; H10B 12/033; H10B 12/05

(57) ABSTRACT

A first memory cell, a second memory cell over the first memory cell, a first conductor, and a second conductor over the first conductor are included; the first memory cell and the second memory cell each include a transistor, a capacitor, and a first insulator over the transistor; the transistor includes a metal oxide, a third conductor, a fourth conductor, and a second insulator over the metal oxide, a fifth conductor over the second insulator, a third insulator under the metal oxide, and a sixth conductor under the third insulator; the capacitor includes a seventh conductor, a fourth insulator over the seventh conductor, and an eighth conductor over the fourth insulator; the fourth conductor and the seventh conductor are in contact with each other through an opening provided in the first insulator; the first conductor and the second conductor each include a portion in contact with the third conductor; one side end portion of the third conductor is substantially aligned with one side end portion of the metal oxide and one side end portion of the fourth conductor is substantially aligned with the other side end portion of the metal oxide.

### TECHNICAL FIELD

One embodiment of the present invention relates to a semiconductor device, a memory device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

Note that in this specification and the like, a semiconductor device means any device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, semiconductor devices such as an LSI (Large Scale Integration), a CPU (Central Processing Unit), a GPU (Graphic Processing Unit), and a memory (a memory device) have been developed. These semiconductor devices have been used in various electronic devices such as computers and portable information terminals. In addition, memories under development employ various memory systems for intended uses such as temporary storage at the time of executing arithmetic processing and long-term storage of data. Examples of memories with typical memory systems include a DRAM (Dynamic Random Access Memory), an SRAM (Static Random Access Memory), and a flash memory.

With an increasing amount of data to process, a semiconductor device having a larger memory capacity has been required. Patent Document 1 and Non-Patent Document 1 disclose memory cells formed by stacking transistors.

### REFERENCES

### Patent Documents

Patent Document 1] PCT International Publication No. 2021/053473

### Non-Patent Document

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

One object of one embodiment of the present invention is to provide a semiconductor device that can be miniaturized or highly integrated. One object of one embodiment of the present invention is to provide a semiconductor device with high operating speed. One object of one embodiment of the present invention is to provide a semiconductor device having favorable electrical characteristics. One object of one embodiment of the present invention is to provide a semiconductor device with a small variation in electrical characteristics of transistors. One object of one embodiment of the present invention is to provide a highly reliable semiconductor device. One object of one embodiment of the present invention is to provide a semiconductor device with high on-state current. One object of one embodiment of the present invention is to provide a semiconductor device with low power consumption. One object of one embodiment of the present invention is to provide a novel semiconductor device. One object of one embodiment of the present invention is to provide a method for manufacturing a semiconductor device with high productivity. One object of one embodiment of the present invention is to provide a method for manufacturing a novel semiconductor device.

One object of one embodiment of the present invention is to provide a memory device having a large memory capacity. One object of one embodiment of the present invention is to provide a memory device occupying a small area. One object of one embodiment of the present invention is to provide a highly reliable memory device. One object of one embodiment of the present invention is to provide a memory device with low power consumption. One object of one embodiment of the present invention is to provide a novel memory device. One object of one embodiment of the present invention is to provide a method for manufacturing a memory device with high productivity. One object of one embodiment of the present invention is to provide a method for manufacturing a novel memory device.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device which includes a first memory cell, a second memory cell over the first memory cell, a first conductor, and a second conductor over the first conductor and in which the first memory cell and the second memory cell each include a transistor, a capacitor, and a first insulator over the transistor; the transistor includes a metal oxide, a third conductor, a fourth conductor, and a second insulator over the metal oxide, a fifth conductor over the second insulator, a third insulator under the metal oxide, and a sixth conductor under the third insulator; the capacitor includes a seventh conductor, a fourth insulator over the seventh conductor, and an eighth conductor over the fourth insulator; part of the seventh conductor, part of the fourth insulator, and part of the eighth conductor are positioned over the first insulator; the fourth conductor and the seventh conductor are in contact with each other through an opening provided in the first insulator; the first conductor includes a portion in contact with the third conductor included in the first memory cell; a top surface of the first conductor includes a portion in contact with a bottom surface of the second conductor; the second conductor includes a portion in contact with the third conductor included in the second memory cell; the sixth conductor included in the second memory cell includes the same material as the eighth conductor included in the first memory cell; and in a cross-sectional view of the transistor, one side end portion of the third conductor is substantially aligned with one side end portion of the metal oxide and one side end portion of the fourth conductor is substantially aligned with the other side end portion of the metal oxide.

In the above, preferably, the first conductor is in contact with part of a top surface and the one side end portion of the third conductor included in the first memory cell.

In the above, preferably, a side end portion of the third insulator is substantially aligned with the side end portion of the metal oxide.

In the above, preferably, the third conductor and the fourth conductor each include a first layer and a second layer over the first layer; the first layer includes a metal nitride; and the second layer has higher conductivity than the first layer. In the above, preferably, the first layer includes tantalum nitride, and the second layer includes tungsten.

In the above, preferably, a fifth insulator in contact with a top surface of the third conductor is further included; a sixth insulator in contact with a top surface of the fourth conductor is further included; and a side end portion of the sixth insulator is aligned with the side end portion of the fourth conductor.

In the above, preferably, a seventh insulator covering the third conductor, the fourth conductor, the metal oxide, and the third insulator are further included; the seventh insulator includes a first opening overlapping with a region sandwiched between the third conductor and the fourth conductor, and a second opening overlapping with the opening in the first insulator; at least part of the second insulator and at least part of the fifth conductor are placed in the first opening in the seventh insulator; and at least part of the seventh conductor, at least part of the fourth insulator, and at least part of the eighth conductor are placed in the second opening in the seventh insulator.

In the above, preferably, an eighth insulator over the first insulator is further included; part of the fourth insulator is in contact with a top surface of the eighth insulator; and the eighth insulator includes an opening overlapping with the opening in the first insulator. In the above, preferably, a thickness of the eighth insulator is greater than or equal to 50 nm and less than or equal to 250 nm. In the above, preferably, the first insulator includes aluminum oxide.

In the above, preferably, a ninth insulator in contact with a bottom surface of the sixth conductor is further included; the ninth insulator included in the second memory cell is in contact with the top surface of the eighth insulator included in the first memory cell; and the ninth insulator included in the second memory cell includes the same material as the fourth insulator included in the first memory cell.

In the above, preferably, a side end portion of the seventh conductor is covered with the fourth insulator. In the above, preferably, the fourth insulator includes one or both of zirconium oxide and aluminum oxide.

In the above, preferably, the sixth conductor overlaps with the fifth conductor with the metal oxide therebetween.

In the above, preferably, a tenth insulator in contact with a side surface of the first conductor is further included, and at least part of the third conductor is exposed from the tenth insulator and is in contact with the first conductor. In the above, preferably, the tenth insulator includes one or both of aluminum oxide and silicon nitride.

Another embodiment of the present invention is a method for manufacturing a semiconductor device, the method including: forming a first insulator, a second insulator, a metal oxide, a second conductor, and a third insulator in this order over a first conductor; processing the second insulator, the metal oxide, the second conductor, and the third insulator to form an island-shaped second insulator, an island-shaped metal oxide, an island-shaped second conductor, and an island-shaped third insulator; forming a fourth insulator to cover the first insulator, the island-shaped second insulator, the island-shaped metal oxide, the island-shaped second conductor, and the island-shaped third insulator; forming a first opening in the fourth insulator, dividing the island-shaped third insulator at a position overlapping with the first opening to form a fifth insulator and a sixth insulator, and dividing the island-shaped second conductor to form a third conductor and a fourth conductor; forming a seventh insulator and a fifth conductor over the seventh insulator in the first opening; forming an eighth insulator over the fourth insulator and the fifth conductor; forming a second opening reaching the third conductor in the eighth insulator, the fourth insulator, and the fifth insulator; forming a sixth conductor in the second opening; forming a ninth insulator and a seventh conductor to cover the sixth conductor; and processing the ninth insulator and the seventh conductor to form a tenth insulator and an eleventh insulator, an eighth conductor over the tenth insulator, and a ninth conductor over the eleventh insulator. The eighth conductor overlaps with the tenth insulator and the sixth conductor. The ninth conductor overlaps with the metal oxide and the fifth conductor.

The above method for manufacturing a semiconductor device preferably further includes forming a third opening to penetrate the eighth insulator, the fourth insulator, the sixth insulator, and the first insulator before the second opening is formed, and forming a tenth conductor in the third opening. The tenth conductor is preferably in contact with part of the fourth conductor.

The above method for manufacturing a semiconductor device preferably further includes forming a metal film over the third insulator and forming an organic coating film over the metal film before the second insulator, the metal oxide, the second conductor, and the third insulator are processed. The second insulator, the metal oxide, the second conductor, and the third insulator are preferably processed using a capacitively coupled plasma etching apparatus.

In the above method for manufacturing a semiconductor device, electric power of a lower electrode of a chamber of the capacitively coupled plasma etching apparatus is preferably set to less than or equal to 10 W during processing of the second conductor. In the above method for manufacturing a semiconductor device, the island-shaped second conductor is preferably formed before the organic coating film disappears during processing of the second conductor.

In the above method for manufacturing a semiconductor device, preferably, the first conductor overlaps with the metal oxide and the fifth conductor.

In the above method for manufacturing a semiconductor device, preferably, the first insulator includes hafnium oxide.

In the above method for manufacturing a semiconductor device, preferably, the second insulator includes silicon oxide.

In the above method for manufacturing a semiconductor device, preferably, the metal oxide includes indium, gallium, and zinc.

In the above method for manufacturing a semiconductor device, preferably, the second conductor has a stacked-layer structure of a layer including tantalum nitride and a layer including tungsten over the layer including tantalum nitride.

In the above method for manufacturing a semiconductor device, preferably, a thickness of the eighth insulator is greater than or equal to 50 nm and less than or equal to 250 nm.

In the above method for manufacturing a semiconductor device, preferably, the tenth insulator includes the same material as the eleventh insulator, and the eighth conductor includes the same material as the ninth conductor.

### Effect of the Invention

According to one embodiment of the present invention, a semiconductor device that can be miniaturized or highly integrated can be provided. According to one embodiment of the present invention, a semiconductor device with high operating speed can be provided. According to one embodiment of the present invention, a semiconductor device having favorable electrical characteristics can be provided. According to one embodiment of the present invention, a semiconductor device with a small variation in electrical characteristics of transistors can be provided. According to one embodiment of the present invention, a highly reliable semiconductor device can be provided. According to one embodiment of the present invention, a semiconductor device with high on-state current can be provided. According to one embodiment of the present invention, a semiconductor device with low power consumption can be provided. According to one embodiment of the present invention, a novel semiconductor device can be provided. According to one embodiment of the present invention, a method for manufacturing a semiconductor device with high productivity can be provided. According to one embodiment of the present invention, a method for manufacturing a novel semiconductor device can be provided.

According to one embodiment of the present invention, a memory device having a large memory capacity can be provided. According to one embodiment of the present invention, a memory device occupying a small area can be provided. According to one embodiment of the present invention, a highly reliable memory device can be provided. According to one embodiment of the present invention, a memory device with low power consumption can be provided. According to one embodiment of the present invention, a novel memory device can be provided. According to one embodiment of the present invention, a method for manufacturing a memory device with high productivity can be provided. According to one embodiment of the present invention, a method for manufacturing a novel memory device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1 is a cross-sectional view illustrating an example of a semiconductor device.

FIG. 2A and FIG. 2B are cross-sectional views illustrating examples of a semiconductor device.

FIG. 3A and FIG. 3B are cross-sectional views illustrating an example of a semiconductor device.

FIG. 4A and FIG. 4B are cross-sectional views illustrating an example of a semiconductor device.

FIG. 5 is a cross-sectional view illustrating an example of a semiconductor device.

FIG. 6A and FIG. 6B are top views illustrating examples of a semiconductor device.

FIG. 7A to FIG. 7C are views illustrating an example of a method for manufacturing a semiconductor device.

FIG. 8A to FIG. 8F are views illustrating an example of a method for manufacturing a semiconductor device.

FIG. 9A to FIG. 9C are views illustrating an example of a method for manufacturing a semiconductor device.

FIG. 10A to FIG. 10C are views illustrating an example of a method for manufacturing a semiconductor device.

FIG. 11A to FIG. 11C are views illustrating an example of a method for manufacturing a semiconductor device.

FIG. 12A to FIG. 12C are views illustrating an example of a method for manufacturing a semiconductor device.

FIG. 13A and FIG. 13B are views illustrating an example of a method for manufacturing a semiconductor device.

FIG. 14 is a view illustrating an example of a method for manufacturing a semiconductor device.

FIG. 15 is a block diagram showing an example of a memory device.

FIG. 16A and FIG. 16B are schematic views and a circuit diagram showing an example of a memory device.

FIG. 17A and FIG. 17B are schematic views each showing an example of a memory device.

FIG. 18 is a circuit diagram showing an example of a memory device.

FIG. 19 is a timing chart showing an operation example of a memory device.

FIG. 20A and FIG. 20B are circuit diagrams showing examples of a memory device.

FIG. 21A and FIG. 21B are circuit diagrams showing examples of a memory device.

FIG. 22A and FIG. 22B are views illustrating an example of a semiconductor device.

FIG. 23A and FIG. 23B are views illustrating an example of an electronic component.

FIG. 24A to FIG. 24J are views illustrating examples of electronic devices.

FIG. 25A to FIG. 25E are views illustrating examples of electronic devices.

FIG. 26A to FIG. 26C are views illustrating an example of an electronic device.

FIG. 27 is a view illustrating an example of a device for space.

FIG. 28A and FIG. 28B are graphs of this example.

FIG. 29A and FIG. 29B are cross-sectional SEM images of this example.

FIG. 30A and FIG. 30B are cross-sectional SEM images of this example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Thus, the disclosed invention is not necessarily limited to the position, size, range, or the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”. The term “conductor” can be replaced with the term “conductive layer” or “conductive film” depending on the case or the circumstances. The term “insulator” can be replaced with the term “insulating layer” or “insulating film” depending on the case or the circumstances.

The term “opening” includes a groove and a slit, for example. A region where an opening is formed is referred to as an opening portion in some cases.

In the drawings used in embodiments, a sidewall of an insulator in an opening portion in the insulator is illustrated as being substantially perpendicular to a substrate surface or a formation surface, but the sidewall may have a tapered shape.

Note that in this specification and the like, the tapered shape refers to a shape such that at least part of a side surface of a component is inclined to a substrate surface or a formation surface. For example, the tapered shape preferably includes a region where the angle formed between the inclined side surface and the substrate surface or the formation surface (the angle is hereinafter referred to as a taper angle in some cases) is less than 90°. Note that the side surface of the component and the substrate surface are not necessarily completely flat and may be substantially flat with a slight curvature or substantially flat with slight unevenness.

### Embodiment 1

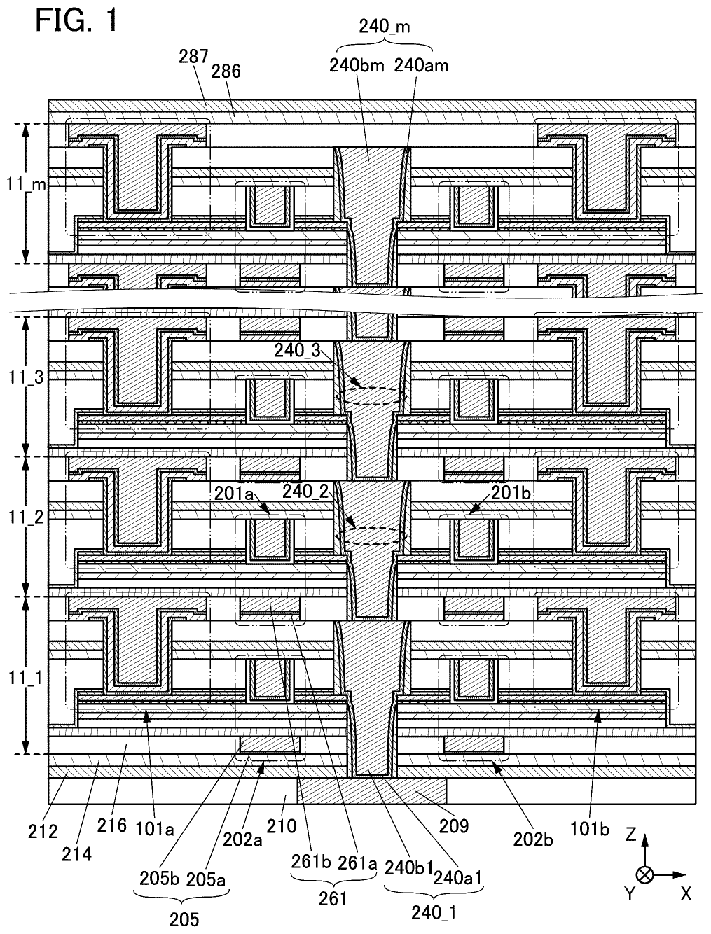

In this embodiment, a semiconductor device of one embodiment of the present invention is described with reference to FIG. 1 to FIG. 14.

One embodiment of the present invention is a semiconductor device which includes a first memory cell, a second memory cell over the first memory cell, a first conductor, and a second conductor over the first conductor and in which the first memory cell and the second memory cell each include a transistor, a capacitor, and a first insulator over the transistor; the transistor includes a metal oxide, a third conductor, a fourth conductor, and a second insulator over the metal oxide, a fifth conductor over the second insulator, a third insulator under the metal oxide, and a sixth conductor under the third insulator; the capacitor includes a seventh conductor, a fourth insulator over the seventh conductor, and an eighth conductor over the fourth insulator; part of the seventh conductor, part of the fourth insulator, and part of the eighth conductor are positioned over the first insulator; the fourth conductor and the seventh conductor are in contact with each other through an opening provided in the first insulator; the first conductor includes a portion in contact with the third conductor included in the first memory cell; a top surface of the first conductor includes a portion in contact with a bottom surface of the second conductor; the second conductor includes a portion in contact with the third conductor included in the second memory cell; the sixth conductor included in the second memory cell includes the same material as the eighth conductor included in the first memory cell; and in a cross-sectional view of the transistor, one side end portion of the third conductor is substantially aligned with one side end portion of the metal oxide and one side end portion of the fourth conductor is substantially aligned with the other side end portion of the metal oxide.

The semiconductor device of one embodiment of the present invention includes a transistor (OS transistor) including a metal oxide in a channel formation region. Since the OS transistor has low off-state current, a memory device that uses the OS transistor can retain stored data for a long time. In other words, such a memory device does not require refresh operation or has extremely low frequency of the refresh operation, which leads to a sufficient reduction in power consumption of the memory device. The OS transistor also has high frequency characteristics and thus enables high-speed reading and writing of the memory device.

The first conductor and the second conductor included in the semiconductor device of one embodiment of the present invention can each function as part of a write and read bit line (also simply referred to as a bit line) in a memory device. That is, a memory device to which one embodiment of the present invention is applied can employ a structure in which the third conductor is directly in contact with the bit line. With such a structure, a separate electrode for connection does not need to be provided between the third conductor and the bit line, so that the degree of integration of memory cells can be increased.

In the semiconductor device of one embodiment of the present invention, a plurality of memory cells are provided in stacked layers, and the bit line employs a stacked-layer structure of a plurality of conductors. The first conductor includes a portion in contact with the third conductor included in the first memory cell, and the second conductor includes a portion in contact with the third conductor included in the second memory cell. The top surface of the first conductor includes a portion in contact with the bottom surface of the second conductor. When a conductor functioning as the bit line has such a stacked-layer structure of a plurality of conductors, the manufacturing yield of the semiconductor device of one embodiment of the present invention can be increased as compared with the case where one conductor is used as the bit line.

In a method for manufacturing the semiconductor device of one embodiment of the present invention, the sixth conductor included in the second memory cell and the eighth conductor included in the first memory cell can be formed in the same layer in the same step. In this case, the sixth conductor included in the second memory cell includes the same material as the eighth conductor included in the first memory cell. With such a structure, the productivity of the method for manufacturing the semiconductor device of one embodiment of the present invention can be increased as compared with the case where the sixth conductor included in the second memory cell and the eighth conductor included in the first memory cell are formed in different steps.

In the method for manufacturing a semiconductor device of one embodiment of the present invention, an island-shaped metal oxide and a conductor (a conductor to be the third conductor and the fourth conductor in a later step) over the island-shaped metal oxide can be processed into an island shape in the same step. Through such a step, the one side end portion of the third conductor is substantially aligned with the one side end portion of the metal oxide, and the one side end portion of the fourth conductor is substantially aligned with the other side end portion of the metal oxide. With this structure, the productivity of the method for manufacturing the semiconductor device of one embodiment of the present invention can be increased as compared with the case where the island-shaped metal oxide and the conductor over the island-shaped metal oxide are formed in different steps.

### <Cross-Sectional Structure Example 1 of Semiconductor Device>

Cross-sectional structure examples of the semiconductor device of one embodiment of the present invention are described with reference to FIG. 1 to FIG. 4.

Note that in FIG. 1 to FIG. 4, the X direction is parallel to the channel length direction of illustrated transistors, the Y direction is perpendicular to the X direction, and the Z direction is perpendicular to the X direction and the Y direction.

A semiconductor device illustrated in FIG. 1 includes an insulator 210, a conductor 209 embedded in the insulator 210, an insulator 212 over the insulator 210, an insulator 214 over the insulator 212, m (m is an integer greater than or equal to 1) layers (a first layer 11_1 to an m-th layer 11_m) over the insulator 214, m conductors 240 (a conductor 240_1 to a conductor 240_m) provided to extend in the Z direction so as to penetrate the m layers and electrically connected to the conductor 209, an insulator 286 over the m-th layer 11_m, and an insulator 287 over the insulator 286. Note that components of the semiconductor device of this embodiment may each have either a single-layer structure or a stacked-layer structure.

Note that the conductors 240 each preferably include a conductor 240a and a conductor 240b. As illustrated in FIG. 1, for example, the conductor 240_1 includes a conductor 240al and a conductor 240b1, and the conductor 240_mincludes a conductor 240am and a conductor 240bm. Hereinafter, the conductor 240al to the conductor 240am are collectively referred to as the conductor 240a in some cases. The conductor 240b1 to the conductor 240bm are collectively referred to as the conductor 240b in some cases.

The conductor 209 functions as part of a circuit element such as a switch, a transistor, a capacitor, an inductor, a resistor, or a diode, a wiring, an electrode, or a terminal.

Among the m layers, FIG. 1 illustrates the first layer 11_1, which is the lowermost layer, the second layer 11_2 over the first layer 11_1, the third layer 11_3 over the second layer 11_2, and the m-th layer 11_m, which is the uppermost layer. Among the m conductors 240, FIG. 1 illustrates the conductor 240_1, which is the lowermost layer, the conductor 240_2 over the conductor 240_1, the conductor 240_3 over the conductor 240_2, and the conductor 240_m, which is the uppermost layer.

Although this embodiment gives an example of including the m layers and the m conductors 240, the present invention is not limited thereto. For example, the number of conductors 240 can be greater than or equal to two and less than or equal to m. This can increase the yield of the semiconductor device as compared with the case where the number of conductors 240 is one (the case of including one conductor 240a and one conductor 240b).

The semiconductor device of this embodiment can be used as a memory cell (or a memory array) in a memory device. Each of the m layers corresponds to a memory array 20[i] in a memory device described in Embodiment 2. A plurality of memory cells are provided in each of the m layers. The conductor 209 is electrically connected to a driver circuit for driving the memory cells, which is provided below the conductor 209. Increasing the number of stacked memory arrays (increasing the value of m) can increase the memory capacity of the memory device without increasing the area occupied by the memory cells. This can reduce the area occupied per bit, enabling the memory device to have a small size and a large memory capacity.

The second layer 11_2 and the layers above the second layer 11_2 among the m layers have a similar structure; thus, the second layer 11_2 is mainly described as an example in this embodiment. As for the first layer 11_1, portions similar to those of the second layer 11_2 are not described, and portions different from those of the second layer 11_2 are mainly described.

The first layer 11_1 includes transistors 202a and 202b and capacitors 101a and 101b.

The second layer 11_2 includes transistors 201a and 201b and the capacitors 101a and 101b. Each of the layers from the third layer 11_3 to the m-th layer 11_malso includes the transistors 201a and 201b and the capacitors 101a and 101b.

As illustrated in FIG. 1, in each of the first layer 11_1 and the second layer 11_2, a structure on the right side and a structure on the left side are symmetrical with respect to the conductor 240. That is, in FIG. 1, the transistor 201a and the transistor 201b are symmetrical, the transistor 202a and the transistor 202b are symmetrical, and the capacitor 101a and the capacitor 101b are symmetrical. In this embodiment, the structure on the left side in the first layer 11_1 and the second layer 11_2 (the transistors 201a and 202a and the capacitor 101a) is mainly described as an example.

The transistor 202a included in the first layer 11_1 is provided over the insulator 214. A conductor 205 (a conductor 205a and a conductor 205b) is provided as a lower gate electrode of the transistor 202a. One electrode (lower electrode) of the capacitor 101a is over one of a source and a drain of the transistor 202a and is physically and electrically connected to the one of the source and the drain of the transistor 202a.

The one electrode (lower electrode) of the capacitor 101a included in the second layer 11_2 is over one of a source and a drain of the transistor 201a included in the second layer 11_2 and is physically and electrically connected to the one of the source and the drain of the transistor 201a included in the second layer 11_2. A conductor 261 (a conductor 261a and a conductor 261b) is provided as a lower gate electrode of the transistor 201a. The conductor 261 included in the transistor 201a in the second layer 11_2 is formed in the same layer as the other electrode (upper electrode) of the capacitor 101a included in the first layer 11_1. The conductor 261 of the transistor 201a included in the second layer 11_2 and the other electrode of the capacitor 101a included in the first layer 11_1 can be formed in the same step.

Similarly, the upper electrode of the capacitor 101a included in the second layer 11_2 is formed in the same layer as the conductor 261 of the transistor 201a included in the third layer 11_3.

As described above, while the upper electrode of the capacitor is not formed in the same layer as the conductor 205 in the first layer 11_1, in the second layer 11_2 and the layers above the second layer 11_2, the conductor 261 is formed in the same layer as the upper electrode of the capacitor 101a in the next lower layer. In this regard, the first layer 11_1 is different from the second layer 11_2 and the layers above the second layer 11_2.

The other of the source and the drain of the transistor 202a included in the first layer 11_1 is connected to the conductor 240_1, and the other of the source and the drain of the transistor 201a included in the second layer 11_2 is connected to the conductor 240_2.

Here, in the case where an opening portion for providing the conductor 240 is provided in the stacked-layer structure of insulators after the m layers of memory cells are stacked, the opening portion needs to be deep, resulting in a high degree of processing difficulty or a low manufacturing yield in some cases. Specifically, it is sometimes difficult to maintain a constant width of the opening portion (also referred to as an opening diameter, which corresponds to a length in the X axis direction in FIG. 1 or the like). For example, the width of the opening portion on the upper side (the m-th layer side) is likely to be large, and the width of the opening portion on the lower side (the first layer side) is likely to be small.

Thus, in a method for manufacturing a semiconductor device of this embodiment, after the transistors 202a and 202b included in the first layer 11_1 are formed, the opening portion for providing the conductor 240_1 is provided in the stacked-layer structure of insulators, and the opening portion is filled with the conductor 240_1. After the formation of the conductor 240_1, the capacitors 101a and 101b are formed. Subsequently, the transistors 201a and 201b included in the second layer 11_2 are formed, an opening portion for providing the conductor 240_2 is provided in the stacked-layer structure of insulators, and the opening portion is filled with the conductor 240_2. After the formation of the conductor 240_2, the capacitors 101a and 101b are formed. By repeating such steps, the m layers and the m conductors can be electrically connected to each other. The use of a plurality of conductors enables the depth of one opening to be small, which can facilitate processing and increase the manufacturing yield.

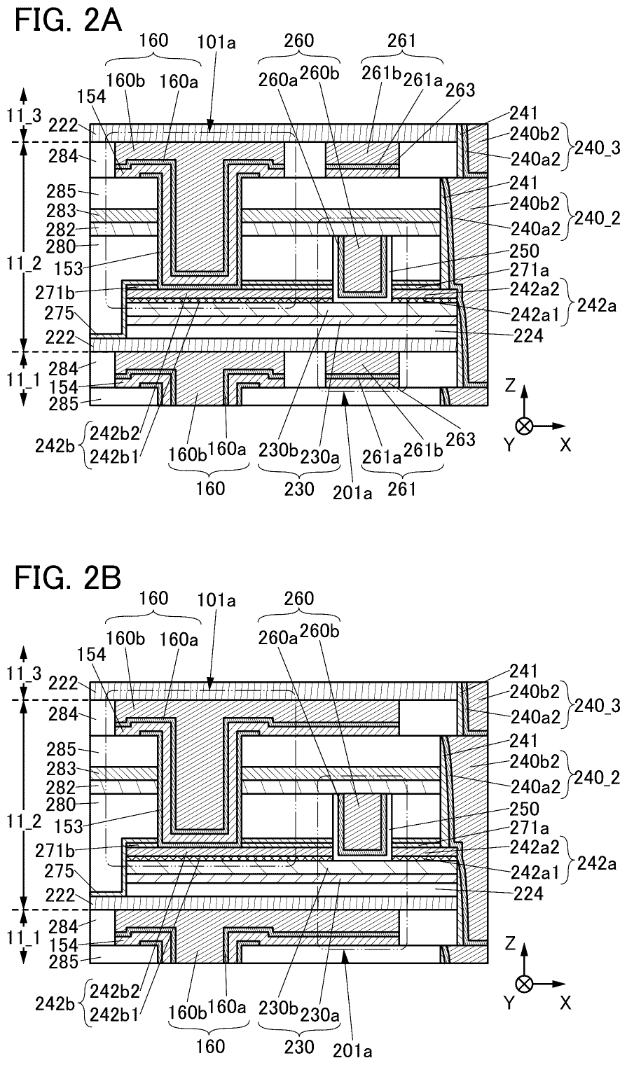

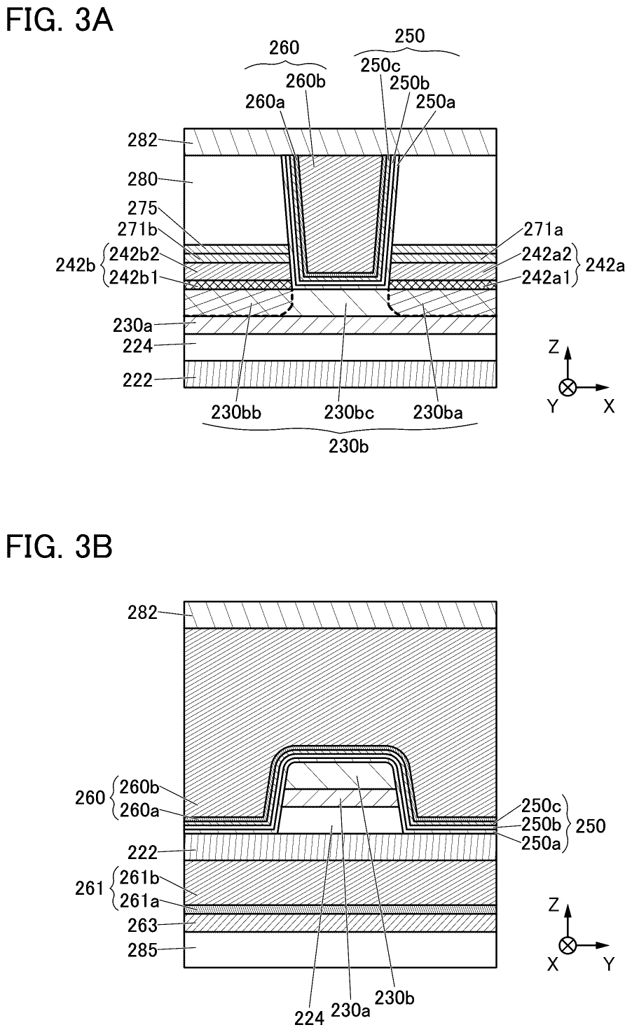

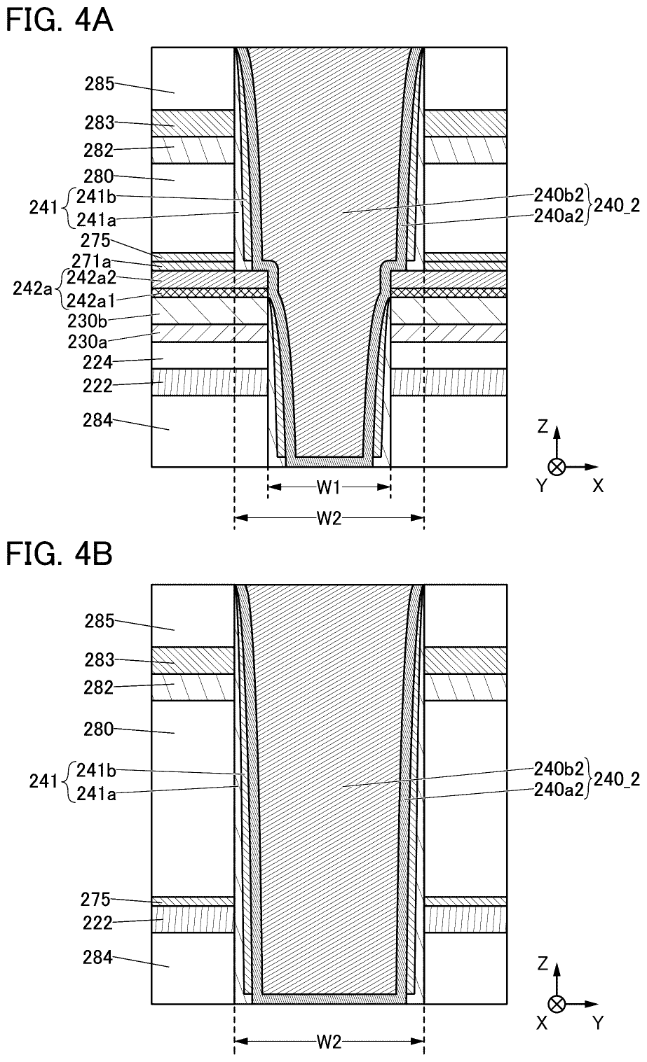

FIG. 2A is an enlarged view of the structure in the left half of the second layer 11_2 and its vicinity in FIG. 1 (the conductor 240_2 and the structure on the left side thereof). FIG. 2B illustrates a modification example of FIG. 2A. FIG. 3A is an enlarged cross-sectional view of the transistor 201a in the channel length direction, and FIG. 3B is an enlarged cross-sectional view of the transistor 201a in the channel width direction. FIG. 4A and FIG. 4B are enlarged views of a region where the conductor 240_2 is in contact with the other of the source and the drain of the transistor 201a in the structure illustrated in FIG. 1 and the vicinity thereof. FIG. 4A is an enlarged cross-sectional view of the transistor 201a in the channel length direction, and FIG. 4B is an enlarged cross-sectional view of the transistor 201a in the channel width direction.

As illustrated in FIG. 2A, the second layer 11_2 includes the transistor 201a and the capacitor 101a.

The transistor 201a includes the conductor 261 (the conductor 261a and the conductor 261b) provided to be embedded in an insulator 284; an insulator 222 over the conductor 261; an insulator 224 over the insulator 222; an oxide 230 (an oxide 230a and an oxide 230b) over the insulator 224; a conductor 242a (a conductor 242al and a conductor 242a2) and a conductor 242b (a conductor 242b1 and a conductor 242b2) over the oxide 230; an insulator 271a over the conductor 242a; an insulator 271b over the conductor 242b; an insulator 250 over the oxide 230; and a conductor 260 (a conductor 260a and a conductor 260b) over the insulator 250.

An insulator 275 is provided over the insulators 271a and 271b, and an insulator 280 is provided over the insulator 275. The insulator 250 and the conductor 260 are embedded in an opening provided in the insulator 280 and the insulator 275. An insulator 282 is provided over the insulator 280 and the conductor 260. An insulator 283 is provided over the insulator 282, and an insulator 285 is provided over the insulator 283. An insulator 284 is provided over the insulator 285.

The oxide 230 includes a region functioning as a channel formation region of the transistor 201a.

The conductor 242a includes a region functioning as one of a source electrode and a drain electrode of the transistor 201a. The conductor 242b includes a region functioning as the other of the source electrode and the drain electrode of the transistor 201a.

As illustrated in FIG. 2A, in a cross-sectional view of the transistor 201a, it is preferable that one side end portion of the conductor 242a be substantially aligned with one side end portion of the oxide 230 and one side end portion of the conductor 242b be substantially aligned with the other side end portion of the oxide 230. Furthermore, side end portions of the insulator 224 are preferably substantially aligned with the side end portions of the oxide 230. In one embodiment of the present invention, the insulator 224, the oxide 230, and a conductor to be the conductor 242a and the conductor 242b in a later step can be collectively processed into an island shape. Accordingly, the semiconductor device of one embodiment of the present invention can be manufactured with favorable productivity. In the case of processing in the above manner, the side end portions of the insulator 224, the oxide 230, the conductor 242a, and the conductor 242b are substantially aligned with each other as described above.

The insulator 271a and the insulator 271b are films for protecting the conductor 242a and the conductor 242b in the processing into island shape. For example, the insulator 271a and the insulator 271b function as etching stoppers when a hard mask is removed in the processing into the conductor 242a and the conductor 242b. Thus, as illustrated in FIG. 2A, in a cross-sectional view of the transistor 201a, it is preferable that a side end portion of the insulator 271a on the insulator 250 side be substantially aligned with a side end portion of the conductor 242a on the insulator 250 side and both side end portions of the insulator 271b be substantially aligned with side end portions of the conductor 242b.

In the case where side end portions are aligned or substantially aligned with each other in a cross-sectional view and the case where top surface shapes are the same or substantially the same, it can be said that outlines of stacked layers at least partly overlap with each other in a top view. Examples of such cases include the case where the lower portion of the side end portion of the upper layer is in contact with the upper portion of the side end portion of the lower layer.

Examples of such cases also include the case of processing the upper layer and the lower layer with the use of the same mask pattern or mask patterns that are partly the same. Note that, in some cases, the outlines do not exactly overlap with each other and the outline of part of the upper layer is positioned inward from the outline of the lower layer or the outline of part of the upper layer is positioned outward from the outline of the lower layer; such a case is also regarded as side end portions being substantially aligned or top surface shapes being substantially the same.

The conductor 260 includes a region functioning as a first gate electrode (an upper gate electrode) of the transistor 201a. The insulator 250 includes a region functioning as a first gate insulator of the transistor 201a. The conductor 261 includes a region functioning as a second gate electrode (a lower gate electrode) of the transistor 201a. Each of the insulator 224 and the insulator 222 includes a region functioning as a second gate insulator of the transistor 201a.

The capacitor 101a includes a conductor 153 over the conductor 242b, an insulator 154 over the conductor 153, and a conductor 160 (a conductor 160a and a conductor 160b) over the insulator 154

The conductor 153, the insulator 154, and the conductor 160 are at least partly provided in an opening provided in the insulator 271b, the insulator 275, the insulator 280, the insulator 282, the insulator 283, and the insulator 285. An end portion of each of the conductor 153, the insulator 154, and the conductor 160 is positioned over at least the insulator 282, preferably over the insulator 285. The insulator 154 is provided to cover the end portion of the conductor 153. This enables the conductor 153 and the conductor 160 to be electrically insulated from each other.

The deeper the opening provided in the insulator 271b, the insulator 275, the insulator 280, the insulator 282, the insulator 283, and the insulator 285 is (i.e., the larger the thickness of one or more of the insulator 271b, the insulator 275, the insulator 280, the insulator 282, the insulator 283, and the insulator 285 is), the larger the capacitance of the capacitor 101a can be. Increasing the capacitance per unit area of the capacitor 101a can achieve miniaturization or higher integration of the semiconductor device.

The conductor 153 includes a region functioning as the one electrode (lower electrode) of the capacitor 101a. The insulator 154 includes a region functioning as a dielectric of the capacitor 101a. The conductor 160 includes a region functioning as the other electrode (upper electrode) of the capacitor 101a. The capacitor 101a forms a MIM (Metal-Insulator-Metal) capacitor.

Here, the conductor 160 functioning as the upper electrode of the capacitor 101a in the lower layer (e.g., the first layer 11_1) and the conductor 261 functioning as the second gate electrode of the transistor 201a in the upper layer (e.g., the second layer 11_2) are formed in the same layer. In other words, the conductor 160 of the capacitor 101a in the lower layer and the conductor 261 of the transistor 201a in the upper layer are formed to be embedded in openings formed in the same insulator 284. When the conductor 160 of the capacitor 101a in the lower layer and the conductor 261 of the transistor 201a in the upper layer are formed by processing one conductive film, the above-described structure is obtained. In this case, the conductor 160 of the capacitor 101a in the lower layer includes the same material as the conductor 261 of the transistor 201a in the upper layer.

An insulator 263 is preferably provided in contact with the bottom surface of the conductor 261. In the above step, when the conductor 160 of the capacitor 101a in the lower layer and the conductor 261 of the transistor 201a in the upper layer are formed, the insulator 263 is formed concurrently with the insulator 154 functioning as a dielectric film of the capacitor 101a in the lower layer. That is, the insulator 154 of the capacitor 101a in the lower layer (e.g., the first layer 11_1) and the insulator 263 of the transistor 201a in the upper layer (e.g., the second layer 11_2) are formed in the same layer. In other words, the insulator 154 of the capacitor 101a in the lower layer and the insulator 263 of the transistor 201a in the upper layer are formed to be embedded in openings formed in the same insulator 284. Here, the insulator 154 of the capacitor 101a in the lower layer includes the same material as the insulator 263 of the transistor 201a in the upper layer.

When the conductor 160 and the insulator 154 of the capacitor 101a in the lower layer are respectively formed at the same time as the conductor 261 and the insulator 263 of the transistor 201a in the upper layer as described above, the number of manufacturing steps of the semiconductor device of this embodiment can be reduced, and the productivity of the semiconductor device can be improved.

Although FIG. 2A illustrates a structure in which the upper electrode (the conductor 160) of the capacitor 101a in the lower layer (e.g., the first layer 11_1) and the second gate electrode (the conductor 261) of the transistor 201a in the upper layer (e.g., the second layer 11_2) are provided separately from each other, the present invention is not limited thereto. As illustrated in FIG. 2B, the conductor 160 may serve as the upper electrode of the capacitor 101a in the lower layer (e.g., the first layer 11_1) and the second gate electrode of the transistor 201a in the upper layer (e.g., the second layer 11_2).

The conductor 242b provided over the oxide 230 and overlapping with the oxide 230 functions as a wiring electrically connected to the conductor 153 of the capacitor 101a.

The conductor 242a provided over the oxide 230 and overlapping with the oxide 230 functions as a wiring electrically connected to the conductor 240. In FIG. 2A, for example, the top surface and the side end portion of the conductor 242a are electrically connected to the conductor 240_2 extending in the Z direction.

When the conductor 240_2 is directly in contact with at least one of the top surface and the side end portion of the conductor 242a, a separate electrode for connection does not need to be provided, so that the area occupied by memory arrays can be reduced. In addition, the integration degree of the memory cells can be increased and the memory capacity can be increased. Note that the conductor 240_2 is preferably in contact with the side end portion and part of the top surface of the conductor 242a. When the conductor 240_2 is in contact with a plurality of surfaces of the conductor 242a, the contact resistance between the conductor 240_2 and the conductor 242a can be reduced.

As illustrated in FIG. 4A, the conductor 240_2 includes a region having a width W1 and a region having a width W2. The width W1 corresponds to the distance of an opening between the conductor 242a included in the transistor 201a and the conductor 242a included in the transistor 201b. The width W2 corresponds to the diameter of the uppermost surface of the opening provided in the insulator 285, and for example, corresponds to the distance between the interface between the insulator 285 and the conductor 240a2 on the transistor 201a side and the interface between the insulator 285 and the conductor 240a2 on the transistor 201b side.

As illustrated in FIG. 4A, the width W2 is preferably larger than the width W1. In this structure, the conductor 240_2 is in contact with at least part of the top surface and part of the side end portion of the conductor 242a. Accordingly, the area of the region where the conductor 240_2 and the conductor 242a are in contact with each other can be increased. Note that in this specification and the like, contact between the conductor 240_2 and the conductor 242a illustrated in FIG. 4A and the like is referred to as top-side contact in some cases.

An opening in the insulator 285 to the insulator 284 can be formed in a state where the conductor 242a of the transistor 201a and the conductor 242b of the transistor 201b are each formed into an island shape. In this case, as illustrated in FIG. 4B, in a cross section of the opening on the YZ plane, the conductor 242a does not necessarily overlap with the opening.

An insulator 241 is preferably provided in contact with the side surface of the conductor 240 (e.g., in FIG. 4A and FIG. 4B, the conductor 240_2 corresponds to the conductor 240). As illustrated in FIG. 4A and FIG. 4B, the insulator 241 is preferably provided between the conductor 240_2 and the insulator 284, the insulator 222, the insulator 224, the oxide 230, the insulator 271a, the insulator 275, the insulator 280, the insulator 282, the insulator 283, and the insulator 285. Here, at least part of the conductor 242a is exposed from the insulator 241 and is in contact with the conductor 240_2. With such a structure, the insulator 241 can prevent oxygen and impurities such as hydrogen included in the conductor 240_2 from diffusing into the oxide 230. Thus, the electrical characteristics and reliability of the transistor 201a can be improved.

Next, the transistors included in the semiconductor device of this embodiment are described in detail.

Although the components of the transistor 201a are mainly described below as an example, the same can be applied to the components of the transistor 202a.

The oxide 230 preferably includes the oxide 230a over the insulator 224 and the oxide 230b over the oxide 230a. Including the oxide 230a under the oxide 230b makes it possible to inhibit diffusion of impurities into the oxide 230b from components formed below the oxide 230a.

Although an example in which the oxide 230 has a two-layer structure of the oxide 230a and the oxide 230b is described in this embodiment, the present invention is not limited thereto. For example, the oxide 230 may have a single-layer structure of the oxide 230b or a stacked-layer structure of three or more layers.

As illustrated in FIG. 3A, the oxide 230b includes a region 230bc and a region 230ba and a region 230bb that are provided to sandwich the region 230bc in the transistor 201a. Here, the region 230bc functions as the channel formation region. The region 230ba functions as one of a source region and a drain region, and the region 230bb functions as the other of the source region and the drain region. At least part of the region 230bc overlaps with the conductor 260. The region 230ba overlaps with the conductor 242a, and the region 230bb overlaps with the conductor 242b.

The region 230bc has a smaller amount of oxygen vacancies or a lower impurity concentration than the region 230ba and the region 230bb, and thus is a high-resistance region with a low carrier concentration. Thus, the region 230bc can be regarded as being i-type (intrinsic) or substantially i-type.

The region 230ba and the region 230bb have a large amount of oxygen vacancies or a high concentration of an impurity such as hydrogen, nitrogen, or a metal element, and thus are each a low-resistance region with a high carrier concentration. That is, the region 230ba and the region 230bb are each an n-type region (a low-resistance region) having a higher carrier concentration than the region 230bc.

Note that the carrier concentration of the region 230bc is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the region 230bc is not particularly limited and can be, for example, 1× 10-9 cm⁻³.

In order to reduce the carrier concentration in the oxide 230b, the impurity concentration in the oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration may be referred to as a highly purified intrinsic or substantially highly purified intrinsic oxide semiconductor (or metal oxide).

In order to obtain stable electrical characteristics of the transistor 201a, reducing the impurity concentration in the oxide 230b is effective. In order to reduce the impurity concentration in the oxide 230b, it is preferable that the impurity concentration in an adjacent film be also reduced. Examples of impurities include hydrogen, nitrogen, an alkali metal, an alkaline earth metal, iron, nickel, and silicon. Note that an impurity in the oxide 230b refers to, for example, an element other than the main components of the oxide 230b. For example, an element with a concentration lower than 0.1 atomic % can be regarded as an impurity.

Note that the region 230bc, the region 230ba, and the region 230bb may each be formed not only in the oxide 230b but also in the oxide 230a.

In the oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the region 230bc may have lower concentrations of a metal element and impurity elements such as hydrogen and nitrogen.

A metal oxide functioning as a semiconductor (hereinafter also referred to as an oxide semiconductor) is preferably used as the oxide 230 (the oxide 230a and the oxide 230b).

The metal oxide functioning as a semiconductor preferably has a band gap of 2 eV or higher, further preferably 2.5 eV or higher. With the use of a metal oxide having a wide bandgap, the off-state current of the transistor can be reduced.

As the oxide 230, a metal oxide such as indium oxide, gallium oxide, or zinc oxide is preferably used, for example. Alternatively, as the oxide 230, a metal oxide including two or three selected from indium, an element M, and zinc is preferably used, for example. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin. Note that a metal oxide including indium, the element M, and zinc is referred to as In-M-Zn oxide in some cases.

The oxide 230 preferably has a stacked-layer structure of a plurality of oxide layers with different chemical compositions. For example, the atomic ratio of the element M to a metal element that is a main component in the metal oxide used as the oxide 230a is preferably greater than the atomic ratio of the element M to a metal element that is a main component in the metal oxide used as the oxide 230b. Moreover, the atomic ratio of the element M to In in the metal oxide used as the oxide 230a is preferably greater than the atomic ratio of the element M to In in the metal oxide used as the oxide 230b. With this structure, impurities and oxygen can be inhibited from diffusing into the oxide 230b from the components formed below the oxide 230a.

Furthermore, the atomic ratio of In to the element M in the metal oxide used as the oxide 230b is preferably greater than the atomic ratio of In to the element M in the metal oxide used as the oxide 230a. With this structure, the transistor 201a can have high on-state current and high frequency characteristics.

When the oxide 230a and the oxide 230b include a common element as the main component besides oxygen, the density of defect states at an interface between the oxide 230a and the oxide 230b can be decreased. Thus, the influence of interface scattering on carrier conduction is small, and the transistor 201a can have high on-state current and high frequency characteristics.

Specifically, as the oxide 230a, a metal oxide with a composition of In:M:Zn=1:3:4 [atomic ratio] or in the neighborhood thereof, a composition of In:M:Zn=1:3: 2 [atomic ratio] or in the neighborhood thereof, or a composition of In:M:Zn=1:1:0.5 [atomic ratio] or in the neighborhood thereof can be used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of +30% of an intended atomic ratio. Gallium is preferably used as the element M. In the case where a single layer of the oxide 230b is provided as the oxide 230, a metal oxide that can be used as the oxide 230a may be used as the oxide 230b. The compositions of the metal oxides that can be used as the oxide 230a and the oxide 230b are not limited to the above. For example, the composition of the metal oxide that can be used as the oxide 230a can be applied to the oxide 230b. Similarly, the composition of the metal oxide that can be used as the oxide 230b can be applied to the oxide 230a.

When the metal oxide film is formed by a sputtering method, the above atomic ratio is not limited to the atomic ratio of the formed metal oxide film and may be the atomic ratio of a sputtering target used for forming the metal oxide film.

The oxide 230b preferably has crystallinity. It is particularly preferable to use a CAAC-OS (c-axis aligned crystalline oxide semiconductor) as the oxide 230b.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Thus, the metal oxide including the CAAC-OS is resistant to heat and has high reliability.

When an oxide having crystallinity, such as CAAC-OS, is used as the oxide 230b, oxygen extraction from the oxide 230b by the source electrode or the drain electrode can be inhibited. This can reduce oxygen extraction from the oxide 230b even when heat treatment is performed; thus, the transistor 201a is stable with respect to high temperatures in a manufacturing process (what is called thermal budget).

A transistor using an oxide semiconductor is likely to have its electrical characteristics changed by impurities and oxygen vacancies in a region where a channel is formed in the oxide semiconductor, which might affect the reliability. In some cases, a defect that is an oxygen vacancy into which hydrogen in the vicinity of the oxygen vacancy has entered (hereinafter sometimes referred to as VoH) is formed, which generates an electron serving as a carrier. Accordingly, when the region 230bc where a channel is formed in the oxide semiconductor includes oxygen vacancies, the transistor is likely to have normally-on characteristics (characteristics with which, even when no voltage is applied to the gate electrode, the channel exists and current flows through the transistor). Thus, impurities, oxygen vacancies, and VoH are preferably reduced as much as possible in the region 230bc of the oxide semiconductor. In other words, the region 230bc of the oxide semiconductor is preferably an i-type (intrinsic) or substantially i-type region with a reduced carrier concentration.

As a countermeasure against the above, an insulator including oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the region 230ba or the region 230bb might cause a decrease in the on-state current or field-effect mobility of the transistor 201a. Furthermore, a variation of the amount of oxygen supplied to the region 230ba or the region 230bb in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the region 230bc is preferably an i-type or substantially i-type region with a reduced carrier concentration, whereas the region 230ba and the region 230bb are preferably n-type regions with high carrier concentrations. That is, the amounts of oxygen vacancies and VoH in the region 230bc of the oxide semiconductor are preferably reduced. Supply of an excess amount of oxygen to the region 230ba and the region 230bb and excessive reduction in the amount of VoH in the region 230ba and the region 230bb are preferably inhibited. Furthermore, a structure is preferable in which a reduction in the conductivity of the conductor 260, the conductor 242a, the conductor 242b, and the like is inhibited. For example, a structure is preferable in which oxidation of the conductor 260, the conductor 242a, the conductor 242b, and the like is inhibited. Note that hydrogen in the oxide semiconductor can form VoH;

thus, the hydrogen concentration needs to be reduced in order to reduce the amount of VoH.

The semiconductor device of this embodiment thus has a structure in which the hydrogen concentration in the region 230bc is reduced, oxidation of the conductor 242a, the conductor 242b, and the conductor 260 is inhibited, and a reduction in the hydrogen concentration in the region 230ba and the region 230bb is inhibited.

The insulator 250 in contact with the region 230bc of the oxide 230b preferably has a function of capturing and fixing hydrogen. This can reduce the hydrogen concentration in the region 230bc of the oxide 230b. Thus, VoH in the region 230bc can be reduced, and the region 230bc can be an i-type or substantially i-type region.

Here, as illustrated in FIG. 3A, the insulator 250 preferably has a stacked-layer structure of an insulator 250a in contact with the oxide 230, an insulator 250b over the insulator 250a, and an insulator 250c over the insulator 250b. In that case, the insulator 250a preferably has a function of capturing and fixing hydrogen.

Examples of insulators having a function of capturing and fixing hydrogen include a metal oxide having an amorphous structure. As the insulator 250a, for example, a metal oxide, such as magnesium oxide or an oxide including one or both of aluminum and hafnium, is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

A high dielectric constant (high-k) material is preferably used for the insulator 250a. An example of the high-k material is an oxide including one or both of aluminum and hafnium. With the use of the high-k material for the insulator 250a, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 250a, an oxide including one or both of aluminum and hafnium is preferably used, more preferably, an oxide including one or both of aluminum and hafnium and having an amorphous structure is used, and further preferably, hafnium oxide having an amorphous structure is used. In this embodiment, hafnium oxide is used for the insulator 250a. In this case, the insulator 250a is an insulator that includes at least oxygen and hafnium. The hafnium oxide has an amorphous structure. In this case, the insulator 250a has an amorphous structure.

Next, an insulator having a thermally stable structure, such as silicon oxide or silicon oxynitride, is preferably used as the insulator 250b. The insulator 250b may have a stacked-layer structure. In this case, the insulator 250b can have a stacked-layer structure in which an insulator that can be used as the insulator 250a is provided over silicon oxide or silicon oxynitride. As another example, the insulator 250 may have a stacked-layer structure including silicon oxide or silicon oxynitride and hafnium oxide over the silicon oxide or the silicon oxynitride.

Note that in this specification and the like, oxynitride refers to a material that includes more oxygen than nitrogen in its composition, and nitride oxide refers to a material that includes more nitrogen than oxygen in its composition. For example, silicon oxynitride refers to a material that includes more oxygen than nitrogen in its composition, and silicon nitride oxide refers to a material that includes more nitrogen than oxygen in its composition.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 250a, the insulator 250c, and the insulator 275, for example.

Note that in this specification and the like, a barrier insulator refers to an insulator having a barrier property. A barrier property in this specification and the like means a function of inhibiting diffusion of a targeted substance (also referred to as having low permeability). Alternatively, the barrier property means a function of capturing and fixing (also referred to as gettering) a targeted substance.

Examples of the barrier insulator against oxygen include an oxide including one or both of aluminum and hafnium, magnesium oxide, gallium oxide, indium gallium zinc oxide, silicon nitride, and silicon nitride oxide. Examples of the oxide including one or both of aluminum and hafnium include aluminum oxide, hafnium oxide, an oxide including aluminum and hafnium (hafnium aluminate), and an oxide including hafnium and silicon (hafnium silicate). For example, each of the insulator 250a, the insulator 250c, and the insulator 275 preferably has a single-layer structure or a stacked-layer structure of the barrier insulator against oxygen.

The insulator 250a preferably has a barrier property against oxygen. Oxygen is less likely to pass through the insulator 250a than at least the insulator 280. The insulator 250a includes a region in contact with the side surface of the conductor 242a and the side surface of the conductor 242b. When the insulator 250a has a barrier property against oxygen, oxidation of the side surfaces of the conductor 242a and the conductor 242b and formation of oxide films on the side surfaces can be inhibited. Accordingly, a decrease in the on-state current or field-effect mobility of the transistor 201a can be inhibited.

The insulator 250a is provided in contact with the top surface and the side surface of the oxide 230b, the side surface of the oxide 230a, the side surface of the insulator 224, and the top surface of the insulator 222. When the insulator 250a has a barrier property against oxygen, release of oxygen from the region 230bc of the oxide 230b caused by heat treatment or the like can be inhibited. This can reduce formation of oxygen vacancies in the oxide 230a and the oxide 230b.

Even when an excess amount of oxygen is included in the insulator 280, in contrast, oxygen can be inhibited from being excessively supplied to the oxide 230a and the oxide 230b. Thus, it is possible to inhibit excessive oxidation of the region 230ba and the region 230bb and a decrease in the on-state current or field-effect mobility of the transistor 201a.

The oxide including one or both of aluminum and hafnium has a barrier property against oxygen and thus can be suitably used for the insulator 250a.

The insulator 250c preferably has a barrier property against oxygen. The insulator 250c is provided between the conductor 260 and the region 230bc of the oxide 230 and between the insulator 280 and the conductor 260. Such a structure can inhibit diffusion of oxygen included in the region 230bc of the oxide 230 into the conductor 260 and formation of oxygen vacancies in the region 230bc of the oxide 230. Oxygen included in the oxide 230 and oxygen included in the insulator 280 can be inhibited from diffusing into the conductor 260 and oxidizing the conductor 260. Oxygen is less likely to pass through the insulator 250c than at least the insulator 280. For example, silicon nitride is preferably used for the insulator 250c. In this case, the insulator 250c is an insulator that includes at least nitrogen and silicon.

The insulator 250c preferably has a barrier property against hydrogen. Accordingly, diffusion of impurities included in the conductor 260, such as hydrogen, into the oxide 230b can be prevented.

The insulator 275 preferably has a barrier property against oxygen. The insulator 275 is provided between the insulator 280 and the conductor 242a and between the insulator 280 and the conductor 242b. With this structure, oxygen included in the insulator 280 can be inhibited from diffusing into the conductor 242a and the conductor 242b. Thus, the conductor 242a and the conductor 242b can be inhibited from being oxidized by oxygen included in the insulator 280, so that an increase in resistivity and a reduction in on-state current can be inhibited. Oxygen is less likely to pass through the insulator 275 than at least the insulator 280. For example, silicon nitride is preferably used for the insulator 275. In this case, the insulator 275 is an insulator that includes at least nitrogen and silicon.

In order to inhibit a reduction in hydrogen concentration in the region 230ba and the region 230bb in the oxide 230, a barrier insulator against hydrogen is preferably provided in the vicinity of each of the region 230ba and the region 230bb. In the semiconductor device described in this embodiment, the barrier insulator against hydrogen is, for example, the insulator 275.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the above barrier insulator against hydrogen.

The insulator 275 preferably has a barrier property against hydrogen. When the insulator 275 has a barrier property against hydrogen, capturing and fixing of hydrogen in the region 230ba and the region 230bb by the insulator 250 can be inhibited. Thus, the region 230ba and the region 230bb can be n-type regions.

With the above structure, the region 230bc can be an i-type or substantially i-type region, and the region 230ba and the region 230bb can be n-type regions. Thus, a semiconductor device with favorable electrical characteristics can be provided. The semiconductor device with the above structure can have favorable electrical characteristics even when miniaturized or highly integrated. Miniaturization of the transistor 201a can improve the high frequency characteristics. Specifically, the cutoff frequency can be improved.

The insulator 250a to the insulator 250c function as part of the first gate insulator. The insulator 250a to the insulator 250c are provided in an opening formed in the insulator 280 and the like, together with the conductor 260. The thicknesses of the insulator 250a to the insulator 250c are each preferably small for miniaturization of the transistor 201a. The thicknesses of the insulator 250a to the insulator 250c are each preferably greater than or equal to 0.1 nm and less than or equal to 10 nm, further preferably greater than or equal to 0.1 nm and less than or equal to 5.0 nm, still further preferably greater than or equal to 0.5 nm and less than 5.0 nm, yet further preferably greater than or equal to 1.0 nm and less than or equal to 5.0 nm, yet still further preferably greater than or equal to 1.0 nm and less than or equal to 3.0 nm. Note that each of the insulator 250a to the insulator 250c at least partly includes a region having the above-described thickness.

To form the insulator 250a to the insulator 250c each having a small thickness as described above, an atomic layer deposition (ALD) method is preferably used for film formation.

Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because film formation at a lower temperature is possible.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Thus, the insulator 250 can be formed on the side surface of the opening portion formed in the insulator 280 and the like, the side end portions of the conductors 242a and 242b, and the like, with a small thickness like the above-described thickness and favorable coverage.

Note that some of precursors usable in an ALD method include carbon or the like. Thus, in some cases, a film provided by an ALD method includes impurities such as carbon in a larger amount than a film provided by another film formation method. Note that impurities can be quantified by secondary ion mass spectrometry (SIMS), X-ray photoelectron spectroscopy (XPS), or auger electron spectroscopy (AES).

Although the structure in which the insulator 250 has a three-layer structure of the insulator 250a to the insulator 250c is described above, the present invention is not limited thereto. The insulator 250 can include at least one of the insulator 250a to the insulator 250c. When the insulator 250 is formed of one or two of the insulator 250a to the insulator 250c, the manufacturing process of the semiconductor device can be simplified, and the productivity can be improved.

In addition to the above structure, the semiconductor device of this embodiment preferably has a structure in which hydrogen is inhibited from entering the transistors 201a and 202a and the like. For example, one or both of upper and lower insulators having a function of inhibiting diffusion of hydrogen is/are preferably provided to cover the transistors 201a and 202a and the like. In the semiconductor device described in this embodiment, the insulator corresponds to the insulator 212, the insulator 214, the insulator 282, the insulator 283, and the insulator 286, for example.

One or more of the insulator 212, the insulator 214, the insulator 282, the insulator 283, the insulator 286, and the insulator 287 preferably function as a barrier insulator, which inhibits diffusion of impurities such as water and hydrogen into the transistors 201a and 202a and the like from the substrate side or from above the transistor 201a and 202a and the like. Thus, one or more of the insulator 212, the insulator 214, the insulator 282, and the insulator 286 preferably include an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (an insulating material through which the impurities are less likely to pass). Alternatively, it is preferable to include an insulating material having a function of inhibiting diffusion of oxygen (e.g., at least one of an oxygen atom, an oxygen molecule, and the like) (an insulating material through which the oxygen is less likely to pass).

The insulator 212, the insulator 214, the insulator 282, the insulator 283, the insulator 286, and the insulator 287 each preferably include an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride or the like, which has a higher hydrogen barrier property, is preferably used for the insulator 212, the insulator 283, and the insulator 287. For example, the insulator 214, the insulator 282, and the insulator 286 each preferably include aluminum oxide, magnesium oxide, or the like, which has a function of capturing and fixing hydrogen well. In this case, impurities such as water and hydrogen can be inhibited from diffusing into the transistors 201a and 202a and the like from the substrate side through the insulator 212 and the insulator 214. Alternatively, impurities such as water and hydrogen can be inhibited from diffusing into the transistors 201a and 202a and the like from an interlayer insulating film and the like which are placed outside the insulator 283 or the insulator 287. Alternatively, oxygen included in the insulator 224 and the like can be inhibited from diffusing to the substrate side. Alternatively, oxygen included in the insulator 280 and the like can be inhibited from diffusing to above the transistors 201a and 202a and the like through the insulator 282 and the like. In this manner, it is preferable that the transistors 201a and 202a and the like be surrounded by upper and lower insulators having a function of inhibiting diffusion of oxygen and impurities such as water and hydrogen.

In the transistors 201a and 201b, the conductor 261 is placed to overlap with the oxide 230 and the conductor 260. Here, the conductor 261 is preferably provided to fill an opening portion formed in the insulator 284. As illustrated in FIG. 3B, the conductor 261 is preferably provided to extend in the channel width direction (the Y direction illustrated in FIG. 3B). With this structure, the conductor 261 functions as a wiring and functions as a second gate electrode of a plurality of transistors arranged in the Y direction.

The conductor 261 may have a single-layer structure or a stacked-layer structure. In FIG. 1 or the like, the conductor 261 includes the conductor 261a and the conductor 261b. The conductor 261a is provided in contact with the bottom surface and the sidewall of the opening portion. The conductor 261b is provided in contact with the top surface of the conductor 261a and a sidewall of the opening portion. Here, the top surface of the conductor 261b is substantially level with the top surface of the insulator 284.

Here, the conductor 261a preferably includes a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to include a conductive material having a function of inhibiting diffusion of oxygen (e.g., at least one of an oxygen atom, an oxygen molecule, and the like).

When a conductive material having a function of inhibiting diffusion of hydrogen is used for the conductor 261a, impurities such as hydrogen included in the conductor 261b can be prevented from diffusing into the oxide 230 through the insulator 284, and the like. When a conductive material having a function of inhibiting diffusion of oxygen is used for the conductor 261a, the conductivity of the conductor 261b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 261a can have a single-layer structure or a stacked-layer structure of the above conductive material. For example, the conductor 261a preferably includes titanium nitride.

A conductive material including tungsten, copper, or aluminum as its main component is preferably used for the conductor 261b. For example, the conductor 261b preferably includes tungsten.

The conductor 261 can function as the second gate electrode. In that case, by changing a potential applied to the conductor 261 not in conjunction with but independently of a potential applied to the conductor 260, the threshold voltage (V′th) of the transistor 201a can be controlled. In particular, by applying a negative potential to the conductor 261, V′th of the transistor 201a can be higher, and its off-state current can be reduced. Thus, drain current at the time when a potential applied to the conductor 260 is 0 V can be lower in the case where a negative potential is applied to the conductor 261 than in the case where the negative potential is not applied to the conductor 261.

The electrical resistivity of the conductor 261 is designed in consideration of the potential applied to the conductor 261, and the thickness of the conductor 261 is set in accordance with the electrical resistivity. The thickness of the insulator 284 is substantially equal to that of the conductor 261. Here, the conductor 261 and the insulator 284 are preferably as thin as possible in the allowable range of the design of the conductor 261. When the thickness of the insulator 284 is reduced, the absolute amount of impurities such as hydrogen included in the insulator 284 can be reduced, thereby suppressing diffusion of the impurities into the oxide 230.

Since the conductor 261 is formed in the same layer as the conductor 160 as described above, the conductor 261a and the conductor 261b can have the same structure as the conductor 160a and the conductor 160b, respectively. In this case, the insulator 263 having the same structure as the insulator 154 is provided in contact with the bottom surface of the conductor 261.

Note that in the transistors 202a and 202b, the conductor 205 is placed to overlap with the oxide 230 and the conductor 260. Here, the conductor 205 is preferably provided to fill an opening portion formed in the insulator 216. Part of the conductor 205 is embedded in the insulator 214 in some cases. The conductor 205 includes the conductor 205a and the conductor 205b over the conductor 205a. The conductor 205 has a structure similar to that of the conductor 261, the conductor 205a has a structure similar to that of the conductor 261a, and the conductor 205b has a structure similar to that of the conductor 261b.

Note that the upper electrode of the capacitor does not need to be provided in the same layer as the conductor 205; thus, unlike the conductor 261, the conductor 205 does not need to be provided with an insulator similar to the insulator 154. Thus, the bottom surface of the conductor 205 is in contact with the insulator 214. The conductor 205 can also be formed in the following manner: a conductive film is formed to fill the opening provided in the insulator 216, and an upper portion of the conductive film is removed. In this case, the conductor 205a is provided in contact with the bottom surface and the side surface of the conductor 205b.

The insulator 222 and the insulator 224 function as the second gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

The insulator 222 preferably includes an insulator including an oxide of one or both of aluminum and hafnium, which is an insulating material. For the insulator, aluminum oxide, hafnium oxide, an oxide including aluminum and hafnium (hafnium aluminate), or the like is preferably used. Alternatively, an oxide including hafnium and zirconium, e.g., a hafnium zirconium oxide, is preferably used. In the case where the insulator 222 is formed using such a material, the insulator 222 functions as a layer that inhibits release of oxygen from the oxide 230 to the substrate side and diffusion of impurities such as hydrogen from the periphery of the transistors 201a and 202a into the oxide 230. Thus, providing the insulator 222 can inhibit diffusion of impurities such as hydrogen to the inside of the transistors 201a and 202a and inhibit generation of oxygen vacancies in the oxide 230. Moreover, the conductor 205 or the conductor 160 can be inhibited from reacting with oxygen included in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulators, for example. Alternatively, these insulators may be subjected to nitriding treatment. A stack of silicon oxide, silicon oxynitride, or silicon nitride over the above insulators may be used for the insulator 222.

For example, the insulator 222 may have a single-layer structure or a stacked-layer structure of an insulator(s) including what is called a high-k material such as aluminum oxide, hafnium oxide, tantalum oxide, zirconium oxide, or hafnium zirconium oxide. As miniaturization and high integration of the transistors progress, the second gate insulator becomes thinner, and thus, a problem such as leakage current may arise. When a high-k material is used for the insulator functioning as the second gate insulator, a gate potential at the time of the operation of the transistor can be reduced while the physical thickness is maintained. Furthermore, a substance with a high dielectric constant such as lead zirconate titanate (PZT), strontium titanate (SrTiO₃), or (Ba,Sr)TiO₃ (BST) can be used for the insulator 222 in some cases.

The insulator 224 that is in contact with the oxide 230 preferably includes silicon oxide or silicon oxynitride, for example.

Note that the insulator 222 and the insulator 224 may each have a stacked-layer structure of two or more layers. In that case, without limitation to a stacked-layer structure formed of the same material, a stacked-layer structure formed of different materials may be employed.

A conductive material that is less likely to be oxidized or a conductive material having a function of inhibiting diffusion of oxygen is preferably used for each of the conductor 242a, the conductor 242b, and the conductor 260. Examples of the conductive material include a conductive material including nitrogen and a conductive material including oxygen. This can inhibit a reduction in the conductivity of the conductor 242a, the conductor 242b, and the conductor 260. In the case where a conductive material including metal and nitrogen is used for the conductor 242a, the conductor 242b, and the conductor 260, the conductor 242a, the conductor 242b, and the conductor 260 are conductors that include at least metal and nitrogen.

The conductors 242a and 242b may have a single-layer structure or a stacked-layer structure. The conductor 260 may have a single-layer structure or a stacked-layer structure.

In FIG. 2A, the conductors 242a and 242b each have a two-layer structure. The conductor 242a is a stacked film of the conductor 242al and the conductor 242a2 over the conductor 242al, and the conductor 242b is a stacked film of the conductor 242b1 and the conductor 242b2 over the conductor 242b1. In this case, a conductive material that is less likely to be oxidized or a conductive material having a function of inhibiting diffusion of oxygen is preferably used for the layer (the conductor 242al and the conductor 242b1) in contact with the oxide 230b. This can inhibit a reduction in the conductivity of the conductors 242a and 242b. For the layer (the conductors 242al and 242b1) in contact with the oxide 230b, a material that is likely to absorb (extract) hydrogen is preferably used, in which case the hydrogen concentration in the oxide 230 can be reduced.

As the conductors 242al and 242b1, a metal nitride is preferably used; for example, a nitride including tantalum, a nitride including titanium, a nitride including molybdenum, a nitride including tungsten, a nitride including tantalum and aluminum, or a nitride including titanium and aluminum is preferably used. In one embodiment of the present invention, a nitride including tantalum is particularly preferable. As another example, ruthenium oxide, ruthenium nitride, an oxide including strontium and ruthenium, or an oxide including lanthanum and nickel may be used. These materials are preferable because they are each a conductive material that is less likely to be oxidized or a material that maintains the conductivity even after absorbing oxygen.

Note that hydrogen included in the oxide 230b or the like diffuses into the conductor 242al or the conductor 242b1 in some cases. In particular, when a nitride including tantalum is used for the conductor 242al and the conductor 242b1, hydrogen included in the oxide 230b or the like is likely to diffuse into the conductor 242al or the conductor 242b1, and the diffused hydrogen is bonded to nitrogen included in the conductor 242al or the conductor 242b1 in some cases. That is, hydrogen included in the oxide 230b or the like is absorbed by the conductor 242a 1 or the conductor 242b1 in some cases.

The conductor 242a2 and the conductor 242b2 preferably have a higher conductivity than the conductor 242al and the conductor 242b1. For example, the thicknesses of the conductor 242a2 and the conductor 242b2 are preferably larger than those of the conductor 242al and the conductor 242b1. As the conductor 242a2 and the conductor 242b2, a conductor that can be used as the conductor 261b is used. With the above structure, the contact resistance between the conductor 242a2 and the conductor 240 and the contact resistance between the conductor 242b2 and the conductor 153 can be reduced. Accordingly, the operating speed of the semiconductor device of this embodiment can be improved.

For example, tantalum nitride or titanium nitride can be used for the conductor 242a1 and the conductor 242b1, and tungsten can be used for the conductor 242a2 and the conductor 242b2.

To inhibit a reduction in the conductivity of the conductors 242a and 242b, an oxide having crystallinity, such as a CAAC-OS, is preferably used as the oxide 230b. Specifically, a metal oxide including indium, zinc, and one or more selected from gallium, aluminum, and tin is preferably used. When a CAAC-OS is used, oxygen extraction from the oxide 230b by the conductor 242a or the conductor 242b can be inhibited. Furthermore, it is possible to inhibit a reduction in the conductivity of the conductor 242a and the conductor 242b.

The insulator 271a and the insulator 271b are inorganic insulators functioning as etching stoppers in the processing into the conductor 242a and the conductor 242b. The insulator 271a is in contact with the top surface of the conductor 242a and the bottom surface of the insulator 275, and the insulator 271b is in contact with the top surface of the conductor 242b and the bottom surface of the insulator 275. As the insulator 271a and the insulator 271b, one or more of insulators that can be used as the insulator 250a to the insulator 250c can be used. For example, the insulator 271a and the insulator 271b can each be a stacked film of a silicon nitride film and a silicon oxide film over the silicon nitride film.

As illustrated in FIG. 3A and FIG. 3B, the conductor 260 is provided in an opening formed in an insulator that forms the insulator 280, the insulator 275, the insulator 271a, and the insulator 271b, a conductor that forms the conductor 242a and the conductor 242b, the oxide 230, and the insulator 224. The conductor 260 is provided in the opening to cover the side surface of the insulator 224, the side surface of the oxide 230a, the side surface of the oxide 230b, and the top surface of the oxide 230b with the insulator 250 therebetween. Furthermore, the top surface of the conductor 260 is provided to be substantially level with the uppermost portion of the insulator 250 and the top surface of the insulator 280.

Note that in the opening portion which is provided in the insulator 280 and the like and in which the conductor 260 and the insulator 250 are provided, the sidewall of the opening portion may be substantially perpendicular to the top surface of the insulator 222 or may have a tapered shape. The tapered shape of the sidewall can improve the coverage with the insulator 250 and the like provided in the opening portion in the insulator 280; as a result, the number of defects such as voids can be reduced.

The conductor 260 functions as the first gate electrode of the transistor 201a. Here, as illustrated in FIG. 3B, the conductor 260 is preferably provided to extend in the channel width direction (the Y direction illustrated in FIG. 3B). With such a structure, the conductor 261 functions as a wiring and functions as the first gate electrode in a plurality of transistors arranged in the Y direction.

In the case of the above structure, a curved surface may be provided between the side surface of the oxide 230b and the top surface of the oxide 230b in a cross-sectional view of the transistor 201a in the channel width direction as illustrated in FIG. 3B. That is, an end portion of the side surface and an end portion of the top surface may be curved (hereinafter, also referred to as rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 250 and the conductor 260.

Note that in this specification and the like, a transistor structure in which a channel formation region is electrically surrounded by an electric field of at least a first gate electrode is referred to as a surrounded channel (S-channel) structure. The S-channel structure disclosed in this specification and the like is different from a Fin-type structure and a planar structure. Meanwhile, the S-channel structure disclosed in this specification and the like can be regarded as a kind of Fin-type structure. Note that in this specification and the like, a Fin-type structure refers to a structure in which a gate electrode is provided to cover at least two surfaces (specifically, two surfaces, three surfaces, or four surfaces, for example) of a channel. With the Fin structure or the S-channel structure, resistance to a short-channel effect can be enhanced, that is, a transistor in which a short-channel effect is less likely to occur can be provided.

When the transistor 201a has the above S-channel structure, the channel formation region can be electrically surrounded. Since the channel formation region is electrically surrounded, the S-channel structure can be said to be substantially the same structure as a GAA (Gate All Around) structure or an LGAA (Lateral Gate All Around) structure. When the transistor 201a has the S-channel structure, the GAA structure, or the LGAA structure, the channel formation region that would be formed at the interface between the oxide 230 and the gate insulator or in the vicinity of the interface can be formed in the entire bulk of the oxide 230. Accordingly, the density of current flowing through the transistor can be improved, so that it can be expected that the on-state current of the transistor or the field-effect mobility of the transistor is increased.

Although the transistor having the S-channel structure is described as an example of the transistor 201a illustrated in FIG. 3B, the semiconductor device of one embodiment of the present invention is not limited thereto. For example, the transistor structure that can be used in one embodiment of the present invention may be any one or more selected from a planar structure, a Fin-type structure, and a GAA structure.

FIG. 2 illustrates the conductor 260 as having a two-layer structure. Here, the conductor 260 preferably includes the conductor 260a and the conductor 260b placed over the conductor 260a. For example, the conductor 260a is preferably placed to cover the bottom surface and the side surface of the conductor 260b. In this case, a conductive material that is less likely to be oxidized or a conductive material having a function of inhibiting diffusion of oxygen is preferably used for the conductor 260a.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen included in the insulator 280 or the like. As the conductive material having a function of inhibiting diffusion of oxygen, for example, titanium, titanium nitride, tantalum, tantalum nitride, ruthenium, or ruthenium oxide is preferably used.

As the conductor 260b, a conductor having high conductivity is preferably used. For example, a conductive material including tungsten, copper, or aluminum as its main component can be used for the conductor 260b. The conductor 260b may have a stacked-layer structure; for example, a stacked-layer structure of the conductive material and titanium or titanium nitride may be employed.

In the transistor 201a, the conductor 260 is formed in a self-aligned manner to fill the opening formed in the insulator 280 and the like. The formation of the conductor 260 in this manner allows the conductor 260 to be placed properly in a region between the conductor 242a and the conductor 242b without alignment.

The insulator 216, the insulator 280, the insulator 285, and the insulator 284 each preferably have a lower dielectric constant than the insulator 214. When a material with a low dielectric constant is used for an interlayer film, parasitic capacitance generated between wirings can be reduced.

For example, the insulator 216, the insulator 280, the insulator 285, and the insulator 284 each preferably include one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region including oxygen that is released by heating can be easily formed.

The top surfaces of the insulator 216, the insulator 280, the insulator 285, and the insulator 284 may be planarized.

The concentration of impurities such as water and hydrogen in the insulator 280 is preferably reduced. For example, the insulator 280 preferably includes an oxide including silicon such as silicon oxide, silicon oxynitride, or the like.

Each of the conductor 153 and the conductor 160 included in the capacitor 101a can be formed with any of a variety of conductors that can be used for the conductor 205, the conductor 242, and the conductor 260. The conductor 153 and the conductor 160 are preferably formed by a film formation method that offers excellent coverage, such as an ALD method or a CVD method. A film of titanium nitride or tantalum nitride formed by an ALD method or a CVD method can be used for the conductor 153, for example.

The top surface of the conductor 242b2 is in contact with the bottom surface of the conductor 153. Here, when a conductive material having excellent conductivity is used for the conductor 242b2, the contact resistance between the conductor 153 and the conductor 242b can be reduced.

For example, a titanium nitride film formed by an ALD method or a CVD method can be used for the conductor 160a, and a tungsten film formed by a CVD method can be used for the conductor 160b. Note that in the case where the adhesion of tungsten to the insulator 154 is sufficiently high, a single-layer structure of a tungsten film formed by a CVD method may be used for the conductor 160.

For the insulator 154 included in the capacitor 101a, a high dielectric constant (high-k) material (a material with a high relative dielectric constant) is preferably used. The insulator 154 is preferably formed by a film formation method that offers excellent coverage, such as an ALD method or a CVD method.

Examples of insulators of the high dielectric constant (high-k) material include an oxide, an oxynitride, a nitride oxide, and a nitride including one or more kinds of metal elements selected from aluminum, hafnium, zirconium, gallium, and the like. The above oxide, oxynitride, nitride oxide, and nitride may include silicon. Stacked insulators formed of any of the above materials can also be used.

Examples of the insulators of the high dielectric constant (high-k) material include aluminum oxide, hafnium oxide, zirconium oxide, an oxide including aluminum and hafnium, an oxynitride including aluminum and hafnium, an oxide including silicon and hafnium, an oxynitride including silicon and hafnium, an oxide including silicon and zirconium, an oxynitride including silicon and zirconium, an oxide including hafnium and zirconium, and an oxynitride including hafnium and zirconium. Using such a high-k material allows the insulator 154 to be thick enough to inhibit leakage current and the capacitor 101a to have a sufficiently high capacitance.

It is preferable to use stacked insulators formed of any of the above materials, and it is preferable to use a stacked-layer structure of a high dielectric constant (high-k) material and a material having a higher dielectric strength than the high dielectric constant (high-k) material. As the insulator 154, an insulator in which zirconium oxide, aluminum oxide, and zirconium oxide are stacked in this order can be used, for example. As another example, an insulator in which zirconium oxide, aluminum oxide, zirconium oxide, and aluminum oxide are stacked in this order can be used. As another example, an insulator in which hafnium zirconium oxide, aluminum oxide, hafnium zirconium oxide, and aluminum oxide are stacked in this order can be used. Using such stacked insulators with relatively high dielectric strength, such as aluminum oxide, can increase the dielectric strength and inhibit electrostatic breakdown of the capacitor 101a.

The deeper the opening provided in the insulator 271b, the insulator 275, the insulator 280, the insulator 282, the insulator 283, and the insulator 285 is (i.e., the larger the thickness of one or more of the insulator 271b, the insulator 275, the insulator 280, the insulator 282, the insulator 283, and the insulator 285 is), the larger the capacitance of the capacitor 101a can be. Here, since the insulator 271b, the insulator 275, the insulator 282, and the insulator 283 function as barrier insulators, their thicknesses are preferably set in accordance with a barrier property required for the semiconductor device. Since the thickness of the conductor 260 functioning as the gate electrode is set in accordance with the thickness of the insulator 280, the thickness of the insulator 280 is preferably determined in accordance with the thickness of the conductor 260 required for the semiconductor device.

Thus, the capacitance of the capacitor 101a is preferably set by adjusting the thickness of the insulator 285. For example, the thickness of the insulator 285 is set to be greater than or equal to 50 nm and less than or equal to 250 nm, and the depth of the opening is approximately greater than or equal to 150 nm and less than or equal to 350 nm. When the capacitor 101a is formed within such ranges, sufficient capacitance can be provided for the capacitor 101a, and the level of one layer in a semiconductor device where a plurality of layers of memory cells are stacked can be prevented from being excessively high. Note that the capacitance of the capacitors provided in each memory cell may differ between the plurality of layers of memory cells. In the case of this structure, the thickness of the insulator 285 provided in each of the layers of the memory cells differs depending on the layer, for example.

Note that in the opening portion which is provided in the insulator 285 and the like and in which the capacitor 101a is placed, the sidewall of the opening portion may be substantially perpendicular to the top surface of the insulator 222 or may have a tapered shape. The tapered shape of the sidewall can improve the coverage with the insulator 153 and the like provided in the opening portion in the insulator 285 and the like; as a result, the number of defects such as voids can be reduced.

The conductor 240 is provided in an opening formed in the insulator 284, the insulator 222, the insulator 275, the insulator 280, the insulator 282, the insulator 283, and the insulator 285. Note that as for the opening in which the conductor 240_1 is formed, the opening is formed also in the insulator 212, the insulator 214, and the insulator 216. Furthermore, the conductor 240 is in contact with the top surface and the side end portion of the conductor 242a and the top surface of the conductor 240 in the lower layer. Note that the conductor 240_1 is in contact with the top surface of the conductor 209.

The conductor 240 functions as a plug or a wiring for electrically connecting the transistors 201a and 202a to a circuit element such as a switch, a transistor, a capacitor, an inductor, a resistor, or a diode, a wiring, an electrode, or a terminal.

For example, in the memory device described in Embodiment 2, the conductor 240 functions as a write and read bit line.

The conductor 240 preferably has a stacked-layer structure of the conductor 240a and the conductor 240b. For example, as illustrated in FIG. 4A and FIG. 4B, the conductor 240_2 can have a structure in which the conductor 240a2 is provided in contact with the inner wall of the opening portion and the conductor 240b2 is provided inside the conductor 240a2. That is, the conductor 240a2 is placed closer to the insulator 222, the insulator 275, the insulator 280, the insulator 282, the insulator 283, the insulator 285, and the insulator 284 than the conductor 240b2 is. The conductor 240a2 is in contact with the top surface and the side end portion of the conductor 242a.

A conductive material having a function of inhibiting passage of impurities such as water and hydrogen is preferably used for the conductor 240a. The conductor 240a can have a single-layer structure or a stacked-layer structure including one or more of tantalum, tantalum nitride, titanium, titanium nitride, ruthenium, and ruthenium oxide, for example. Thus, impurities such as water and hydrogen can be inhibited from entering the oxide 230 through the conductor 240.

The conductor 240 also functions as a wiring and thus is preferably formed using a conductor having high conductivity. For example, a conductive material including tungsten, copper, or aluminum as its main component can be used for the conductor 240b.

For example, it is preferable to use titanium nitride for the conductor 240a and tungsten for the conductor 240b. In that case, the conductor 240a is a conductor that includes titanium and nitrogen, and the conductor 240b is a conductor that includes tungsten.

Note that the conductor 240 may have a single-layer structure or a stacked-layer structure of three or more layers.

As illustrated in FIG. 2A, the insulator 241 is preferably provided in contact with the side surface of the conductor 240. Specifically, the insulator 241 is provided in contact with the inner wall of the opening in the insulator 284, the insulator 222, the insulator 275, the insulator 280, the insulator 282, the insulator 283, the insulator 285, the insulator 216, the insulator 214, and the insulator 212. The insulator 241 is formed also on the side surfaces of the insulator 224, the oxide 230, and the conductor 242a that protrude in the opening. Here, at least part of the conductor 242a is exposed from the insulator 241 and in contact with the conductor 240. That is, the conductor 240 is provided to fill the opening with the insulator 241 therebetween.

Note that as illustrated in FIG. 4A, the uppermost portion of the insulator 241 formed below the conductor 242a is preferably positioned below the top surface of the conductor 242a. With this structure, the conductor 240 can be in contact with at least part of the side end portion of the conductor 242a. Note that the insulator 241 formed below the conductor 242a preferably includes a region in contact with the side surface of the oxide 230. With this structure, impurities such as water and hydrogen included in the insulator 280 and the like can be inhibited from entering the oxide 230 through the conductor 240.

As the insulator 241, a barrier insulating film that can be used as the insulator 275 or the like is used. For example, an insulator such as silicon nitride, aluminum oxide, or silicon nitride oxide is used for the insulator 241. With this structure, impurities such as water and hydrogen included in the insulator 280 and the like can be inhibited from entering the oxide 230 through the conductor 240. In particular, silicon nitride is suitable because of its high blocking property against hydrogen. Furthermore, oxygen included in the insulator 280 can be inhibited from being absorbed by the conductor 240.

Although FIG. 2A illustrates the structure in which the insulator 241 is a single layer, the present invention is not limited thereto. The insulator 241 may have a stacked-layer structure of two or more layers.

For example, in FIG. 4A and FIG. 4B, the insulator 241 has a two-layer structure of an insulator 241a and an insulator 241b over the insulator 241a.

In the case where the insulator 241 has the two-layer structure as illustrated in FIG. 4A and FIG. 4B, the insulator 241a in contact with the inner wall of the opening in the insulator 280 and the like and the insulator 241b inside the insulator 241a are preferably formed using a combination of a barrier insulating film against oxygen and a barrier insulating film against hydrogen. For example, an aluminum oxide film formed by an ALD method is used as the insulator 241a, and a silicon nitride film formed by a PEALD method is used as the insulator 241b. With this structure, oxidation of the conductor 240 can be inhibited, and hydrogen can be inhibited from entering the oxide 230 and the like from the conductor 240.

Note that in the opening portion where the conductor 240 and the insulator 241 are provided, the sidewall of the opening portion may be substantially perpendicular to the top surface of the insulator 222 or may have a tapered shape. When the sidewall has a tapered shape, coverage with the insulator 241 and the like provided in the opening portion can be improved.

### <Cross-Sectional Structure Example 2 of Semiconductor Device>

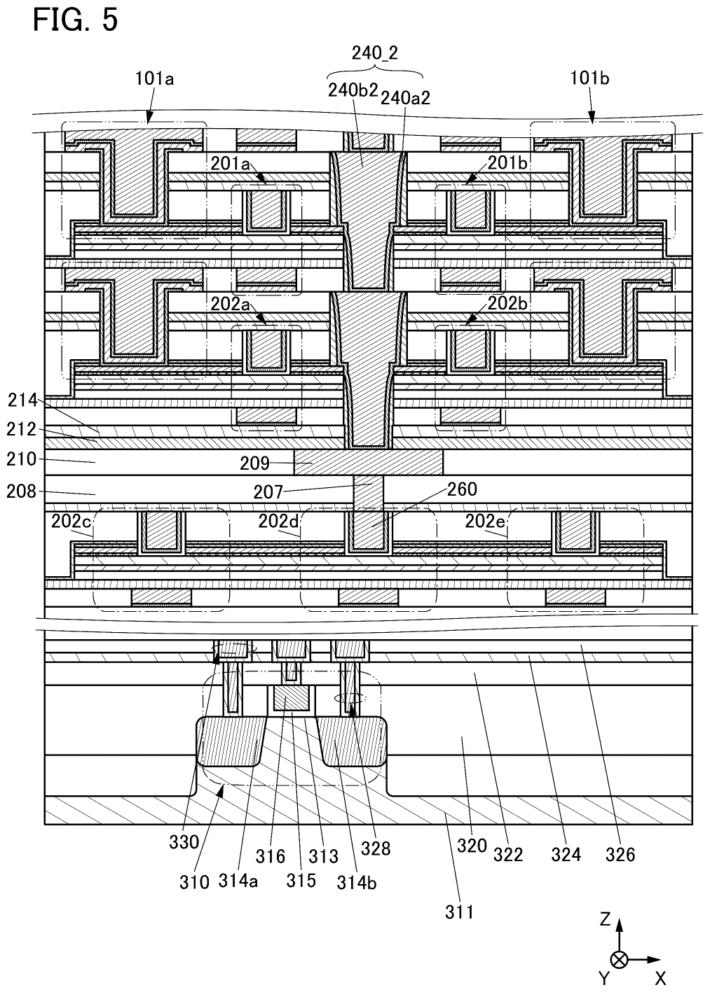

A cross-sectional structure example of the semiconductor device of one embodiment of the present invention is described with reference to FIG. 5.

In the semiconductor device illustrated in FIG. 5, a layer including a transistor 202c to a transistor 202e and the like (corresponding to a functional layer 50 described in Embodiment 2) is provided over a layer including a transistor 310 and the like (corresponding to a driver circuit 21 described in Embodiment 2), and a stacked-layer structure similar to the stacked-layer structure illustrated in FIG. 1 (corresponding to a plurality of memory cells 10 included in memory arrays 20 described in Embodiment 2) is further provided thereover. A structure above the insulator 210 in FIG. 5 is similar to that in FIG. 1 and thus is not described in detail.

FIG. 5 illustrates an example of the transistor 310 included in the driver circuit 21 described in Embodiment 2. The transistor 310 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 310 may be a p-channel transistor or an n-channel transistor. As the substrate 311, a single crystal silicon substrate can be used, for example.

Here, in the transistor 310 illustrated in FIG. 5, the semiconductor region 313 (part of the substrate 311) in which a channel is formed has a projecting shape. The conductor 316 is provided to cover the side surface and the top surface of the semiconductor region 313 with the insulator 315 therebetween. Note that a material for adjusting the work function may be used for the conductor 316. Such a transistor 310 is also referred to as a FIN-type transistor because it utilizes a projecting portion of a semiconductor substrate. Note that an insulator functioning as a mask for forming the projecting portion may be included in contact with an upper portion of the projecting portion. Furthermore, although the case where the projecting portion is formed by processing part of the semiconductor substrate is described here, a semiconductor film having a projecting shape may be formed by processing an SOI (Silicon on Insulator) substrate.

Note that the transistor 310 illustrated in FIG. 5 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are sequentially provided in stacked layers over the transistor 310 as interlayer films. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as interlayer films may also function as planarization films that cover uneven shapes therebelow. For example, the top surface of the insulator 322 may be planarized by planarization treatment using a chemical mechanical polishing (CMP) method or the like to have improved planarity.

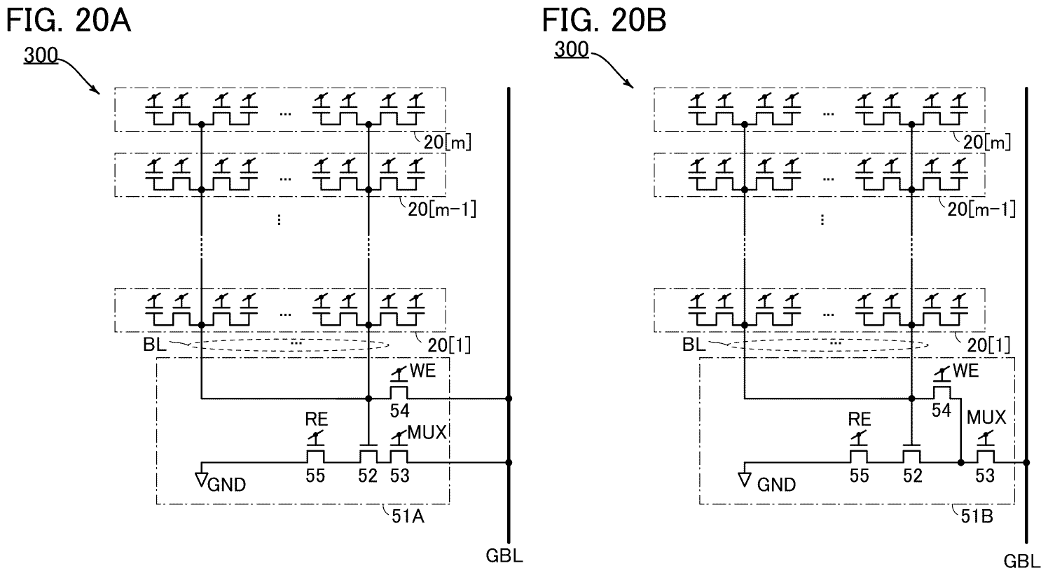

FIG. 5 also illustrates an example of the transistors 202c, 202d, and 202e included in the functional layer 50 described in Embodiment 2. The transistors 202c, 202d, and 202e have a structure similar to that of the transistors 202a and 202b included in the memory cells 10. The transistors 202c, 202d, and 202e correspond to transistors 52, 53, and 55 illustrated in FIG. 20A or the like. Like the transistors 52, 53, and 55, the transistors 202c, 202d, and 202e have their sources and drains connected in series.

An insulator 208 is provided over the transistors 202c, 202d, and 202e, and a conductor 207 is provided in an opening formed in the insulator 208. An insulator similar to the insulator 210 can be provided as the insulator 208, and a conductor similar to the conductor 209 can be provided as the conductor 207.

The bottom surface of the conductor 207 is provided in contact with the top surface of a conductor 260 of the transistor 202d. The top surface of the conductor 207 is provided in contact with the bottom surface of the conductor 209. With such a structure, the conductor 240 corresponding to a wiring BL functioning as a bit line can be electrically connected to a gate of the transistor 202c corresponding to the transistor 52.

### <Top-Surface Structure Example of Semiconductor Device>

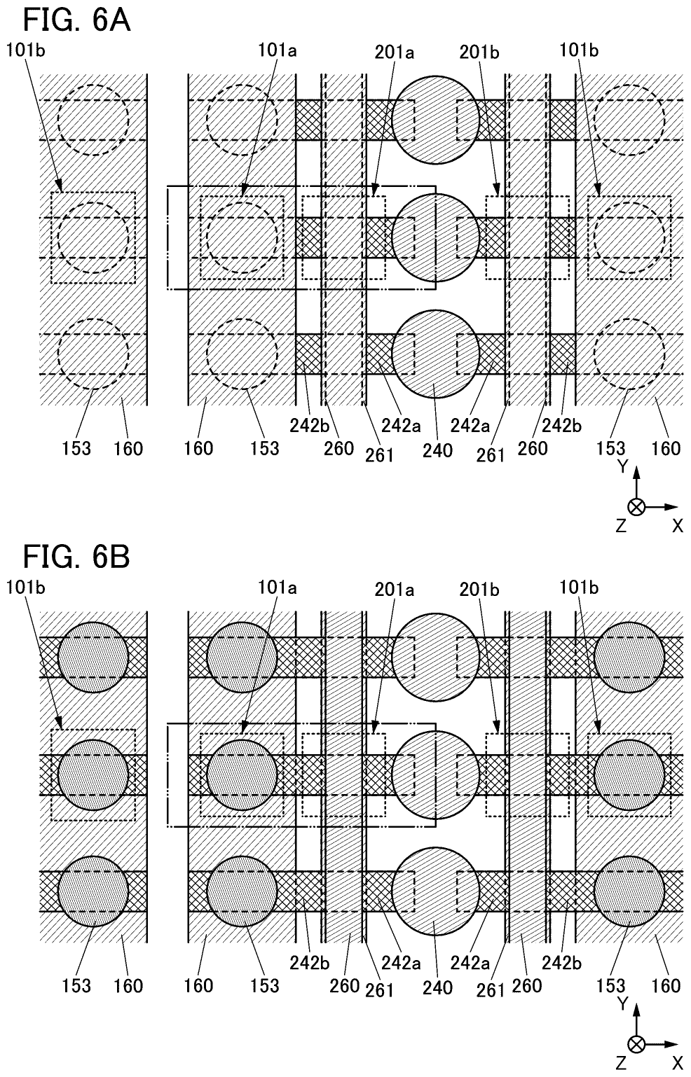

Top-surface structure examples of the semiconductor device of one embodiment of the present invention are described with reference to FIG. 6A and FIG. 6B.

Note that in FIG. 6A and FIG. 6B, the X direction is parallel to the channel length direction of illustrated transistors, the Y direction is parallel to the channel width direction of the illustrated transistors, and the Z direction is perpendicular to the X direction and the Y direction. Note that some components such as insulators are not illustrated in FIG. 6A and FIG. 6B for simplicity. A frame surrounded by a dashed double-dotted line illustrated in FIG. 6A and FIG. 6B represents a memory cell including one transistor and one capacitor.

FIG. 6A and FIG. 6B are layouts applicable to the second layer 11_2 and the layers above the second layer 11_2 and illustrate the transistors 201a and 201b, the capacitors 101a and 101b, and the like. For example, in the case where FIG. 6A is a top-view layout of the second layer 11_2, FIG. 6A illustrates the conductor 160 included in the second layer 11_2 (i.e., the upper electrodes of the capacitors 101a and 101b in the second layer 11_2) and the conductor 261 included in the third layer 11_3 (i.e., the back gate electrodes of the transistors 201a and 201b in the third layer 11_3), and FIG. 6B illustrates the conductor 160 included in the first layer 11_1 (i.e., the back gate electrodes of the transistors 201a and 201b in the second layer 11_2) and the conductor 261 included in the second layer 11_2 (i.e., the back gate electrodes of the transistors 201a and 201b in the second layer 11_2).

As illustrated in FIG. 6A and FIG. 6B, the conductor 160, the conductor 260, and the conductor 261 are provided to extend in the Y direction. The conductor 160, the conductor 260, and the conductor 261 are shared by memory cells adjacent in the Y direction and function as wirings.

Note that the conductor 240 and the conductor 153 are illustrated to have circular shapes in the top view in FIG. 6A and FIG. 6B but are not limited thereto. For example, the conductor 240 in the top view may have an almost circular shape such as an elliptical shape, a polygonal shape such as a quadrangular shape, or a polygonal shape such as a quadrangular shape with rounded corners.

Although FIG. 6A and FIG. 6B each illustrate a structure in which two memory cells that are adjacent without the conductor 240 therebetween are each provided with the conductor 160, the present invention is not limited thereto. For example, the two memory cells that are adjacent without the conductor 240 therebetween may share one conductor 160.

### <Component Materials of Semiconductor Device>

Component materials that can be used for the semiconductor device are described below. Note that each layer included in the semiconductor device may have a single-layer structure or a stacked-layer structure.

### <<Substrate>>

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples of substrates include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided for the substrate include a capacitor, a resistor, a switching element, a light-emitting element, and a memory element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. In contrast, when a material with a low relative dielectric constant is used for the insulator functioning as an interlayer film, parasitic capacitance generated between wirings can be reduced. Thus, a material is preferably selected depending on the function of the insulator.

Examples of the insulator with a high relative dielectric constant include gallium oxide, hafnium oxide, zirconium oxide, an oxide including aluminum and hafnium, an oxynitride including aluminum and hafnium, an oxide including silicon and hafnium, an oxynitride including silicon and hafnium, and a nitride including silicon and hafnium.

Examples of the insulator with a low relative dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator including, for example, one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used. Specific examples of the insulator having a function of inhibiting passage of oxygen and impurities such as hydrogen include a metal oxide such as aluminum oxide, magnesium oxide, gallium oxide, germanium oxide, yttrium oxide, zirconium oxide, lanthanum oxide, neodymium oxide, hafnium oxide, or tantalum oxide and a metal nitride such as aluminum nitride, silicon nitride oxide, or silicon nitride.

The insulator functioning as the gate insulator is preferably an insulator including a region including oxygen to be released by heating. For example, when a structure is employed in which silicon oxide or silicon oxynitride including a region including oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy including any of the above metal elements; an alloy including a combination of the above metal elements; or the like. Examples of the conductor include tantalum nitride, titanium nitride, tungsten, a nitride including titanium and aluminum, a nitride including tantalum and aluminum, ruthenium oxide, ruthenium nitride, an oxide including strontium and ruthenium, and an oxide including lanthanum and nickel. Tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are conductive materials that are less likely to be oxidized or materials that maintain their conductivity even after absorbing oxygen. Alternatively, a semiconductor having high electrical conductivity, typified by polycrystalline silicon including an impurity element such as phosphorus, or silicide such as nickel silicide may be used.

In the case of using a conductor having a stacked-layer structure, for example, a stacked-layer structure combining a material including the above metal element and a conductive material including oxygen, a stacked-layer structure combining a material including the above metal element and a conductive material including nitrogen, or a stacked-layer structure combining a material including the above metal element, a conductive material including oxygen, and a conductive material including nitrogen may be employed.

In the case where an oxide is used for the channel formation region of the transistor, the conductor functioning as the gate electrode preferably employs a stacked-layer structure combining a material including the above metal element and a conductive material including oxygen. In that case, the conductive material including oxygen is preferably provided on the channel formation region side. When the conductive material including oxygen is provided on the channel formation region side, oxygen released from the conductive material is easily supplied to the channel formation region.

It is particularly preferable to use, for the conductor functioning as the gate electrode, a conductive material including oxygen and a metal element included in the metal oxide where the channel is formed. A conductive material including the above metal element and nitrogen may be used. For example, a conductive material including nitrogen, such as titanium nitride or tantalum nitride, may be used. One or more of indium tin oxide, indium oxide including tungsten oxide, indium zinc oxide including tungsten oxide, indium oxide including titanium oxide, indium tin oxide including titanium oxide, indium zinc oxide, and indium tin oxide to which silicon is added may be used. Indium gallium zinc oxide including nitrogen may be used. With the use of such a material, hydrogen included in the metal oxide where the channel is formed can be captured in some cases. Alternatively, hydrogen entering from an external insulator or the like can be captured in some cases.

<<Metal oxide>>

The oxide 230 is preferably formed using a metal oxide functioning as a semiconductor (an oxide semiconductor). A metal oxide that can be used as the oxide 230 according to one embodiment of the present invention is described below.

The metal oxide preferably includes at least indium or zinc. In particular, indium and zinc are preferably included. In addition, aluminum, gallium, yttrium, tin, or the like is preferably included. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be included.

Here, the case where the metal oxide is an In-M-Zn oxide including indium, an element M, and zinc is considered. The element M is aluminum, gallium, yttrium, or tin. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

It is particularly preferable to use an oxide including indium (In), gallium (Ga), and zinc (Zn) (In—Ga—Zn oxide, also referred to as IGZO) for the semiconductor layer of the transistor. Alternatively, an oxide including indium (In), aluminum (Al), and zinc (Zn) (also referred to as IAZO) may be used for the semiconductor layer of the transistor. Alternatively, an oxide including indium (In), aluminum (Al), gallium (Ga), and zinc (Zn) (IAGZO or IGAZO) may be used for the semiconductor layer. Alternatively, an oxide including indium (In), gallium (Ga), zinc (Zn), and tin (Sn) (In—Ga—Zn—Sn oxide, also referred to as IGZTO) may be used for the semiconductor layer.

Note that in this specification and the like, a metal oxide including nitrogen is also collectively referred to as a metal oxide in some cases. A metal oxide including nitrogen may be referred to as a metal oxynitride.

Hereinafter, In—Ga—Zn oxide is described as an example of the metal oxide.

Amorphous (including completely amorphous), CAAC (c-axis-aligned crystalline), nc (nanocrystalline), CAC (cloud-aligned composite), single crystal, and polycrystalline (polycrystal) structures can be given as examples of crystal structures of an oxide semiconductor.

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail. [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the maximum diameter of the crystal region may be approximately several tens of nanometers.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can also be regarded as an oxide semiconductor that has small amounts of impurities and defects (e.g., oxygen vacancies). Thus, an oxide semiconductor including the CAAC-OS is physically stable. Thus, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the OS transistor can extend the degree of freedom of the manufacturing process. [nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter also referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

In addition, in a material composition of a CAC-OS in an In—Ga—Zn oxide that includes In, Ga, Zn, and O, there are regions including In as a main component (first regions) in part of the CAC-OS and regions including Ga as a main component (second regions) in another part of the CAC-OS. These regions are randomly present to form a mosaic pattern. Thus, it is suggested that the CAC-OS has a structure where metal elements are unevenly distributed.

The CAC-OS can be formed by a sputtering method under a condition where a substrate is not heated, for example. In addition, in the case of forming the CAC-OS by a sputtering method, one or more selected from an inert gas (typically, argon), an oxygen gas, and a nitrogen gas can be used as a film formation gas. The proportion of the flow rate of an oxygen gas in the total flow rate of the film formation gas during film formation is preferably as low as possible. For example, the proportion of the flow rate of an oxygen gas in the total flow rate of the film formation gas during film formation is higher than or equal to 0% and lower than 30%, preferably higher than or equal to 0% and lower than or equal to 10%.

Here, the first region is a region having a higher conductivity than the second region. That is, when carriers flow through the first region, the conductivity of a metal oxide is exhibited. Accordingly, when the first regions are distributed in a metal oxide like a cloud, high field-effect mobility (u) can be achieved.

On the other hand, the second region is a region having a higher insulating property than the first region. That is, when the second regions are distributed in a metal oxide, leakage current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), a high field-effect mobility (u), and favorable switching operation can be achieved.

A transistor using the CAC-OS has high reliability. Thus, the CAC-OS is most suitable for a variety of semiconductor devices such as a display device.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <<Other Semiconductor Materials>>

A semiconductor material that has a band gap (a semiconductor material that is not a zero-gap semiconductor) may be used for the semiconductor layer of the transistor. For example, a single element semiconductor such as silicon or a compound semiconductor such as gallium arsenide may be used.

For the semiconductor layer of the transistor, transition metal chalcogenide functioning as a semiconductor is preferably used, for example. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer of the transistor can provide a semiconductor device with a high on-state current.

### <Example of Method for Manufacturing Semiconductor Device>

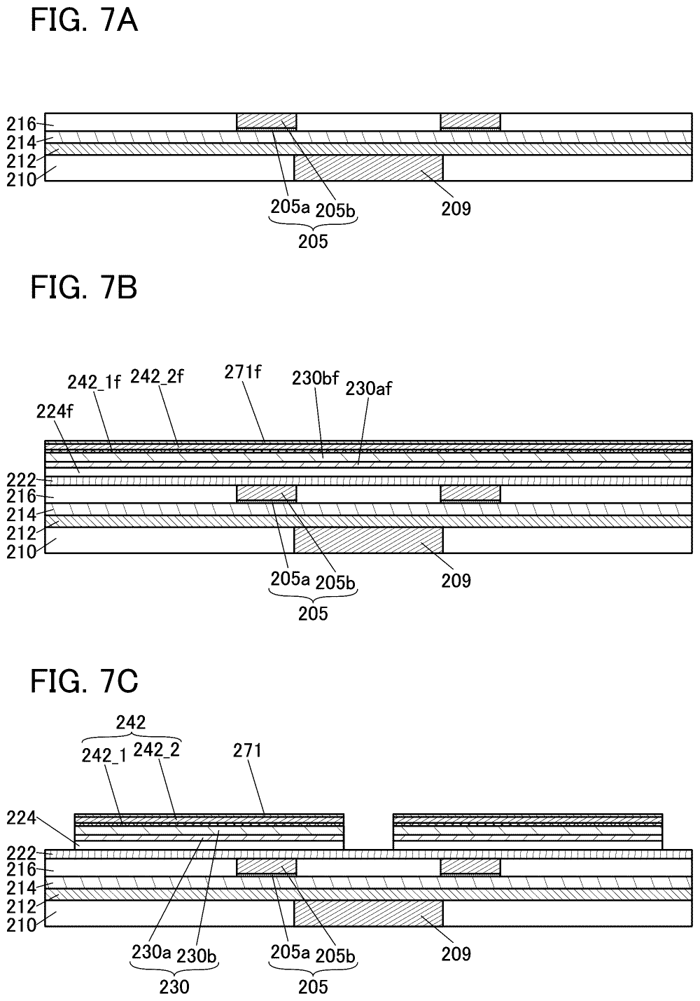

An example of a method for manufacturing a semiconductor device of one embodiment of the present invention is described with reference to FIG. 7 to FIG. 14. Here, the case of manufacturing the semiconductor device illustrated in FIG. 1 is described as an example.

Hereinafter, an insulating material for forming an insulator, a conductive material for forming a conductor, or a semiconductor material for forming a semiconductor can be formed by a sputtering method, a chemical vapor deposition (CVD) method, a molecular beam epitaxy (MBE) method, a pulsed laser deposition (PLD) method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is formed by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a film formation method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. In contrast, such plasma damage is not caused in the case of the thermal CVD method, which does not use plasma, and thus the yield of the semiconductor device can be increased. In addition, the thermal CVD method does not cause plasma damage during film formation, so that a film with few defects can be obtained.

As the ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the CVD method and the ALD method are film formation methods that enable favorable step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low film formation rate, and thus is preferably used in combination with another film formation method with a high film formation rate, such as the CVD method, in some cases.

By the CVD method, a film with a certain composition can be formed depending on the flow rate ratio of the source gases. For example, by the CVD method, a film whose composition is continuously changed can be formed by changing the flow rate ratio of the source gases during film formation. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By the ALD method, a film with a certain composition can be formed by concurrently introducing different kinds of precursors. In the case where different kinds of precursors are introduced, a film with a certain composition can be formed by controlling the number of cycles for each of the precursors.

First, a substrate (not illustrated) is prepared, and the insulator 210 and the conductor 209 are formed over the substrate. Next, the insulator 212 is formed over the insulator 210 and the conductor 209, and the insulator 214 is formed over the insulator 212 (FIG. 7A).

The insulator 212 and the insulator 214 are each preferably formed by a sputtering method. By using a sputtering method that does not need to use a molecule including hydrogen as a film formation gas, the hydrogen concentrations in the insulator 212 and the insulator 214 can be reduced. Without limitation to a sputtering method, the insulator 212 and the insulator 214 may each be formed by, for example, a CVD method, an MBE method, a PLD method, or an ALD method.

The insulator 212 and the insulator 214 are preferably successively formed without exposure to the air. For example, a multi-chamber film formation apparatus is preferably used. As a result, the amount of hydrogen in the formed insulator 212 and insulator 214 can be reduced, and furthermore, entry of hydrogen into the films in intervals between film formation steps can be inhibited.

In this embodiment, for the insulator 212, a silicon nitride film is formed by a pulsed DC sputtering method using a silicon target in an atmosphere including a nitrogen gas. The use of the pulsed DC sputtering method can inhibit generation of particles due to arcing on the target surface, achieving more uniform film thickness. In addition, by using the pulsed voltage, rising and falling in discharge can be made steep as compared with the case where a high-frequency voltage is used. As a result, electric power can be supplied to an electrode more efficiently to improve the sputtering rate and film quality.

The use of an insulator through which impurities such as water and hydrogen are less likely to pass, such as silicon nitride, can inhibit diffusion of impurities such as water and hydrogen included in a layer below the insulator 212. When an insulator through which copper is less likely to pass, such as silicon nitride, is used for the insulator 212, even in the case where a metal that is likely to diffuse, such as copper, is used for a conductor in a layer (not illustrated) below the insulator 212, upward diffusion of the metal through the insulator 212 can be inhibited.

In this embodiment, for the insulator 214, an aluminum oxide film is formed by a pulsed DC sputtering method using an aluminum target in an atmosphere including an oxygen gas. The use of the pulsed DC sputtering method can achieve more uniform film thickness and improve the sputtering rate and film quality. Here, RF (Radio Frequency) power may be applied to the substrate. The amount of oxygen implanted into a layer below the insulator 214 can be controlled depending on the amount of the RF power applied to the substrate. The RF power is higher than or equal to 0 W/cm² and lower than or equal to 1.86 W/cm², for example. That is, an appropriate amount of oxygen for the transistor characteristics can be changed and implanted by RF power used for the formation of the insulator 214. Accordingly, an appropriate amount of oxygen for improving the reliability of the transistor can be implanted. The RF frequency is preferably 10 MHz or higher. The typical frequency is 13.56 MHz. The higher the RF frequency is, the less damage the substrate receives.

A metal oxide having an amorphous structure, an excellent function of capturing hydrogen, and an excellent function of fixing hydrogen, such as aluminum oxide, is preferably used for the insulator 214. In this case, the insulator 214 captures or fixes hydrogen included in the insulator 216 and the like and prevents the hydrogen from diffusing into the oxide 230. It is particularly preferable to use aluminum oxide having an amorphous structure or amorphous aluminum oxide for the insulator 214 because hydrogen can be captured or fixed more effectively in some cases. Accordingly, the transistor and the semiconductor device which have favorable characteristics and high reliability can be manufactured.

Next, a conductive film to be the conductor 205a is formed over the insulator 214. The conductive film to be the conductor 205a desirably includes a conductor having a function of inhibiting passage of oxygen. The conductive film preferably includes one or more of tantalum nitride, tungsten nitride, and titanium nitride, for example. Alternatively, the conductive film can be a stacked film of the conductor having a function of inhibiting passage of oxygen and tantalum, tungsten, titanium, molybdenum, aluminum, copper, or a molybdenum-tungsten alloy. The conductive film to be the conductor 205a can be formed by a sputtering method, a CVD method, an MBE method, a PLD method, or an ALD method, for example.

Subsequently, a conductive film to be the conductor 205b is formed over the conductive film to be the conductor 205a. The conductive film to be the conductor 205b preferably includes one or more of tantalum, tungsten, titanium, molybdenum, aluminum, copper, and a molybdenum-tungsten alloy, for example. The conductive film can be formed by a plating method, a sputtering method, a CVD method, an MBE method, a PLD method, or an ALD method, for example. In this embodiment, a tungsten film is formed for the conductive film to be the conductor 205b.

Next, the conductive film to be the conductor 205a and the conductive film to be the conductor 205b are processed by a lithography method to form the conductor 205 (FIG. 7A). A dry etching method or a wet etching method can be used for forming the conductor 205. A dry etching method is preferably used because processing by a dry etching method is suitable for microfabrication.

Subsequently, an insulating film to be the insulator 216 is formed to cover the conductor 205. The insulating film to be the insulator 216 is preferably formed by a sputtering method. By using a sputtering method that does not need to use a molecule including hydrogen as a film formation gas, the hydrogen concentration in the insulator 216 can be reduced. Without limitation to a sputtering method, the insulator 216 may be formed by, for example, a CVD method, an MBE method, a PLD method, or an ALD method.

In this embodiment, for the insulator 216, a silicon oxide film is formed by a pulsed DC sputtering method using a silicon target in an atmosphere including an oxygen gas. The use of the pulsed DC sputtering method can achieve more uniform film thickness and improve the sputtering rate and film quality.

Next, CMP treatment is performed to remove part of the insulating film to be the insulator 216, so that the conductor 205 is exposed. As a result, the insulator 216 remains in contact with the side surface of the conductor 205 (FIG. 7A).

Note that although the method for forming the insulator 216 after the formation of the conductor 205 is described above, the present invention is not limited thereto. For example, the insulator 216 having an opening may be formed first, and the conductor 205 may be formed to fill the opening.

Next, the insulator 222 is formed over the insulator 216 and the conductor 205 (FIG. 7B).

An insulator including an oxide of one or both of aluminum and hafnium is preferably formed as the insulator 222. Note that as the insulator including an oxide of one or both of aluminum and hafnium, for example, aluminum oxide, hafnium oxide, or an oxide including aluminum and hafnium (hafnium aluminate) is preferably used. Alternatively, hafnium-zirconium oxide is preferably used. The insulator including an oxide of one or both of aluminum and hafnium has a barrier property against oxygen, hydrogen, and water. When the insulator 222 has a barrier property against hydrogen and water, hydrogen and water included in components provided around the transistor are inhibited from diffusing into the transistor through the insulator 222, and generation of oxygen vacancies in the oxide 230 can be inhibited.

Alternatively, the insulator 222 can be a stacked film of the insulator including an oxide of one or both of aluminum and hafnium and silicon oxide, silicon oxynitride, silicon nitride, or silicon nitride oxide.

The insulator 222 can be formed by a sputtering method, a CVD method, an MBE method, a PLD method, or an ALD method, for example. In this embodiment, for the insulator 222, a hafnium oxide film is formed by an ALD method. Alternatively, a stack of silicon nitride formed by a PEALD method and a hafnium oxide film formed by an ALD method may be used as the insulator 222.

Subsequently, heat treatment is preferably performed. The temperature of the heat treatment is preferably higher than or equal to 250° C. and lower than or equal to 650° C., further preferably higher than or equal to 300° C. and lower than or equal to 500° C., still further preferably higher than or equal to 320° C. and lower than or equal to 450° C. Note that the heat treatment is performed in a nitrogen gas or inert gas atmosphere, or an atmosphere including an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment may be performed in an atmosphere including an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture included in the gas used in the above heat treatment is preferably 1 ppb or less, further preferably 0.1 ppb or less, still further preferably 0.05 ppb or less. The heat treatment using a highly purified gas can prevent entry of moisture or the like into the insulator 222 and the like as much as possible.

In this embodiment, as the heat treatment, treatment is performed at 400° C. for one hour with a flow rate ratio of a nitrogen gas to an oxygen gas of 4:1 after the formation of the insulator 222. Through the heat treatment, impurities such as water and hydrogen included in the insulator 222 can be removed, for example. In the case where an oxide including hafnium is used for the insulator 222, the insulator 222 is partly crystallized by the heat treatment in some cases. The heat treatment can also be performed after the formation of the insulator 224, for example.

Next, an insulating film 224f is formed over the insulator 222 (FIG. 7B).

The insulating film 224f can be formed by a sputtering method, a CVD method, an MBE method, a PLD method, or an ALD method, for example. In this embodiment, for the insulating film 224f, a silicon oxide film is formed by a sputtering method. By using a sputtering method that does not need to use a molecule including hydrogen as a film formation gas, the hydrogen concentration in the insulating film 224f can be reduced. The hydrogen concentration in the insulating film 224f is preferably reduced in this manner because the insulating film 224f is in contact with the oxide 230a in a later step.

Next, an oxide film 230af is formed over the insulating film 224f, and an oxide film 230bf is formed over the oxide film 230af (FIG. 7B). Note that the oxide film 230af and the oxide film 230bf are preferably formed successively without being exposed to an atmospheric environment. By the film formation without exposure to the atmosphere, impurities or moisture from the atmospheric environment can be prevented from being attached onto the oxide film 230af and the oxide film 230bf, so that the vicinity of an interface between the oxide film 230af and the oxide film 230bf can be kept clean.

The oxide film 230af and the oxide film 230bf can each be formed by a sputtering method, a CVD method, an MBE method, a PLD method, or an ALD method, for example. In this embodiment, the oxide film 230af and the oxide film 230bf are formed by a sputtering method.

For example, in the case where the oxide film 230af and the oxide film 230bf are formed by a sputtering method, oxygen or a mixed gas of oxygen and a noble gas is used as a sputtering gas. Increasing the proportion of oxygen included in the sputtering gas can increase the amount of excess oxygen in the formed oxide films. In the case where the oxide films are formed by a sputtering method, the above In-M-Zn oxide target or the like can be used.

In particular, when the oxide film 230af is formed, part of oxygen included in the sputtering gas is supplied to the insulating film 224f in some cases. Thus, the proportion of oxygen included in the sputtering gas is preferably higher than or equal to 70%, further preferably higher than or equal to 80%, still further preferably 100%.

In the case where the oxide film 230bf is formed by a sputtering method and the proportion of oxygen included in the sputtering gas for film formation is higher than 30% and lower than or equal to 100%, preferably higher than or equal to 70% and lower than or equal to 100%, an oxygen-excess oxide semiconductor is formed. In a transistor including an oxygen-excess oxide semiconductor for its channel formation region, relatively high reliability can be obtained. Note that one embodiment of the present invention is not limited thereto. In the case where the oxide film 230bf is formed by a sputtering method and the proportion of oxygen included in the sputtering gas for film formation is higher than or equal to 1% and lower than or equal to 30%, preferably higher than or equal to 5% and lower than or equal to 20%, an oxygen-deficient oxide semiconductor is formed. In a transistor including an oxygen-deficient oxide semiconductor for its channel formation region, relatively high field-effect mobility can be obtained. Furthermore, when the film formation is performed while the substrate is being heated, the crystallinity of the oxide film can be improved.

In this embodiment, the oxide film 230af is formed by a sputtering method using an oxide target with In:Ga:Zn=1:3:4 [atomic ratio] or an oxide target with In:Ga:Zn=1:3:2 [atomic ratio]. In addition, the oxide film 230bf is formed by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 230a and the oxide 230b by selecting the film formation conditions and the atomic ratios as appropriate.

Note that the insulating film 224f, the oxide film 230af, and the oxide film 230bf are preferably formed by a sputtering method without exposure to the air. For example, a multi-chamber film formation apparatus is preferably used. As a result, entry of hydrogen into the insulating film 224f, the oxide film 230af, and the oxide film 230bf in intervals between film formation steps can be inhibited.

Next, heat treatment is preferably performed. The heat treatment is performed in a temperature range where the oxide film 230af and the oxide film 230bf do not become polycrystals. The temperature of the heat treatment is preferably higher than or equal to 100° C., higher than or equal to 250° C., or higher than or equal to 350° C. and lower than or equal to 650° C., lower than or equal to 600° C., or lower than or equal to 550° C.

Note that an example of an atmosphere for the heat treatment is an atmosphere similar to the atmosphere that can be used for the heat treatment performed after the formation of the insulator 222.

As in the heat treatment performed after the formation of the insulator 222, a gas used in the heat treatment is preferably highly purified. The heat treatment using a highly purified gas can prevent entry of moisture or the like into the oxide film 230af, the oxide film 230bf, and the like as much as possible.

In this embodiment, the heat treatment is performed at 400° C. for one hour with a flow rate ratio of a nitrogen gas to an oxygen gas being 4:1. Through such heat treatment using the oxygen gas, impurities such as carbon, water, and hydrogen in the oxide film 230af and the oxide film 230bf can be reduced. The reduction of impurities in the films in this manner improves the crystallinity of the oxide film 230bf, thereby offering a dense structure with a higher density. Thus, crystalline regions in the oxide film 230af and the oxide film 230bf are expanded, so that in-plane variations of the crystalline regions in the oxide film 230af and the oxide film 230bf can be reduced. Accordingly, an in-plane variation of electrical characteristics of transistors can be reduced.

By performing the heat treatment, hydrogen in the insulator 216, the insulating film 224f, the oxide film 230af, and the oxide film 230bf moves into the insulator 222 and is absorbed by the insulator 222. In other words, hydrogen in the insulator 216, the insulating film 224f, the oxide film 230af, and the oxide film 230bf diffuses into the insulator 222. Accordingly, the hydrogen concentration in the insulator 222 increases, while the hydrogen concentrations in the insulator 216, the insulating film 224f, the oxide film 230af, and the oxide film 230bf decrease.

Specifically, the insulating film 224f (to be the insulator 224 later) functions as the second gate insulator of the transistor 202a, and the oxide film 230af and the oxide film 230bf (to be the oxide 230a and the oxide 230b later) function as the channel formation region of the transistor 202a. The transistor 202a formed using the insulating film 224f, the oxide film 230af, and the oxide film 230bf with reduced hydrogen concentrations is preferable because of its favorable reliability.

Next, a conductive film 242_1f is formed over the oxide film 230bf, and a conductive film 242_2f is formed over the conductive film 242_1f (FIG. 7B). After the formation of the oxide film 230bf, the conductive film 242_1f is formed over and in contact with the oxide film 230bf without an etching step or the like, whereby the top surface of the oxide film 230bf can be protected by the conductive film 242_1f. Thus, diffusion of impurities into the oxide 230 included in the transistor can be inhibited, so that the electrical characteristics and reliability of the semiconductor device can be improved.×

The conductive film 242_1f and the conductive film 242_2f can each be formed by a sputtering method, a CVD method, an MBE method, a PLD method, or an ALD method, for example.

In this embodiment, a tantalum nitride film is formed for the conductive film 242_1f by a sputtering method, and a tungsten film is formed for the conductive film 242_2f. Note that heat treatment may be performed before the formation of the conductive film 242_1f. This heat treatment may be performed under reduced pressure, and the conductive film 242_1f may be successively formed without exposure to the air. Such treatment can remove moisture and hydrogen adsorbed onto the surface of the oxide 230b, and further can reduce the moisture concentration and the hydrogen concentration in the oxide 230a and the oxide 230b. The heat treatment is preferably performed at a temperature higher than or equal to 100° C. and lower than or equal to 400° C. In this embodiment, the heat treatment is performed at 250° C.

Next, an insulating film 271f is formed over the conductive film 242_2f (FIG. 7B). The insulating film 271f can be formed by a sputtering method, a CVD method, an MBE method, a PLD method, or an ALD method, for example. As the insulating film 271f, an insulating film having a function of inhibiting passage of oxygen is preferably used. For example, as the insulating film 271f, a stacked film of a silicon nitride film and a silicon oxide film over the silicon nitride film may be formed by a sputtering method.

Subsequently, the insulating film 224f, the oxide film 230af, the oxide film 230bf, the conductive film 242_1f, the conductive film 242_2f, and the insulating film 271f are processed into an island shape by a lithography method to form the insulator 224, the oxide 230a, the oxide 230b, the conductor 242_1, the conductor 242_2, and the insulator 271 (FIG. 7C).

Here, the insulator 224, the oxide 230a, the oxide 230b, the conductor 242_1, the conductor 242_2, and the insulator 271 are preferably processed into an island shape at a time. In that case, side end portions of the conductor 242_1 and side end portions of the conductor 242_2 are preferably substantially aligned with side end portions of the oxide 230a and the oxide 230b.

Furthermore, the side end portions of the insulator 224 are preferably substantially aligned with the side end portions of the oxide 230. Furthermore, the side end portions of the insulator 271 are preferably substantially aligned with the side end portions of the conductor 242. With such a structure, the semiconductor device of one embodiment of the present invention can be manufactured with favorable productivity.

The insulator 224, the oxide 230a, the oxide 230b, the conductor 242_1, the conductor 242_2, and the insulator 271 are formed to at least partly overlap with the conductor 205. The conductor 242_1 and the conductor 242_2 are formed such that a region between the conductor 242_1 and the conductor 242_2 at least partly overlaps with the conductor 209. The insulator 222 is exposed in a region not overlapping with the insulator 224, the oxide 230a, the oxide 230b, the conductor 242_1, the conductor 242_2, and the insulator 271.

As illustrated in FIG. 7C, the side surfaces of the insulator 224, the oxide 230a, the oxide 230b, the conductor 242_1, the conductor 242_2, and the insulator 271 may be substantially perpendicular to the top surface of the insulator 222. With such a structure, a plurality of transistors can be provided with high density in a small area.

Without limitation to the above, the side surfaces of the insulator 224, the oxide 230a, the oxide 230b, the conductor 242_1, the conductor 242_2, and the insulator 271 may have tapered shapes. The taper angles of the side surfaces of the insulator 224, the oxide 230a, the oxide 230b, the conductor 242_1, the conductor 242_2, and the insulator 271 may be greater than or equal to 60° and less than 90°, for example. With such tapered shapes of the side surfaces, the coverage with the insulator 275 and the like can be improved in a later step, so that defects such as a void can be reduced.

Note that as illustrated in FIG. 7C, the conductor 242, the oxide 230, and the insulator 224 are preferably formed into two island shapes. However, without limitation to this, the conductor 242, the oxide 230, and the insulator 224 may be formed into one island shape having an opening in a position overlapping with the conductor 209.

A dry etching method or a wet etching method can be used for the processing. Processing by a dry etching method is suitable for microfabrication. The insulating film 224f, the oxide film 230af, the oxide film 230bf, the conductive film 242_1f, the conductive film 242_2f, and the insulating film 271f may be processed under different conditions.

Note that in the lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the oxide film 230bf, a resist mask is formed thereover, and then the hard mask material is etched. The etching of the oxide film 230bf and the like may be performed after removing the resist mask or with the resist mask remaining. In the latter case, the resist mask sometimes disappears during the etching. The hard mask may be removed by etching after the etching of the oxide film 230bf and the like. Meanwhile, the hard mask is not necessarily removed when the hard mask material does not affect later steps or can be utilized in later steps.

An etching gas including a halogen can be used as an etching gas for dry etching treatment; specifically, an etching gas including one or more of fluorine, chlorine, and bromine can be used. As the etching gas, for example, a C₄F₆ gas, a C₅F₆ gas, a C₄F₈ gas, a CF₄ gas, a SF₆ gas, a CHF₃ gas, a CH₂F₂ gas, a Cl₂ gas, a BCl₃ gas, a SiCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. Depending on the object to be processed in the dry etching treatment, a gas that includes not a halogen gas but a hydrocarbon gas or a hydrogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes.

Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

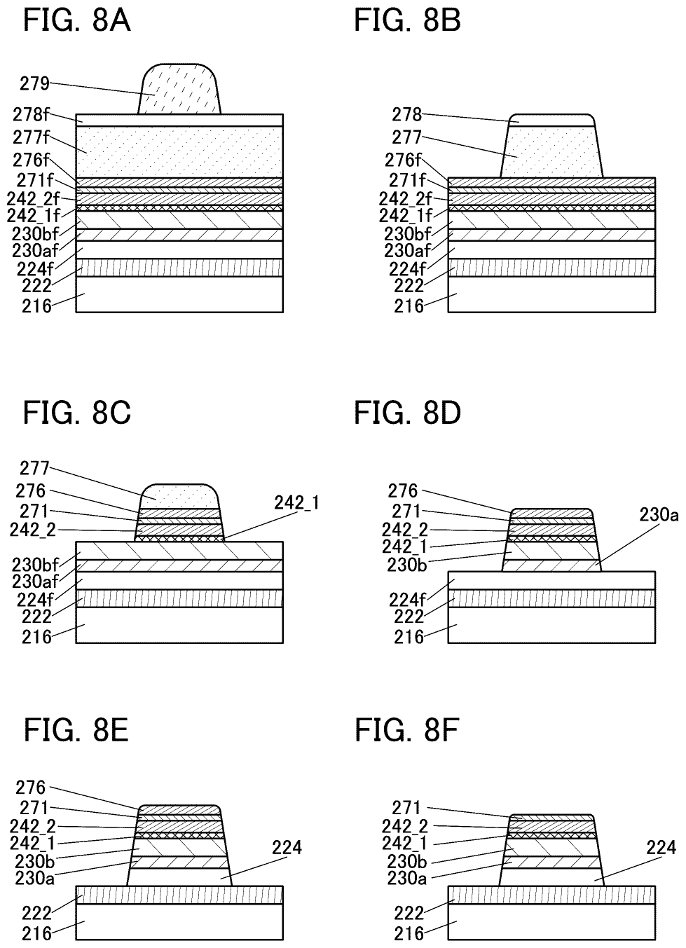

A specific example of processing of the insulating film 224f, the oxide film 230af, the oxide film 230bf, the conductive film 242_1f, the conductive film 242_2f, and the insulating film 271f are described below with reference to FIG. 8A to FIG. 8F.

First, a hard mask layer 276f is formed over the insulating film 271f (FIG. 8A). The hard mask layer 276f can be formed by a sputtering method, a CVD method, an MBE method, a PLD method, an ALD method, or the like. The hard mask layer 276f functions as a hard mask for forming the conductor 242 and the oxide 230 in a later step. For the hard mask layer 276f, a metal material, an inorganic insulating material, or the like is used. For example, a tungsten film formed by a sputtering method may be used as the hard mask layer 276f. Alternatively, a structure may be employed in which the hard mask layer 276f is successively formed without exposure to the air after the formation of the insulating film 271f.

Next, an organic coating film 277f is formed over the hard mask layer 276f, and an organic coating film 278f is further formed (FIG. 8A). The organic coating film 277f and the organic coating film 278f may have a function of improving adhesion between a hard mask and a resist mask described later. The organic coating film 277f and the organic coating film 278f are formed by a spin coating method, for example. For the organic coating film 277f and the organic coating film 278f, a non-photosensitive organic resin is used. In this embodiment, an SOC (Spin On Carbon) film is formed as the organic coating film 277f, and an SOG (Spin On Glass) film is formed as the organic coating film 278f. Here, the organic coating film 277f and the organic coating film 278f include an organic solvent such as alcohol at the time of application; however, in the following steps or when the semiconductor device is completed, an organic substance included in the organic coating film 277f and the organic coating film 278f is reduced or removed in some cases. Note that the organic coating films may be provided if needed; the organic coating films may be a single layer; or the organic coating films are not necessarily provided in the case where the resist mask described later can sufficiently work.

Next, a resist mask 279 is formed over the organic coating film 278f by a lithography method (FIG. 8A). As the resist mask 279, a photosensitive organic resin which is also referred to as a photoresist is used. For example, a positive photoresist or a negative photoresist can be used. A photoresist film to be the resist mask 279 can be formed to have a uniform thickness by a spin coating method or the like, for example.

In the steps in FIG. 8B to FIG. 8F, etching treatment for the stacked films illustrated in FIG. 8A is performed with a dry etching apparatus. The steps in FIG. 8B to FIG. 8F are preferably performed successively without exposure to the air. For example, the treatment is performed without exposure to the air with a multi-chamber etching apparatus. As the dry etching apparatus, a CCP etching apparatus in which high-frequency voltages with different frequencies are applied to the parallel plate electrodes in the chamber can be used. In this case, a structure can be employed in which a high-frequency voltage with a high frequency is applied to the upper electrode and a high-frequency voltage with a low frequency is applied to the lower electrode on which the substrate is provided.

First, with the use of the resist mask 279, the organic coating film 278f is processed into an island shape to form an organic coating film 278, and then the organic coating film 277f is processed into an island shape to form the organic coating film 277 (FIG. 8B). For example, in the case where an SOG film is used as the organic coating film 278f, CHF₃ and O₂ can be used as etching gases. For example, in the case where an SOC film is used as the organic coating film 277f, H₂ and N₂ can be used as etching gases.

The resist mask 279 sometimes disappears before the organic coating film 277 is formed. In the case where the resist mask 279 remains after the formation of the organic coating film 277, the resist mask 279 may be removed.

Next, with the use of the organic coating film 277 as a mask, the hard mask layer 276f is processed into an island shape to form a hard mask layer 276; the insulating film 271f is processed into an island shape to form the insulator 271; and then the conductive film 242_2f and the conductive film 242_1f are processed into island shapes to form the conductor 242_2 and the conductor 242_1, respectively (FIG. 8C). For example, in the case where a tungsten film is used as the hard mask layer 276f, CF₄ and Cl₂ can be used as etching gases. For example, in the case where a stacked film of silicon nitride and silicon oxide is used as the insulating film 271f, CHF₃ and O₂ can be used as etching gases. For example, in the case where a stacked film in which a tungsten film is used as the conductive film 242_2f and a tantalum nitride film is used as the conductive film 242_1f, CHF₃, Cl₂, and Ar can be used as etching gases.

Here, the hard mask layer 276 and the conductive film 242_2f are formed using the same metal material (e.g., tungsten) in some cases. When the organic coating film 277 functioning as a mask disappears during the etching of the conductive film 242_2f and the conductive film 242_1f, the hard mask layer 276 is exposed to the etching. Accordingly, the conductive film 242_2f, the conductive film 242_1f, and the like might be excessively etched and the width of the conductor 242 might be narrower than a designed width.

Thus, in an etching step of the conductive film 242_2f and the conductive film 242_1f, the etching is preferably performed under conditions where the etching rates of the conductive film 242_2f and the conductive film 242_1f are higher than the etching rate of the organic coating film 277. For example, the electric power of the lower electrode on which the substrate is provided is preferably low in the etching step of the conductive film 242_2f and the conductive film 242_1f. For example, the electric power of the lower electrode on which the substrate is provided is lower than the electric power of the lower electrode applied when the hard mask layer 276f is etched, preferably lower than 25 W, further preferably lower than or equal to 10 W. By performing etching under such conditions, even in a semiconductor device having a minute structure, processing can be performed as designed.

Next, the oxide film 230bf and the oxide film 230af are processed into an island shape with the use of the hard mask layer 276 to form the oxide 230b and the oxide 230a (FIG. 8D). For example, in the case where an oxide including any one or more selected from In, Ga, and Zn is used for the oxide film 230bf and the oxide film 230af, CH₄ and Ar can be used as etching gases. An oxide including In, Ga, and Zn easily forms a metal complex having high volatility when reacting with a CH₃ radical. Thus, even at a relatively low substrate temperature, the use of the gas including CH₄ facilitates processing of the oxide including In, Ga, and Zn, which is a hard-to-etch material.

Note that in the case where the organic coating film 277 remains after the step illustrated in FIG. 8D, dry etching treatment such as ashing, wet etching treatment, wet etching treatment after dry etching treatment, or dry etching treatment after wet etching treatment may be performed to remove the organic coating film 277.

Next, the insulating film 224f is processed into an island shape with the use of the hard mask layer 276 to form the insulator 224 (FIG. 8E). For example, in the case where a silicon oxide film is used as the insulating film 224f, CHF₃ and Ar can be used as etching gases.

Here, it is preferable that the insulator 222 not be overetched during the processing of the insulating film 224f. Thus, etching is preferably performed under conditions where the etching selectivity with respect to the insulator 222 is high. For example, in the case where the insulating film 224f includes silicon oxide and is etched with a gas including fluorine, the insulator 222 preferably includes hafnium oxide. By the etching in this manner, the insulator 275 can be provided in contact with the side surface of the insulator 224 and the top surface of the insulator 222 in a step described later. That is, the insulator 224 can be isolated from the insulator 280 by the insulator 275. With such a structure, an excess amount of oxygen and impurities such as hydrogen can be prevented from entering the oxide 230 from the insulator 280 through the insulator 224.

Lastly, the hard mask layer 276 is removed (FIG. 8F). For example, in the case where a tungsten film is used as the hard mask layer 276, CF₄, Cl₂, and O₂ can be used as etching gases. Note that the hard mask layer 276 is not necessarily removed when the material for the hard mask layer 276 does not affect later steps or can be utilized in later steps.

Since the insulator 271 functions as a mask for the conductor 242_2 in the step of removing the hard mask layer 276, the conductor 242_2 does not have a curved surface between its side surface and top surface. Thus, end portions at the intersections of the side surfaces and the top surfaces of the conductor 242a and the conductor 242b are angular. When the end portion at the intersection of the side surface and the top surface of the conductor 242 is angular, the cross-sectional area of the conductor 242 is larger than that in the case where the end portion is rounded. Accordingly, the resistance of the conductor 242 is reduced, so that the on-state current of the transistor can be increased.

In the above manner, the insulator 224, the oxide 230a, the oxide 230b, the conductor 242_1, the conductor 242_2, and the insulator 271 can be collectively processed into an island shape. Thus, the number of steps can be smaller than that in the case where the insulator 224, the oxide 230a, the oxide 230b, the conductor 242_1, the conductor 242_2, and the insulator 271 are individually processed into an island shape. Thus, a method for manufacturing a semiconductor device with high productivity can be provided.

Next, the insulator 275 is formed to cover the insulator 224, the oxide 230a, the oxide 230b, the conductor 242_1, the conductor 242_2, and the insulator 271, and the insulator 280 is formed over the insulator 275.

Here, it is preferable that the insulator 275 be in contact with the top surface of the insulator 222.

As the insulator 280, an insulator having a flat top surface is preferably formed by forming an insulating film to be the insulator 280 and then performing CMP treatment on the insulating film. Note that, for example, a silicon nitride film may be formed over the insulator 280 by a sputtering method and CMP treatment may be performed on the silicon nitride until the insulator 280 is reached.

The insulator 275 and the insulator 280 can each be formed by a sputtering method, a CVD method, an MBE method, a PLD method, or an ALD method, for example.

For the insulator 275, an insulator having a function of inhibiting passage of oxygen is preferably used. For example, a silicon nitride film is preferably formed as the insulator 275 by a PEALD method. Alternatively, for the insulator 275, it is preferable that an aluminum oxide film be formed by a sputtering method and a silicon nitride film be formed thereover by a PEALD method. When the insulator 275 has such a stacked-layer structure, the function of inhibiting diffusion of oxygen and impurities such as water and hydrogen can be improved.

In this manner, the oxide 230a, the oxide 230b, the conductor 242_1, and the conductor 242_2 can be covered with the insulator 275, which has a function of inhibiting diffusion of oxygen. This can suppress direct diffusion of oxygen from the insulator 280 or the like into the insulator 224, the oxide 230a, the oxide 230b, the conductor 242_1, and the conductor 242_2 in a later step.

A silicon oxide film is preferably formed by a sputtering method as the insulator 280, for example. When the insulating film to be the insulator 280 is formed by a sputtering method in an atmosphere including oxygen, the insulator 280 including excess oxygen can be formed. By using a sputtering method that does not need to use a molecule including hydrogen as a film formation gas, the hydrogen concentration in the insulator 280 can be reduced. Note that heat treatment may be performed before the formation of the insulating film. The heat treatment may be performed under reduced pressure, and the insulating film may be successively formed without exposure to the air. Such treatment can remove moisture and hydrogen adsorbed onto the surface of the insulator 275 and the like, and further can reduce the moisture concentration and the hydrogen concentration in the oxide 230a, the oxide 230b, and the insulator 224. For the heat treatment, the above heat treatment conditions can be used.

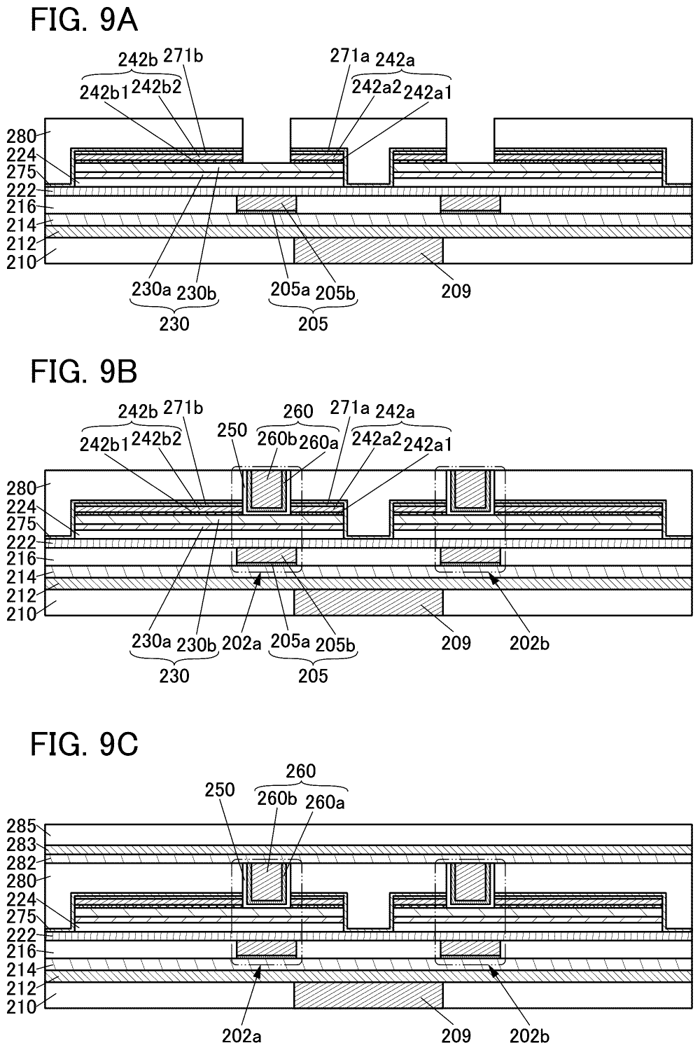

Next, the conductor 242_1, the conductor 242_2, the insulator 271, the insulator 275, and the insulator 280 are processed by a lithography method to form an opening reaching the oxide 230b (FIG. 9A). The opening reaching the oxide 230b is provided in a region where the oxide 230b and the conductor 205 overlap with each other.

A dry etching method or a wet etching method can be used for the processing. The conductor 242_1, the conductor 242_2, the insulator 271, the insulator 275, and the insulator 280 may be processed under different conditions.

By this processing, the conductor 242_1 is divided into the conductors 242al and 242b1 each having an island shape. Similarly, the conductor 242_2 is divided into the conductors 242a2 and 242b2 each having an island shape. Similarly, the insulator 271 is divided into the insulators 271a and 271b each having an island shape.

By the above etching treatment, impurities might be attached onto the side surface of the oxide 230a, the top surface and the side surface of the oxide 230b, the side surfaces of the conductors 242a and 242b, the side surfaces of the insulators 271a and 271b, the side surface of the insulator 275, the side surface of the insulator 280, and the like or the impurities might be diffused thereinto. A step of removing such impurities may be performed. In addition, a damaged region might be formed on the surface of the oxide 230b by the above dry etching. Such a damaged region may be removed. The impurities come from components included in the insulator 280, the insulator 275, the insulators 271a and 271b, and the conductors 242a and 242b; components included in a member of an apparatus used to form the opening; and components included in a gas or a liquid used for etching, for instance. Examples of the impurities include hafnium, aluminum, silicon, tantalum, fluorine, and chlorine.

In particular, impurities such as aluminum and silicon might reduce the crystallinity of the oxide 230b. Thus, it is preferable that impurities such as aluminum and silicon be removed from the surface of the oxide 230b and the vicinity thereof. The concentration of the impurities is preferably reduced. For example, the concentration of aluminum atoms at the surface of the oxide 230b and the vicinity thereof is preferably lower than or equal to 5.0 atomic %, further preferably lower than or equal to 2.0 atomic %, still further preferably lower than or equal to 1.5 atomic %, yet further preferably lower than or equal to 1.0 atomic %, or yet still further preferably lower than 0.3 atomic %.

Note that since the density of a crystal structure is reduced in a low-crystallinity region of the oxide 230b due to impurities such as aluminum and silicon, a large amount of VoH is formed; thus, the transistor is likely to be normally on. Hence, the low-crystallinity region of the oxide 230b is preferably reduced or removed.

In contrast, the oxide 230b preferably has a layered CAAC structure. In particular, the CAAC structure preferably reaches a lower end portion of a drain in the oxide 230b. Here, in the transistor, the conductor 242a or the conductor 242b functions as a drain. In other words, the oxide 230b in the vicinity of the lower end portion of the conductor 242a or the conductor 242b preferably has a CAAC structure. In this manner, the low-crystallinity region of the oxide 230b is removed and the CAAC structure is formed also in the end portion of the drain, which significantly affects the drain withstand voltage, so that a variation in electrical characteristics of transistors can be further suppressed. In addition, the reliability of the transistor can be improved.

In order to remove impurities and the like attached to the surface of the oxide 230b in the above etching step, cleaning treatment is performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the groove portion deeper.

The wet cleaning may be performed using an aqueous solution in which one or more of ammonia water, oxalic acid, phosphoric acid, and hydrofluoric acid is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 230b and the like can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffused into the oxide 230a, the oxide 230b, and the like. Furthermore, the crystallinity of the oxide 230b can be increased.

After the etching or the cleaning, heat treatment may be performed. The temperature of the heat treatment is preferably higher than or equal to 100° C., higher than or equal to 250° C., or higher than or equal to 350° C. and lower than or equal to 650° C., lower than or equal to 600° C., lower than or equal to 550° C., or lower than or equal to 400° C. Note that the heat treatment is performed in a nitrogen gas or inert gas atmosphere, or an atmosphere including an oxidizing gas at 10 ppm or more, 1% or more, or 10% or more. For example, the heat treatment is preferably performed in an oxygen atmosphere. Accordingly, oxygen can be supplied to the oxide 230a and the oxide 230b to reduce oxygen vacancies. In addition, the crystallinity of the oxide 230b can be improved by such heat treatment. Furthermore, hydrogen remaining in the oxide 230a and the oxide 230b reacts with supplied oxygen, so that the hydrogen can be removed as H₂O (dehydration). This can inhibit recombination of hydrogen remaining in the oxide 230a and the oxide 230b with oxygen vacancies and formation of VoH. The heat treatment may be performed under reduced pressure. Alternatively, heat treatment may be performed in an oxygen atmosphere, and then heat treatment may be successively performed in a nitrogen atmosphere without exposure to the air.

When heat treatment is performed in the state where the conductor 242a and the conductor 242b are in contact with the oxide 230b, the sheet resistance of the oxide 230b in each of a region overlapping with the conductor 242a and a region overlapping with the conductor 242b is decreased in some cases. Furthermore, the carrier concentration is sometimes increased. Thus, the resistance of the oxide 230b in the region overlapping with the conductor 242a and the region overlapping with the conductor 242b can be lowered in a self-aligned manner.

Next, insulating films and conductive films are formed to fill the opening and then processed to provide the insulator 250, the conductor 260a, and the conductor 260b in a position overlapping with the conductor 205 (FIG. 9B).

First, an insulating film to be the insulator 250 is formed. The insulating film can be formed by a sputtering method, a CVD method, an MBE method, a PLD method, or an ALD method, for example. The insulating film is preferably formed by an ALD method. Like the insulator 250 described above, the insulator 250 is preferably formed to have a small thickness, and a variation in the film thickness needs to be reduced. Since an ALD method is a film formation method in which a precursor and a reactant (e.g., oxidizer) are alternately introduced and the film thickness can be adjusted with the number of repetition times of the cycle, accurate control of the film thickness is possible. Furthermore, as illustrated in FIG. 9B, the insulator 250 needs to be formed on the bottom surface and the side surface of the opening so as to have good coverage.

By an ALD method, atomic layers can be formed one by one on the bottom surface and the side surface of the opening, whereby the insulator 250 can be formed in the opening with good coverage.

When the insulating film to be the insulator 250 is formed by an ALD method, ozone (O₃), oxygen (O₂), water (H₂O), or the like can be used as the oxidizer. When an oxidizer without including hydrogen, such as ozone (O₃) or oxygen (O₂), is used, the amount of hydrogen diffusing into the oxide 230b can be reduced.

The insulator 250 can have a stacked-layer structure as illustrated in FIG. 3A and FIG. 3B. In that case, an aluminum oxide film can be formed as an insulating film to be the insulator 250a by a thermal ALD method, a silicon oxide film can be formed as an insulating film to be the insulator 250b by a PEALD method, and a silicon nitride film can be formed as an insulating film to be the insulator 250c by a PEALD method. Furthermore, the insulator 250b may have a stacked-layer structure. In that case, for the insulating film to be the insulator 250b, a silicon oxide film can be formed by a PEALD method, and a hafnium oxide film can be formed thereover by a thermal ALD method.

Next, it is preferable to perform microwave treatment in an atmosphere including oxygen. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz. Note that in the case where the insulator 250 has a stacked-layer structure, the microwave treatment is not necessarily performed after all the insulating films to be the insulator 250 are formed. For example, microwave treatment may be performed after the insulating film to be the insulator 250a and the insulating film to be the insulator 250b are formed, and then the insulating film to be the insulator 250c may be formed.

The microwave treatment is preferably performed with a microwave treatment apparatus including a power source for generating high-density plasma using microwaves, for example. Here, the frequency of the microwave treatment apparatus is preferably set to greater than or equal to 300 MHz and less than or equal to 300 GHz, further preferably greater than or equal to 2.4 GHz and less than or equal to 2.5 GHZ, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 230b efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably set to lower than or equal to 750° C., further preferably lower than or equal to 500° C., and can be approximately 250° C., for example. The oxygen plasma treatment can be followed successively by heat treatment without exposure to air. The temperature of the heat treatment is preferably set to higher than or equal to 100° C. and lower than or equal to 750° C., further preferably higher than or equal to 300° C. and lower than or equal to 500° C., for example.

Furthermore, the microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The carrier concentration in the oxide 230b can be reduced by performing the microwave treatment in an atmosphere including oxygen. In addition, the carrier concentrations in the oxide 230b can be prevented from being excessively reduced by preventing an excess amount of oxygen from being introduced into the chamber in the microwave treatment.

The microwave treatment in an atmosphere including oxygen can convert an oxygen gas into plasma using a high-frequency wave such as a microwave or RF, and apply the oxygen plasma to a region of the oxide 230b which is between the conductor 242a and the conductor 242b. By the effect of the plasma, the microwave, or the like, VoH in the region can be divided into an oxygen vacancy and hydrogen, and hydrogen can be removed from the region. That is, VoH included in the channel formation region can be reduced. Accordingly, oxygen vacancies and VoH in the channel formation region can be reduced to lower the carrier concentration. In addition, oxygen radicals generated by the oxygen plasma can be supplied to oxygen vacancies in the channel formation region, thereby further reducing oxygen vacancies in the channel formation region and lowering the carrier concentration.

The oxygen implanted into the channel formation region has any of a variety of forms such as an oxygen atom, an oxygen molecule, an oxygen ion, and an oxygen radical (also referred to as O radical, which is an atom, a molecule, or an ion having an unpaired electron). Note that the oxygen implanted into the channel formation region has any one or more of the above forms, particularly suitably an oxygen radical. Furthermore, the film quality of the insulator 250 can be improved, leading to higher reliability of the transistor.

Meanwhile, the oxide 230b includes a region overlapping with the conductor 242a or 242b. The region can function as a source region or a drain region. Here, the conductors 242a and 242b preferably function as blocking films preventing the effect caused by the high-frequency wave such as a microwave or RF, the oxygen plasma, or the like in the microwave treatment in an atmosphere including oxygen. Thus, the conductors 242a and 242b preferably have a function of blocking an electromagnetic wave of greater than or equal to 300 MHz and less than or equal to 300 GHz, for example, greater than or equal to 2.4 GHz and less than or equal to 2.5 GHz.

The effect of the high-frequency wave such as a microwave or RF, the oxygen plasma, or the like is blocked by the conductors 242a and 242b and does not affect the region of the oxide 230b overlapping with the conductor 242a or 242b. Hence, a reduction in VoH and supply of an excess amount of oxygen do not occur in the source region and the drain region in the microwave treatment, preventing a decrease in carrier concentration.

Furthermore, the insulator 250 having a barrier property against oxygen is provided in contact with the side surfaces of the conductors 242a and 242b. This can inhibit formation of oxide films on the side surfaces of the conductors 242a and 242b by the microwave treatment.

Furthermore, the film quality of the insulator 250 can be improved, leading to higher reliability of the transistor.

In the above manner, oxygen vacancies and VoH can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited, and the conductivity (the state of the low-resistance regions) before the microwave treatment is performed can be maintained. As a result, a change in the electrical characteristics of the transistor can be inhibited, and thus a variation in the electrical characteristics of transistors in the substrate plane can be inhibited.

In the microwave treatment, thermal energy is directly transmitted to the oxide 230b in some cases owing to an electromagnetic interaction between the microwave and a molecule in the oxide 230b. The oxide 230b may be heated by this thermal energy. Such heat treatment is sometimes referred to as microwave annealing. When microwave treatment is performed in an atmosphere including oxygen, an effect equivalent to that of oxygen annealing is sometimes obtained. In the case where hydrogen is included in the oxide 230b, it is probable that the thermal energy is transmitted to the hydrogen in the oxide 230b and the hydrogen activated by the energy is released from the oxide 230b.

Note that microwave treatment may be performed before the formation of the insulating film to be the insulator 250, without the microwave treatment performed after the formation of the insulating film.

After the microwave treatment following the formation of the insulating film to be the insulator 250, heat treatment may be performed with the reduced pressure being maintained. Such treatment enables hydrogen in the insulating film, the oxide 230b, and the oxide 230a to be removed efficiently. Part of hydrogen is gettered by the conductors 242a and 242b in some cases. Alternatively, the step of performing microwave treatment and then performing heat treatment with the reduced pressure being maintained may be repeated a plurality of cycles. The repetition of the heat treatment enables hydrogen in the insulating film, the oxide 230b, and the oxide 230a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are adequately heated by the microwave annealing.

Furthermore, the microwave treatment improves the film quality of the insulating film to be the insulator 250, thereby inhibiting diffusion of hydrogen, water, impurities, and the like. Accordingly, hydrogen, water, impurities, and the like can be inhibited from diffusing into the oxide 230b, the oxide 230a, and the like through the insulator 250 in a later step such as formation of a conductive film to be the conductor 260 or later treatment such as heat treatment.

Next, a conductive film to be the conductor 260a and a conductive film to be the conductor 260b are formed in this order. The conductive film to be the conductor 260a and the conductive film to be the conductor 260b can each be formed by a sputtering method, a CVD method, an MBE method, a PLD method, or an ALD method, for example. In this embodiment, a titanium nitride film is formed as the conductive film to be the conductor 260a by an ALD method, and a tungsten film is formed as the conductive film to be the conductor 260b by a CVD method.

Then, the insulating film to be the insulator 250, the conductive film to be the conductor 260a, and the conductive film to be the conductor 260b are polished by CMP treatment until the insulator 280 is exposed. That is, portions of the insulating film to be the insulator 250, the conductive film to be the conductor 260a, and the conductive film to be the conductor 260b that are exposed outside the opening are removed. Thus, the insulator 250, and the conductor 260 (the conductor 260a and the conductor 260b) are formed in the opening overlapping with the conductor 205 (FIG. 9B).

Accordingly, the insulator 250 is provided in contact with the inner wall and the side surface of the opening overlapping with the oxide 230b. The conductor 260 is placed to fill the opening with the insulator 250 therebetween. In this manner, the transistors 202a and 202b are formed. As described above, the transistors 202a and 202b can be manufactured in parallel through the same steps.

Subsequently, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 280. After the heat treatment, the insulator 282 may be successively formed without exposure to the air.

Next, the insulator 282 is formed over the insulator 250, the conductor 260, and the insulator 280 (FIG. 9C). The insulator 282 can be formed by a sputtering method, a CVD method, an MBE method, a PLD method, or an ALD method, for example. The insulator 282 is preferably formed by a sputtering method. By using a sputtering method that does not need to use a molecule including hydrogen as a film formation gas, the hydrogen concentration in the insulator 282 can be reduced.

In this embodiment, for the insulator 282, an aluminum oxide film is formed by a pulsed DC sputtering method using an aluminum target in an atmosphere including an oxygen gas. The use of the pulsed DC sputtering method can achieve more uniform film thickness and improve the sputtering rate and film quality. The RF power applied to the substrate is lower than or equal to 1.86 W/cm², preferably higher than or equal to 0 W/cm² and lower than or equal to 0.62 W/cm². Note that the RF power of 0 W/cm² means no application of RF power to the substrate. The amount of oxygen implanted into a layer below the insulator 282 can be controlled depending on the amount of the RF power applied to the substrate. For example, the amount of oxygen implanted into the layer below the insulator 282 decreases as the RF power decreases, and the amount of oxygen is easily saturated even when the insulator 282 has a small thickness. Moreover, the amount of oxygen implanted into the layer below the insulator 282 increases as the RF power increases. With low RF power, the amount of oxygen implanted into the insulator 280 can be reduced. Alternatively, the insulator 282 may have a stacked-layer structure of two layers. In that case, for example, the lower layer of the insulator 282 is formed with an RF power of 0 W/cm² applied to the substrate, and the upper layer of the insulator 282 is formed with an RF power of 0.62 W/cm² applied to the substrate.

The RF frequency is preferably 10 MHz or higher. The typical frequency is 13.56 MHz. The higher the RF frequency is, the less damage the substrate receives.

When the insulator 282 is formed by a sputtering method in an atmosphere including oxygen, oxygen can be added to the insulator 280 during the film formation. Thus, excess oxygen can be included in the insulator 280. At this time, the insulator 282 is preferably formed while the substrate is being heated.

Next, the insulator 283 is formed over the insulator 282 (FIG. 9C). The insulator 283 can be formed by a sputtering method, a CVD method, an MBE method, a PLD method, or an ALD method, for example. The insulator 283 is preferably formed by a sputtering method. By using a sputtering method that does not need to use a molecule including hydrogen as a film formation gas, the hydrogen concentration in the insulator 283 can be reduced. In this embodiment, for the insulator 283, a silicon nitride film is formed by a sputtering method.

Next, the insulator 285 is formed over the insulator 283 (FIG. 9C). The insulator 285 can be formed by a sputtering method, a CVD method, an MBE method, a PLD method, or an

ALD method, for example. The insulator 285 is preferably formed by a sputtering method. By using a sputtering method that does not need to use a molecule including hydrogen as a film formation gas, the hydrogen concentration in the insulator 285 can be reduced. In this embodiment, for the insulator 285, a silicon oxide film is formed by a sputtering method.

Here, the capacitance of the capacitor 101a is preferably set by adjusting the thickness of the insulator 285. For example, the thickness of the insulator 285 is set to be greater than or equal to 50 nm and less than or equal to 250 nm, and the depth of the opening in which the capacitor 101a is formed is approximately greater than or equal to 150 nm and less than or equal to 350 nm. When the capacitor 101a is formed within such ranges, sufficient capacitance can be provided for the capacitor 101a, and the level of one layer in a semiconductor device where a plurality of layers of memory cells are stacked can be prevented from being excessively high.

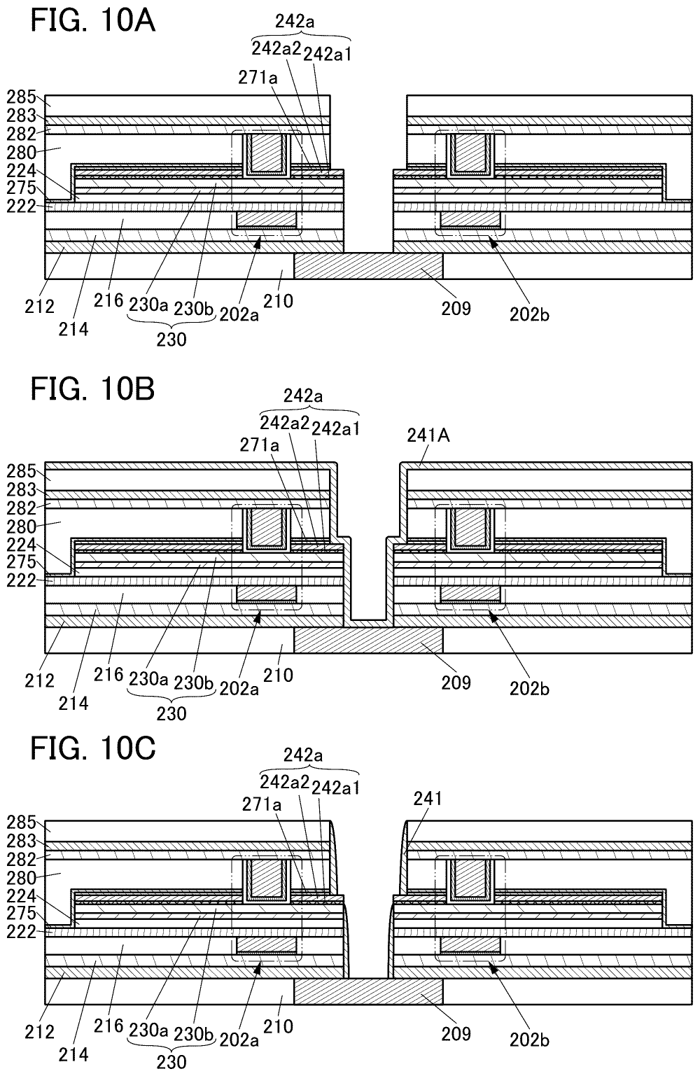

Next, the insulators 285, 283, 282, 280, 275, 271a, 222, 216, 214, and 212 are processed by a lithography method to form an opening where part of the top surface of the conductor 209 is exposed (FIG. 10A). The opening is preferably formed so that part of the top surface of the conductor 242a is exposed in the top view. The opening can have a circular shape, an almost circular shape such as an elliptical shape, a polygonal shape such as a quadrangular shape, or a polygonal shape such as a quadrangular shape with rounded corners in the top view.

A dry etching method or a wet etching method can be used for forming the opening. A dry etching method is preferably used because processing by a dry etching method is suitable for microfabrication. As an etching gas, the above-described gas can be used.

Here, aluminum oxide and hafnium oxide are sometimes more difficult to etch than silicon oxide or silicon oxynitride. It can also be said that aluminum oxide and hafnium oxide are each a hard-to-etch material.

In the case where the above-described hard-to-etch material is used for the insulators 282 and 222 and the like, forming openings in the insulators in advance enables the processing step in FIG. 10A to be performed with high yield and the productivity of the semiconductor device to be improved. Meanwhile, forming an opening in the insulators at a time in the processing step in FIG. 10A enables the number of masks to be reduced, which is preferable.

Although FIG. 10A illustrates an example in which the width of the opening provided in the insulators 285, 283, 282, 280, 275, and 271a is substantially constant, one embodiment of the present invention is not limited thereto. In the case where one or more of the insulators 285, 283, 282, 280, 275, and 271a have different etching rates, even when the opening is formed at a time, end portions of the insulators 285, 283, 282, 280, 275, and 271a are not aligned with each other in some cases in a cross-sectional view.

Although FIG. 10A illustrates an example in which the end portion of the conductor 242a and end portions of the insulators 212, 214, 216, and 222 are substantially aligned with each other in the opening, the present invention is not limited thereto. Depending on etching conditions or the like, one or more of the insulators 212, 214, 216, and 222 may be side-etched, whereby the end portion(s) thereof may be positioned on the inner side (the transistor side) with respect to the end portion of the conductor 242a.

For example, the opening is preferably formed in the insulator 212, the insulator 214, the insulator 216, the insulator 222, the insulator 271a, the insulator 275, the insulator 280, the insulator 282, the insulator 283, and the insulator 285 by anisotropic etching. A dry etching method is preferably employed for the anisotropic etching. This enables formation of the opening having the shape illustrated in FIG. 1, for example.

Next, an insulating film 241A is formed (FIG. 10B). As the insulating film 241A, an insulating film having a function of inhibiting diffusion of at least one of oxygen and hydrogen is preferably used. For example, a silicon nitride film is preferably formed by a PEALD method. Silicon nitride is preferable because of its high blocking property against oxygen and hydrogen.

Note that the insulating film 241A may have a stacked-layer structure. As the insulating film 241A, an aluminum oxide film may be formed by an ALD method and a silicon nitride film may be formed thereover by a PEALD method, for example. In the case where the insulating film 241A is formed by an ALD method, an aluminum oxide film can be formed at a lower temperature than a silicon nitride film. Thus, when the aluminum oxide film is formed before the formation of the silicon nitride film, oxidation of the conductor 260, the conductor 242, and the like can be inhibited.

Next, the insulating film 241A is subjected to anisotropic etching, so that the insulator 241 is formed in contact with a sidewall of the opening formed in the insulators 285, 283, 282, 280, 275, 271a, 222, 216, 214, and 212 (FIG. 10C). Here, at least part of the conductor 242a is exposed from the insulator 241. For the anisotropic etching of the insulating film 241A, a dry etching method may be employed, for example. When the insulator 241 is provided on a side wall portion of the opening, passage of oxygen from the outside can be inhibited, and oxidation of the conductor 240 to be formed next can be prevented. Furthermore, impurities such as water and hydrogen included in the conductor 240, the insulator 280, and the like can be prevented from diffusing into the oxide 230.

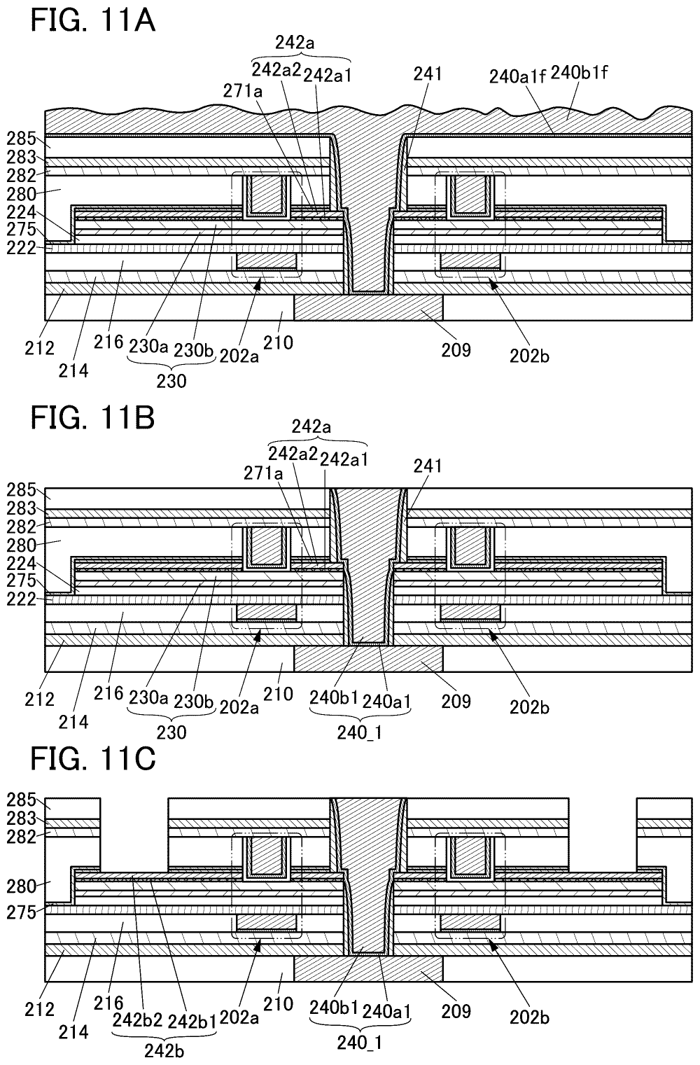

Next, a conductive film 240a1f and a conductive film 240b1f are formed in this order (FIG. 11A). Here, part of the conductive film 240a1f is in contact with the conductor 242a through the opening in the insulator 241. The conductive film 240a1f preferably has a function of inhibiting passage of impurities such as water and hydrogen. For example, tantalum nitride or titanium nitride can be used for the conductive film 240b1f. For example, tungsten, molybdenum, or copper can be used for the conductive film 240a1f. These conductive films can each be formed by a sputtering method, a CVD method, an MBE method, a PLD method, or an ALD method, for example.

Next, by performing CMP treatment, the conductive film 240a1f and the conductive film 240b If are partly removed to expose the top surface of the insulator 285. As a result, these conductive films remain only in the opening, so that the conductor 240_1 (the conductor 240al and the conductor 240b1) having a flat top surface can be formed (FIG. 11B). Note that the top surface of the insulator 285 is partly removed by the CMP treatment in some cases. Thus, the conductor 240 electrically connected to the conductor 209 and the conductor 242a can be formed.

Next, the insulators 285, 283, 282, 280, 275, and 271b are processed by a lithography method to form an opening reaching the conductor 242b (FIG. 11C).

The width of the opening provided in this step is preferably minute. For example, the width of the opening is preferably less than or equal to 200 nm, less than or equal to 100 nm, less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm. In order to form such a minute opening, an electron beam or short-wavelength light such as EUV light is preferably used for the lithography method. The opening can have a circular shape, an almost circular shape such as an elliptical shape, a polygonal shape such as a quadrangular shape, or a polygonal shape such as a quadrangular shape with rounded corners in the top view.

Since the opening provided in this step has a high aspect ratio, part of the insulator 285, part of the insulator 283, part of the insulator 282, part of the insulator 280, part of the insulator 275, and part of the insulator 271b, are preferably processed by anisotropic etching. Processing by a dry etching method is particularly preferable because it is suitable for microfabrication. The processing may be performed under different conditions.

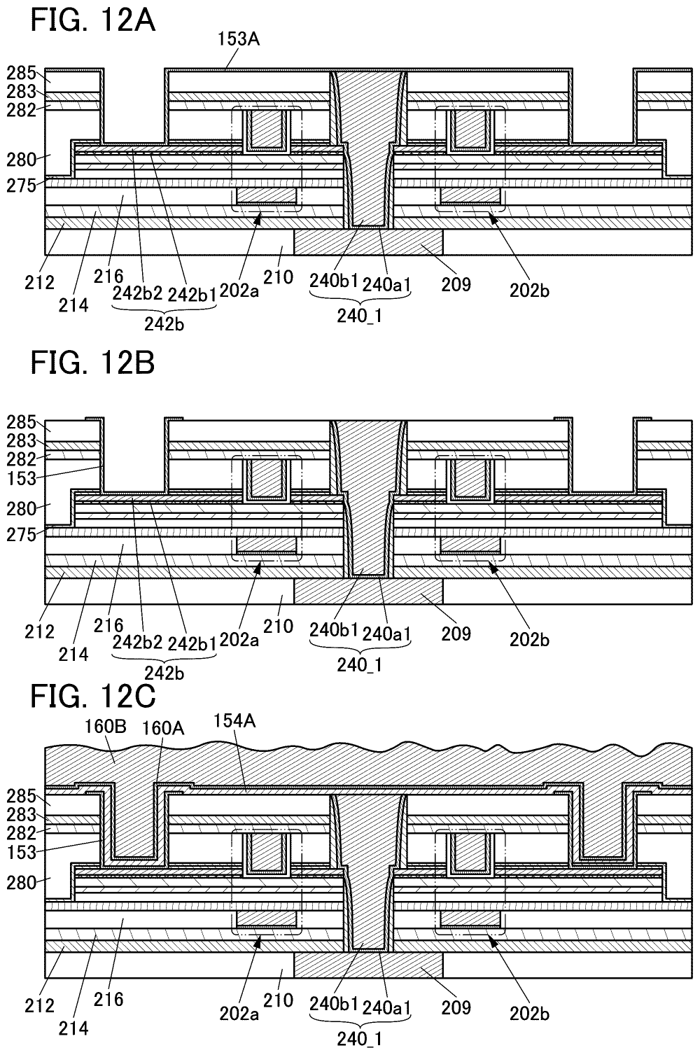

Next, a conductive film 153A to be the conductor 153 is formed to cover the opening and the insulator 285 (FIG. 12A). The conductive film 153A is preferably formed in contact with the side surface and the bottom surface of the opening. Thus, the conductive film 153A is preferably formed by a film formation method that offers excellent coverage, such as an ALD method or a CVD method. For example, a film of titanium nitride or tantalum nitride is preferably formed by an ALD method or a CVD method.

Next, a resist mask is provided over the conductive film 153A, and the conductive film 153A is processed by a lithography method to form the conductor 153 (FIG. 12B). Accordingly, part of the conductor 153 is formed in the opening, and the other part is in contact with part of the top surface of the insulator 282.

The conductive film 153A may be processed by a CMP method. In this case, a shape can be obtained in which the uppermost portion of the conductor 153 is substantially level with the top surface of the insulator 282.

Next, an insulating film 154A to be the insulator 154 is formed over the conductor 153 (FIG. 12C). The insulating film 154A is preferably formed in contact with the conductor 153 that is provided inside the opening. Thus, the insulating film 154A is preferably formed by a film formation method that offers excellent coverage, such as an ALD method or a CVD method. The insulating film 154A is preferably formed using the above-described high-k material.

Next, a conductive film 160A to be the conductor 160a and a conductive film 160B to be the conductor 160b are formed in this order (FIG. 12C). The conductive film 160A is preferably formed in contact with the insulating film 154A provided inside the opening, and the conductive film 160B is preferably formed to fill the opening. Thus, the conductive film 160A and the conductive film 160B are each preferably formed by a film formation method that offers excellent coverage, such as an ALD method or a CVD method. For example, it is preferable that a titanium nitride film be formed for the conductive film 160A by an ALD method or a CVD method and a tungsten film be formed for the conductive film 160B by a CVD method.

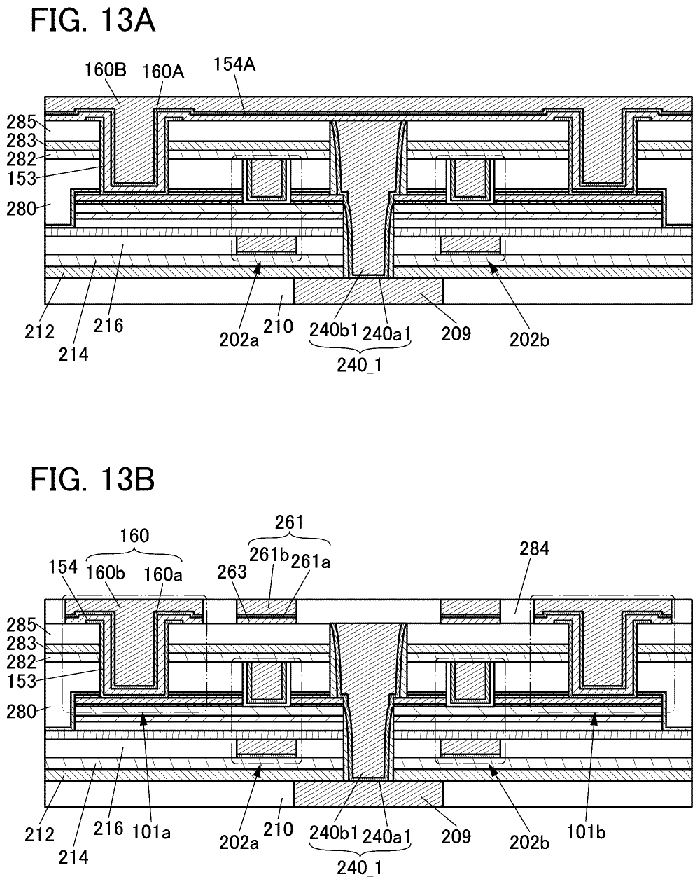

In the case where the conductive film 160B is formed by a CVD method, the average surface roughness of the top surface of the conductive film 160B is sometimes large as illustrated in FIG. 12C. In that case, the conductive film 160B is preferably planarized by a CMP method as illustrated in FIG. 13A.

Next, the insulating film 154A, the conductive film 160A, and the conductive film 160B are processed by a lithography method to form the insulator 154, the conductor 160a, the conductor 160b, the insulator 263, the conductor 261a, and the conductor 261b (FIG. 13B). At that time, the insulator 154, the conductor 160a, and the conductor 160b are preferably formed to cover the side end portion of the conductor 153. With such a structure, the conductor 160 and the conductor 153 can be separated from each other by the insulator 154, so that a short circuit between the conductor 160 and the conductor 153 can be inhibited.

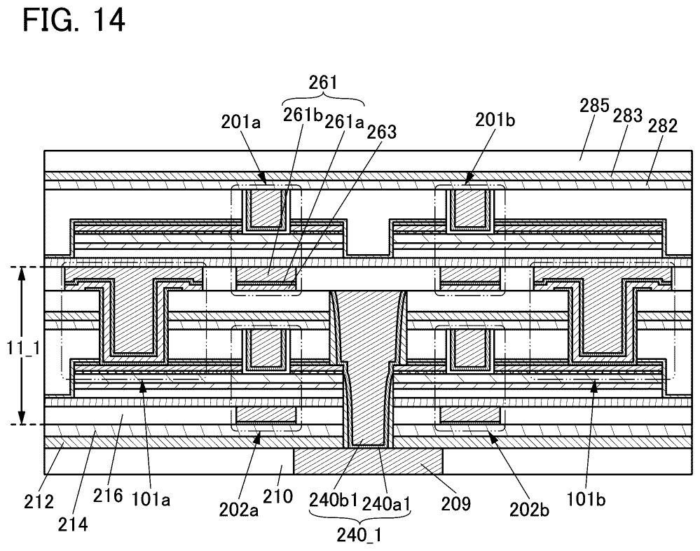

As described above, the conductor 160 in the lower layer (i.e., the upper electrodes of the capacitors 101a and 101b illustrated in FIG. 13B) and the conductor 261 in the upper layer (i.e., the back gate electrodes of the transistors 201a and 201b illustrated in FIG. 14) are formed from the conductive film 160A and the conductive film 160B; thus, the conductor 160 in the lower layer includes the same material as the conductor 261 in the upper layer. Since the insulator 154 in the lower layer and the insulator 263 in the upper layer are formed from the insulating film 154A, the insulator 154 in the lower layer includes the same material as the insulator 263 in the upper layer.

As described above, when the conductor 160 and the insulator 154 in the lower layer and the conductor 261 and the insulator 263 in the upper layer are formed at the same time, the number of manufacturing steps of the semiconductor device of this embodiment can be reduced and the productivity of the semiconductor device can be improved.

Although an example in which the insulating film 154A is processed is described above, the present invention is not limited thereto. A structure may be employed in which only the conductive film 160A and the conductive film 160B are processed and the insulating film 154A is left without being processed. Accordingly, the processing step for the insulator 154 can be eliminated, and the productivity can be improved.

Although the structure in which the upper electrode (the conductor 160) of the capacitor 101a and the second gate electrode (the conductor 261) of the transistor 201a are provided separately is described above, the present invention is not limited thereto. As illustrated in FIG. 2B, only the insulator 154, the conductor 160a, and the conductor 160b can be formed from the insulating film 154A, the conductive film 160A, and the conductive film 160B. In that case, the conductor 160 serves as the upper electrode of the capacitor 101a and the second gate electrode of the transistor 201a.

In the above manner, the capacitors 101a and 101b can be formed.

After that, the insulator 284 is preferably provided to fill a gap between the conductor 160 and the conductor 261 adjacent to each other (FIG. 13B). The insulator 284 is preferably planarized by a CMP method.

Then, the second layer 11_2 and the layers above the second layer 11_2 can be manufactured by repeating the above-described steps from the formation of the insulator 222 (FIG. 7B) to the manufacturing of the capacitors 101a and 101b (FIG. 13B). FIG. 14 illustrates a cross-sectional structure example at the time when the formation of the insulator 285 in the second layer 11_2 is completed, for example. Note that as illustrated in FIG. 14, the conductor 261 formed in the step illustrated in FIG. 13B is provided to overlap with the first gate electrode of each of the transistors 201a and 201b and functions as the second gate electrode of each of the transistors 201a and 201b.

Through the above steps, the semiconductor device illustrated in FIG. 1 can be manufactured.

The semiconductor device of this embodiment includes OS transistors. Since the off-state current of the OS transistors is low, a semiconductor device or a memory device with low power consumption can be achieved. Since the OS transistors have high frequency characteristics, a semiconductor device or a memory device with high operating speed can be achieved. With use of the OS transistors, a semiconductor device having favorable electrical characteristics, a semiconductor device with a small variation in electrical characteristics of transistors, a semiconductor device with a high on-state current, or a highly reliable semiconductor device or memory device can be achieved.

Since the semiconductor device of this embodiment includes the conductor 240 having the stacked-layer structure of the plurality of conductors, the manufacturing yield thereof can be increased as compared with the case of using one conductor.

This embodiment can be combined with the other embodiments as appropriate. In this specification, in the case where a plurality of structure examples are described in one embodiment, the structure examples can be combined as appropriate.

### Embodiment 2

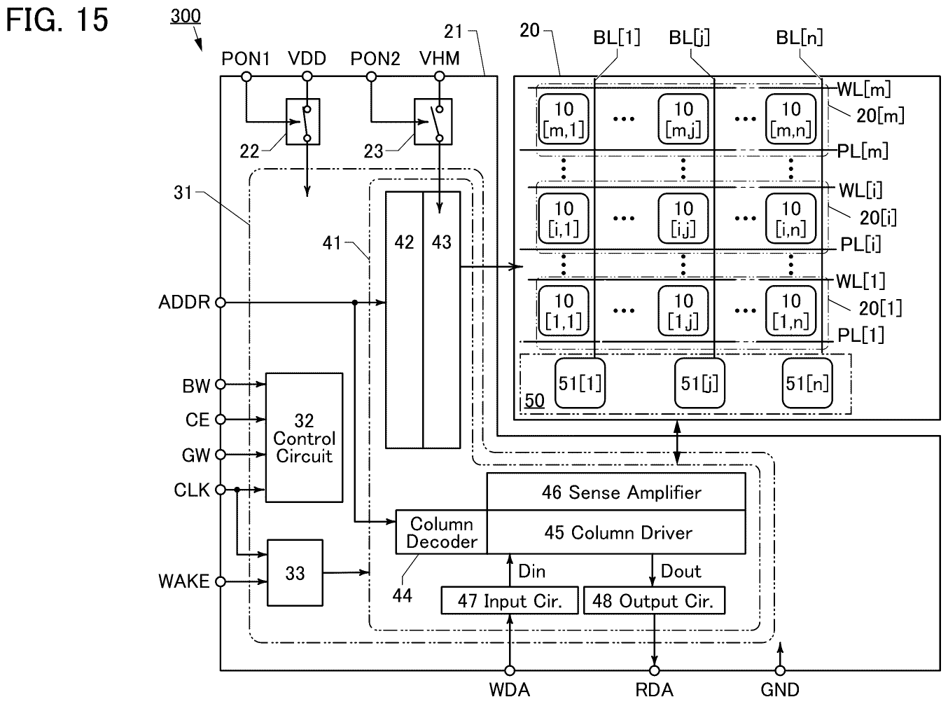

In this embodiment, a memory device of one embodiment of the present invention will be described with reference to FIG. 15 to FIG. 21.

In this embodiment, structure examples of memory devices using the semiconductor device described in the above embodiment as memory cells are described. In this embodiment, structure examples of memory devices in which a layer including a functional circuit having functions of amplifying and outputting a data potential retained in a memory cell is provided between stacked layers including memory cells are described.

### [Structure Example of Memory Device]

FIG. 15 shows a block diagram of the memory device of one embodiment of the present invention.

A memory device 300 shown in FIG. 15 includes the driver circuit 21 and the memory array 20. The memory array 20 includes the plurality of memory cells 10 and the functional layer 50 including a plurality of functional circuits 51.

FIG. 15 shows an example in which the memory array 20 includes the plurality of memory cells 10 arranged in a matrix of m rows and n columns (each of m and n is an integer greater than or equal to 2). In the example shown in FIG. 15, the functional circuit 51 is provided for each wiring BL functioning as a bit line and the functional layer 50 includes the plurality of functional circuits 51 which are provided to correspond to n wirings BL.

In FIG. 15, the memory cell 10 in the first row and the first column is referred to as a memory cell 10[1,1], and the memory cell 10 in the m-th row and the n-th column is referred to as a memory cell 10[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is referred to as a memory cell 10[i,j]. Note that in this embodiment and the like, “i+α” (a is a positive or negative integer) is not below 1 and does not exceed m. Similarly, “j+α” is not below 1 and does not exceed n.

The memory array 20 includes m wirings WL extending in the row direction, m wirings PL extending in the row direction, and n wirings BL extending in the column direction. In this embodiment and the like, a first (first row) wiring WL is referred to as a wiring WL[1] and an m-th (m-th row) wiring WL is referred to as a wiring WL[m]. Similarly, a first (first row) wiring PL is referred to as a wiring PL[1] and an m-th (m-th row) wiring PL is referred to as a wiring PL[m]. Similarly, a first (first column) wiring BL is referred to as a wiring BL[1] and an n-th (n-th column) wiring BL is referred to as a wiring BL[n].

The plurality of memory cells 10 provided in the i-th row are electrically connected to the wiring WL in the i-th row (wiring WL[i]) and the wiring PL in the i-th row (wiring PL[i]). The plurality of memory cells 10 provided in the j-th column are electrically connected to the wiring BL in the j-th column (wiring BL[j]).

A DOSRAM (registered trademark) (Dynamic Oxide Semiconductor Random Access Memory) can be used for the memory array 20. A DOSRAM is a RAM including a 1T (transistor) 1C (capacitor) type memory cell and refers to a memory in which an access transistor is an OS transistor. An OS transistor has extremely low current that flows between a source and a drain in an off state, that is, leakage current. A DOSRAM can retain electric charge corresponding to data stored in a capacitor for a long time by turning off an access transistor (a non-conduction state). For this reason, the refresh operation frequency of a DOSRAM can be lower than that of a DRAM formed with a transistor including silicon in its channel formation region (a Si transistor). As a result, power consumption can be reduced.

The memory cells 10 can be provided in stacked layers by stacking OS transistors as described in Embodiment 1 and the like. For example, in the memory array 20 shown in FIG. 15, a plurality of memory arrays 20[1] to 20[m] can be provided in stacked layers. When the memory arrays 20[1] to 20[m] included in the memory array 20 are provided in a direction perpendicular to a surface of the substrate provided with the driver circuit 21, the memory density of the memory cells 10 can be improved. The memory array 20 can be formed by repeating the same manufacturing process in the perpendicular direction. The manufacturing cost of the memory array 20 in the memory device 300 can be reduced.

The wiring BL functions as a bit line for writing and reading data. The wiring WL functions as a word line for controlling on and off states (conduction and non-conduction states) of an access transistor serving as a switch. The wiring PL has a function of a constant potential line connected to a capacitor. Note that a wiring CL (not shown) can be additionally provided as a wiring having a function of supplying a backgate potential to a backgate of an OS transistor serving as the access transistor. The wiring PL may also have a function of supplying the backgate potential.

The memory cell 10 included in each of the memory arrays 20[1] to 20[m] is connected to the functional circuit 51 through the wiring BL. The wiring BL can be provided in the direction perpendicular to the surface of the substrate provided with the driver circuit 21. Since the wiring BL provided to extend from the memory cells 10 included in the memory arrays 20[1] to 20[m] is provided in the direction perpendicular to the surface of the substrate, the length of the wiring between the memory array 20 and the functional circuit 51 can be shortened. Accordingly, a signal transmission distance between the two circuits connected to the bit line can be shortened, and the resistance and parasitic capacitance of the bit line can be significantly reduced, so that power consumption and signal delays can be reduced. Moreover, even when the capacitance of the capacitors included in the memory cells 10 is reduced, operation is possible.

The functional circuit 51 has functions of amplifying a data potential retained in the memory cell 10 and outputting the amplified data potential to a sense amplifier 46 included in the driver circuit 21 through a wiring GBL (not shown) described later. With this structure, a slight difference in the potential of the wiring BL can be amplified at the time of data reading. Like the wiring BL, the wiring GBL can be provided in the direction perpendicular to the surface of the substrate provided with the driver circuit 21. Since the wiring BL and the wiring GBL provided to extend from the memory cells 10 included in the memory arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced, so that power consumption and signal delays can be reduced.

Note that the wiring BL is provided in contact with the semiconductor layer of the transistor included in the memory cell 10. Alternatively, the wiring BL is provided in contact with the region functioning as the source or the drain in the semiconductor layer of the transistor included in the memory cell 10. Alternatively, the wiring BL is provided in contact with the conductor provided in contact with the region functioning as the source or the drain in the semiconductor layer of the transistor included in the memory cell 10. That is, the wiring BL is a wiring for electrically connecting one of the source and the drain of the transistor included in the memory cell 10 in each layer of the memory array 20 to the functional circuit 51 in the perpendicular direction.

The memory array 20 can be provided over the driver circuit 21 to overlap therewith. When the driver circuit 21 and the memory array 20 are provided to overlap with each other, a signal transmission distance between the driver circuit 21 and the memory array 20 can be shortened. Accordingly, resistance and parasitic capacitance between the driver circuit 21 and the memory array 20 are reduced, so that power consumption and signal delays can be reduced. In addition, the memory device 300 can be downsized.

The functional circuit 51 can be provided in any desired position, e.g., over a circuit that is formed using Si transistors in a manner similar to that of the memory arrays 20[1] to 20[m] when the functional circuit 51 is formed with an OS transistor like the transistor included in the memory cell 10 of the DOSRAM, whereby integration can be easily performed. With the structure in which a signal is amplified by the functional circuit 51, a circuit in a subsequent stage, such as the sense amplifier 46, can be downsized, so that the memory device 300 can be downsized. The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the memory device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 300. For example, the control circuit performs a logical operation on the signal CE, the signal GW, and the signal BW to determine an operation mode (e.g., a writing operation or a reading operation) of the memory device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 is a circuit which outputs signals for controlling the functional circuits 51. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 300. Data output from the output circuit 48 is the signal RDA.

The PSW 22 has a function of controlling supply of VDD to the peripheral circuit 31.

The PSW 23 has a function of controlling supply of VHM to the row driver 43. Here, in the memory device 300, a high power supply voltage is VDD and a low power supply voltage is GND (a ground potential). In addition, VHM is a high power supply voltage used to set a word line at a high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 15 but can be more than one. In that case, a power switch is provided for each power domain.

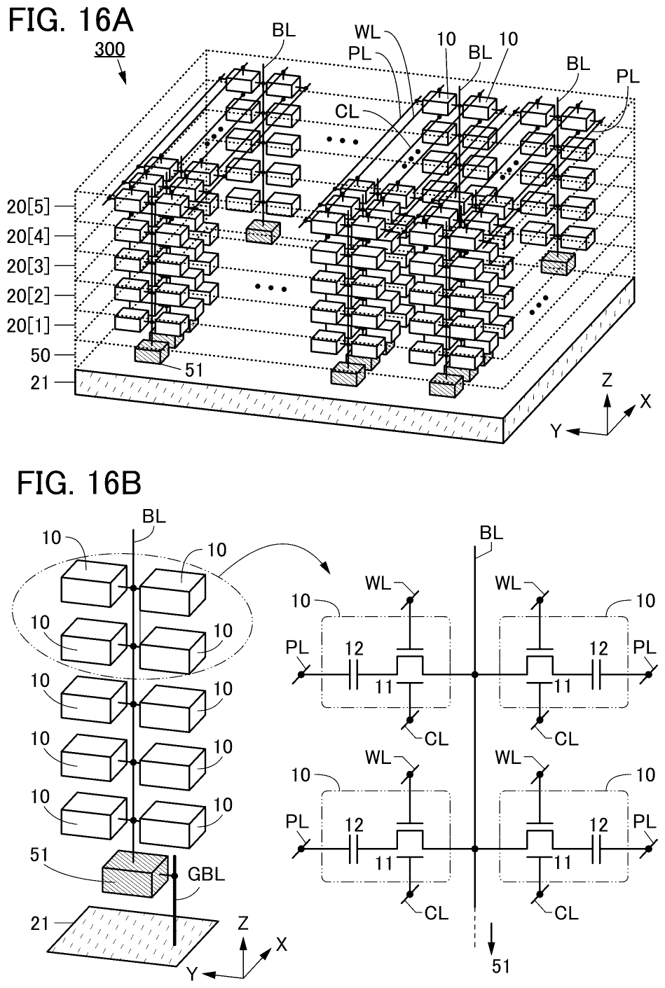

In the memory array 20 including the memory arrays 20[1] to 20[m] (m is an integer greater than or equal to 2) and the functional layer 50, the memory arrays 20 can be provided in stacked layers over the driver circuit 21. Stacking the memory arrays 20 in the plurality of layers can increase the memory density of the memory cells 10. FIG. 16A shows a perspective view of the memory device 300 which includes the functional layer 50 and five layers (m=5) of memory arrays 20[1] to 20[5], which overlap with each other, over the driver circuit 21.

In FIG. 16A, the memory array 20 in the first layer is denoted as the memory array 20[1], the memory array 20 in the second layer is denoted as the memory array 20[2], and the memory array 20 in the fifth layer is denoted as the memory array 20[5]. FIG. 16A also shows the wiring WL, the wiring PL, and the wiring CL provided to extend in the X direction and the wiring BL provided to extend in the Z direction (the direction perpendicular to the surface of the substrate provided with the driver circuit). For easy viewing of the drawing, some of the wirings WL and the wirings PL included in the memory arrays 20 are not shown.

FIG. 16B shows a schematic view for describing a structure example of the functional circuit 51, which is connected to the wiring BL, and the memory cells 10 included in the memory arrays 20[1] to 20[5], which are connected to the wiring BL, shown in FIG. 16A. FIG. 16B also shows the wiring GBL provided between the functional circuit 51 and the driver circuit 21. Note that a structure in which a plurality of memory cells (memory cells 10) are electrically connected to one wiring BL is also referred to as “memory string”. In the drawings, the wiring GBL is represented by a bold line for increasing visibility in some cases.

FIG. 16B shows an example of a circuit structure of the memory cell 10 connected to the wiring BL. The memory cell 10 includes a transistor 11 and a capacitor 12. As for the transistor 11, the capacitor 12, and the wirings (e.g., the wiring BL and the wiring WL), for example, the wiring BL[1] and the wiring WL[1] are referred to as the wiring BL and the wiring WL in some cases. Embodiment 1 can be referred to for a cross-sectional structure example of the memory cell 10 corresponding to this circuit structure.

The transistor 11 corresponds to the transistor 201a or the transistor 201b described in Embodiment 1. The capacitor 12 corresponds to the capacitor 101a or the capacitor 101b described in Embodiment 1. The wiring BL corresponds to the conductor 240 described in Embodiment 1.

As described in Embodiment 1, in the semiconductor device of one embodiment of the present invention, the wiring BL (the conductor 240) is directly in contact with at least one of the top surface, the side surface, and the bottom surface of the conductor 242a including a region functioning as one of a source electrode and a drain electrode of the transistor 11 (the transistor 201a). Thus, a separate electrode for connection does not need to be provided, so that the area occupied by the memory array 20 can be reduced. In addition, the integration degree of the memory cells 10 can be increased and the memory capacity of the memory device 300 can be increased.

In the memory cell 10, one of a source and a drain of the transistor 11 is connected to the wiring BL. The other of the source and the drain of the transistor 11 is connected to one electrode of the capacitor 12. The other electrode of the capacitor 12 is connected to the wiring PL. A gate of the transistor 11 is connected to the wiring WL. A back gate of the transistor 11 is connected to the wiring CL.

The wiring PL is a wiring for supplying a constant potential for retaining the potential of the capacitor 12. The wiring CL is a constant potential for controlling the threshold voltage of the transistor 11. The wiring PL and the wiring CL may have the same potential. In that case, the number of wirings connected to the memory cell 10 can be reduced by connecting the two wirings.

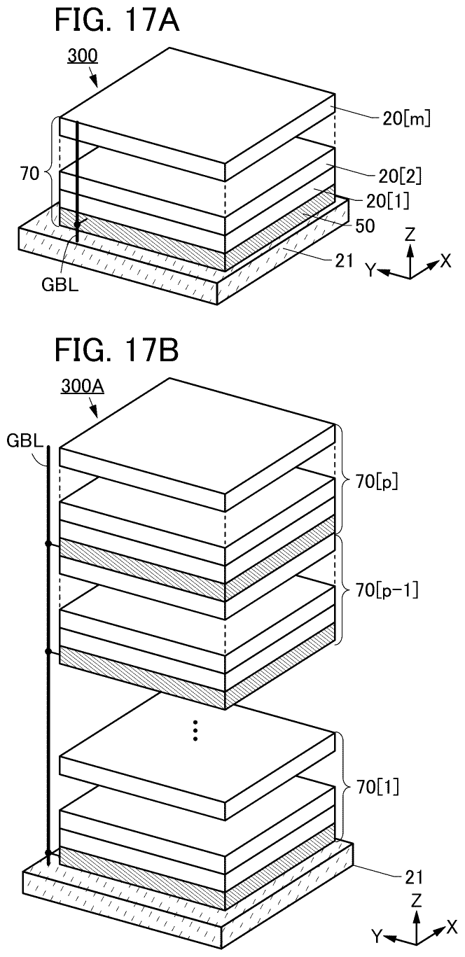

The wiring GBL shown in FIG. 16B is provided to electrically connect the driver circuit 21 and the functional layer 50. FIG. 17A shows a schematic view of the memory device 300 in which the functional circuit 51 and the memory arrays 20[1] to 20[m] are regarded as a repeating unit 70. Note that although FIG. 17A shows one wiring GBL, the wiring GBL is provided as appropriate depending on the number of functional circuits 51 provided in the functional layer 50.

Note that the wiring GBL is provided in contact with a semiconductor layer of a transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. That is, the wiring GBL can be regarded as a wiring for electrically connecting the driver circuit 21 and one of the source and the drain of the transistor included in the functional circuit 51 in the functional layer 50 in the perpendicular direction.

The repeating unit 70 including the functional circuit 51 and the memory arrays 20[1] to 20[m] may have a stacked-layer structure. A memory device 300A of one embodiment of the present invention can include repeating units 70[1] to 70[p] (p is an integer greater than or equal to 2) as shown in FIG. 17B. The wiring GBL is connected to the functional layers 50 included in the repeating unit 70. The wiring GBL is provided as appropriate depending on the number of functional circuits 51.

In one embodiment of the present invention, OS transistors are provided in stacked layers and a wiring functioning as a bit line is provided in the direction perpendicular to the surface of the substrate provided with the driver circuit 21. Since the wiring provided to extend from the memory array 20 and function as a bit line is provided in the direction perpendicular to the surface of the substrate, the length of the wiring between the memory array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the memory device 300 can be downsized. Moreover, even when the capacitance of the capacitors 12 included in the memory cells 10 is reduced, operation is possible.

[Structure examples of memory array 20 and functional circuit 51]

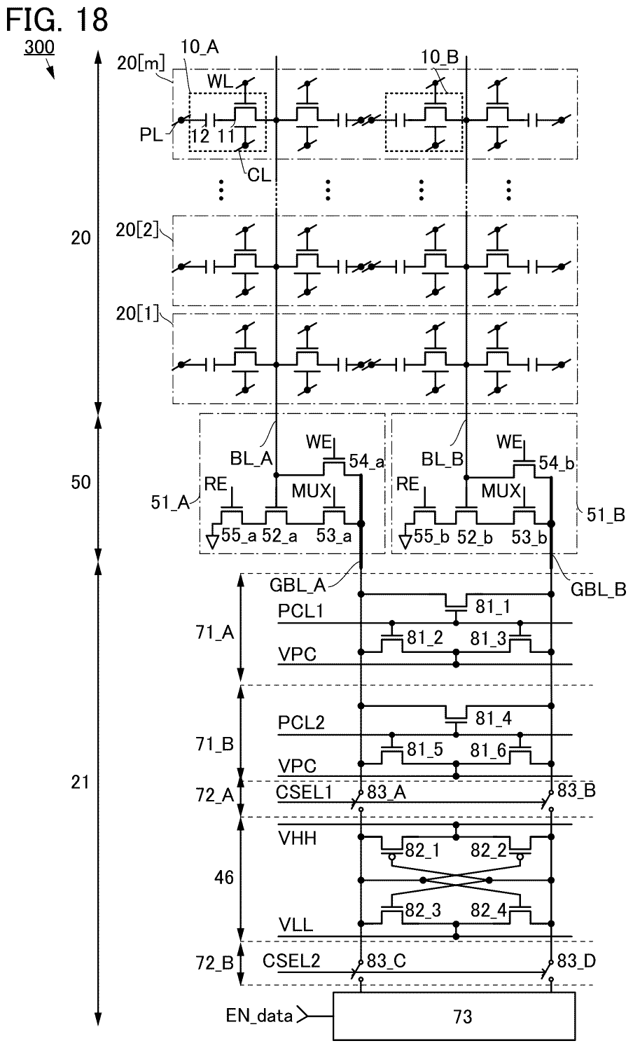

A structure example of the functional circuit 51 and structure examples of the memory array 20 and the sense amplifier 46 included in the driver circuit 21, which are described with reference to FIG. 15 to FIG. 17, are described with reference FIG. 18. FIG. 18 shows the driver circuit 21 connected to the wirings GBL (a wiring GBL_A and a wiring GBL_B) connected to the functional circuits 51 (a functional circuit 51_A and a functional circuit 51_B) connected to the memory cells 10 (a memory cell 10_A and a memory cell 10_B) connected to different wirings BL (a wiring BL_A and a wiring BL_B). FIG. 18 also shows, as the driver circuit 21, a precharge circuit 71_A, a precharge circuit 71_B, a switch circuit 72_A, a switch circuit 72_B, and a write/read circuit 73 in addition to the sense amplifier 46.

As the functional circuits 51_A and 51_B, transistors 52_a, 52_b, 53_a, 53_b, 54_a, 54_b, 55_a, and 55_b are shown. The transistors 52_a, 52_b, 53_a, 53_b, 54_a, 54_b, 55_a, and 55_b shown in FIG. 18 are OS transistors like the transistor 11 included in the memory cell 10. The functional layer 50 including the functional circuits 51 can be provided in stacked layers like the memory arrays 20[1] to 20[m].

The wiring BL_A is connected to a gate of the transistor 52_a, and the wiring BL_B is connected to a gate of the transistor 52_b. One of a source and a drain of each of the transistors 53_aand 54_ais connected to the wiring GBL_A. One of a source and a drain of each of the transistors 53_b and 54_b is connected to the wiring GBL_B. The wirings GBL_A and GBL_B are provided in the perpendicular direction like the wirings BL_A and BL_B and connected to transistors included in the driver circuit 21. As shown in FIG. 18, a selection signal MUX, a control signal WE, or a control signal RE is supplied to gates of the transistors 53_a, 53_b, 54_a, 54_b, 55_a, and 55_b.

Transistors 81_1 to 81_6 and 82_1 to 82_4 included in the sense amplifier 46, the precharge circuit 71_A, and the precharge circuit 71_B shown in FIG. 18 are Si transistors. Switches 83_A to 83_D included in the switch circuit 72_A and the switch circuit 72_B can also be Si transistors. The one of the source and the drain of each of the transistors 53_a, 53_b, 54_a, and 54_b is connected to the transistor or switch included in the precharge circuit 71_A, the precharge circuit 71_B, the sense amplifier 46, or the switch circuit 72_A.

The precharge circuit 71_A includes the n-channel transistors 81_1 to 81_3. The precharge circuit 71_A is a circuit for precharging the wiring BL_A and the wiring BL_B with an intermediate potential VPC corresponding to a potential VDD/2 between a high power supply potential (VDD) and a low power supply potential (VSS) in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes the p-channel transistors 82_1 and 82_2 and the n-channel transistors 82_3 and 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged by selecting the memory cells 10_A and 10_B are changed, and the potentials of the wiring GBL_A and the wiring GBL_B are set to VDD or VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on and off states of the switch circuit 72_A are switched under the control of a switch signal CSEL1. In the case where the switches 83_A and 83_B are n-channel transistors, the switches 83_A and 83_B are turned on and off when the switch signal CSEL1 is at a high level and a low level, respectively. The switch circuit 72_B is a circuit for controlling electrical continuity between the write/read circuit 73 and the bit line pair connected to the sense amplifier 46. The on and off states of the switch circuit 72_B are switched under the control of a switching signal CSEL2. The switches 83_C and 83_D are similar to the switches 83_A and 83_B.

As shown in FIG. 18, the memory device 300 can have a structure where the memory cell 10, the functional circuit 51, and the sense amplifier 46 are connected to each other through the wiring BL and the wiring GBL provided in the perpendicular direction which is the shortest distance. Even with addition of the functional layer 50 including transistors included in the functional circuit 51, the load of the wiring BL is reduced, whereby the writing time can be shortened and data reading can be facilitated.

As shown in FIG. 18, the transistors included in the functional circuits 51_A and 51_B are controlled in accordance with the control signals WE and RE and the selection signal MUX. The transistors can output the potential of the wiring BL through the wiring GBL to the driver circuit 21 in accordance with the control signals and the selection signal. The functional circuits 51_A and 51_B can function as a sense amplifier formed with OS transistors. With this structure, a slight difference in the potential of the wiring BL can be amplified at the time of reading to drive the sense amplifier 46 formed using Si transistors.

[Operation example of memory cell 20, functional circuit 51, and sense amplifier 46]

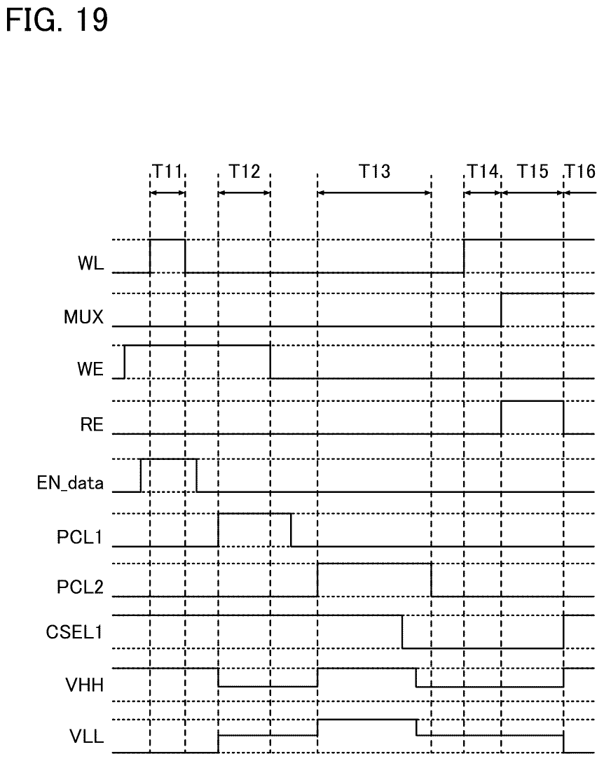

FIG. 19 shows a timing chart for describing the operation of the circuit diagram shown in FIG. 18. In the timing chart shown in FIG. 19, a period T11 corresponds to a period for describing write operation, a period T12 corresponds to a period for describing precharge operation of the wiring BL, a period T13 corresponds to a period for describing precharge operation of the wiring GBL, a period T14 corresponds to a period for describing charge sharing operation, a period T15 corresponds to a period for describing standby operation for reading, and a period T16 corresponds to a period for describing read operation.

In the period T11, the potential of the wiring WL connected to the gate of the transistor 11 included in the memory cell 10 to which a data signal is desired to be written is set to a high level. At this time, the control signal WE and the signal EN_data are set to a high level, and the data signal is written to the memory cell through the wiring GBL and the wiring BL.

In the period T12, in order to precharge the wiring BL, the precharge line PCL1 is set to a high level in a state where the control signal WE is at a high level. The wiring BL is precharged with a precharge potential. In the period T12, the wiring VHH and the wiring VLL through which power supply voltage is supplied to the sense amplifier 46 are both preferably set to VDD/2 in order to suppress power consumption due to flow-through current.

In the period T13, in order to precharge the wiring GBL, the precharge line PCL2 is set to a high level. The wiring GBL is precharged with a precharge potential. In the period T13, the potentials of the wiring VHH and the wiring VLL are both set to VDD, so that the wiring GBL with a large load can be precharged in a short time.

In the period T14, in order to cause charge sharing for balancing electric charge retained in the memory cell 10 and electric charge with which the wiring BL is precharged, the potential of the wiring WL is set to the high level. In the period T14, the potentials of the wiring VHH and the wiring VLL through which power supply voltage is supplied to the sense amplifier 46 are both preferably set to VDD/2 in order to suppress power consumption due to flow-through current.

In the period T15, the control signal RE and the selection signal MUX are set to a high level. Current flows through the transistor 52 in accordance with the potential of the wiring BL, and the potential of the wiring GBL varies in accordance with the current amount. The switch signal CSEL1 is set to a low level so that the variation in the potential of the wiring GBL is not affected by the sense amplifier 46. The wiring VHH or the wiring VLL is similar to that in the period T14.

In the period T16, the switch signal CSEL1 is set to a high level and the variation in the potential of the wiring GBL is amplified by the bit line pair connected to the sense amplifier 46; thus, the data signal written to the memory cell is read.

### [Structure Example of Functional Circuit]

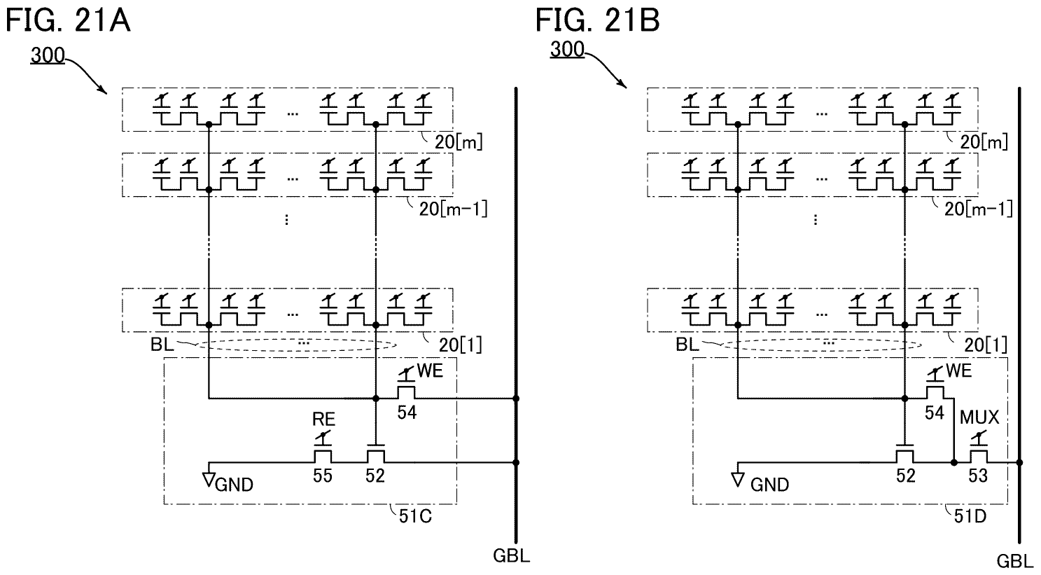

Next, specific structure examples of the functional circuit 51 functioning as the sense amplifier formed with OS transistors included in the functional layer 50 are described with reference to FIG. 20A, FIG. 20B, FIG. 21A, and FIG. 21B.

FIG. 20A shows a functional circuit 51A corresponding to the functional circuit 51_A or 51_B shown in FIG. 18. The functional circuit 51A shown in FIG. 20A includes transistors 52 to 55. Each of the transistors 52 to 55 can be an OS transistor and is shown as an n-channel transistor.

The transistor 52 is a transistor forming a source follower for amplifying the potential of the wiring GBL to a potential corresponding to that of the wiring BL in a period when the data signals are read from the memory cells 10. The transistor 53 is a transistor functioning as a switch where the selection signal MUX is input to a gate and electrical continuity between a source and a drain is controlled in accordance with the selection signal MUX. The transistor 54 is a transistor functioning as a switch where the control signal WE is input to a gate and electrical continuity between a source and a drain is controlled in accordance with the control signal WE. The transistor 55 is a transistor functioning as a switch where the control signal RE is input to a gate and electrical continuity between a source and a drain is controlled in accordance with the control signal RE. Note that the ground potential GND, which is a fixed potential, is supplied to the source side of the transistor 55, for example.

Note that modification examples shown in FIG. 20B, FIG. 21A, and FIG. 21B can be applied to the structure of the functional circuit 51A shown in FIG. 20A. A functional circuit 51B in FIG. 20B has a structure where one of the source and the drain of the transistor 54 is connected to not the wiring GBL but one of a source and a drain of the transistor 52. A functional circuit 51C in FIG. 21A corresponds to a structure where the function of the transistor 53 is performed by the driver circuit 21 and thus the transistor 53 is omitted. A functional circuit 51D in FIG. 21B corresponds to a structure where the transistor 55 is omitted.

In the semiconductor device of one embodiment of the present invention, OS transistors with extremely low off-state current are used as the transistors provided in the memory array 20. OS transistors can be provided in stacked layers over the substrate provided with the driver circuit 21 provided with Si transistors. Thus, OS transistors can be manufactured in a vertical direction by repeating the same manufacturing process, and manufacturing cost can be reduced. Furthermore, in one embodiment of the present invention, the memory density can be improved by arranging the transistors included in the memory cells 10 in not a plane direction but a vertical direction, whereby the memory device can be downsized.

In addition, one embodiment of the present invention is provided with the functional layer 50 including the functional circuits 51. In the functional circuit, the wiring BL is connected to the gate of the transistor 52; thus, the transistor 52 can function as an amplifier. With this structure, a slight difference in the potential of the wiring BL can be amplified at the time of reading to drive the sense amplifier 46 formed using Si transistors. The circuit such as the sense amplifier 46 formed using Si transistors can be downsized, so that the memory device can be downsized. Moreover, even when the capacitance of the capacitors 12 included in the memory cells 10 is reduced, operation is possible.

This embodiment can be combined with the other embodiments as appropriate.

### Embodiment 3

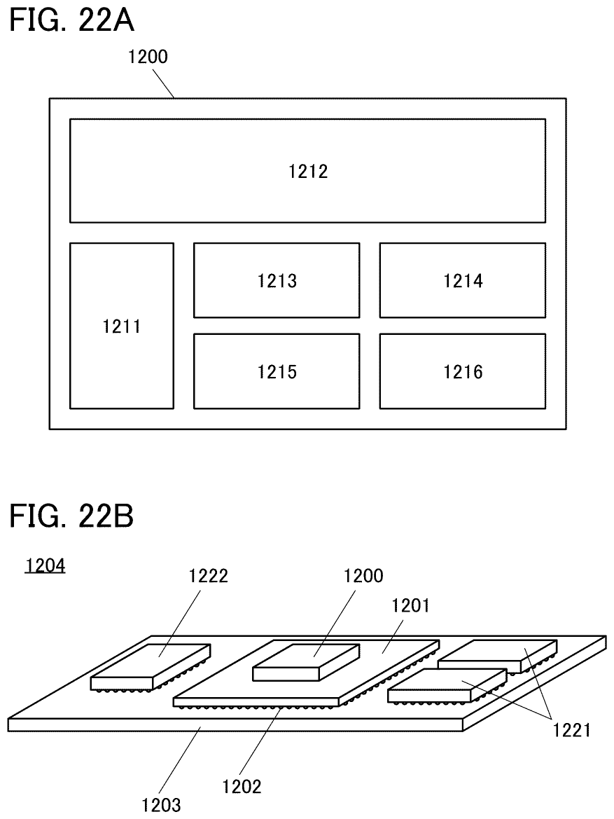

In this embodiment, an example of a chip on which the memory device of one embodiment of the present invention is mounted will be described with reference to FIG. 22. A plurality of circuits (systems) are mounted on a chip 1200 illustrated in FIG. 22A and FIG. 22B. The technique for integrating a plurality of circuits (systems) on one chip is referred to as system on chip (SoC) in some cases.

As illustrated in FIG. 22A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 22B, the chip 1200 is connected to a first surface of a package substrate 1201. A plurality of bumps 1202 are provided on the rear side of the first surface of the package substrate 1201, and the package substrate 1201 is connected to a motherboard 1203.

A memory device such as a DRAM 1221 or a flash memory 1222 may be provided over the motherboard 1203. For example, the DOSRAM described in the above embodiment can be used as the DRAM 1221. This can make the DRAM 1221 have low power consumption, operate at high speed, and have a large capacity.

The CPU 1211 preferably includes a plurality of CPU cores. The GPU 1212 preferably includes a plurality of GPU cores. The CPU 1211 and the GPU 1212 may each include a memory for storing data temporarily. Alternatively, a common memory for the CPU 1211 and the GPU 1212 may be provided in the chip 1200. The DOSRAM described above can be used as the memory. The GPU 1212 is suitable for parallel computation of a large number of data and thus can be used for image processing or product-sum operation. When an image processing circuit or a product-sum operation circuit including an OS transistor is provided in the GPU 1212, image processing or product-sum operation can be performed with low power consumption.

In addition, since the CPU 1211 and the GPU 1212 are provided in the same chip, a wiring between the CPU 1211 and the GPU 1212 can be shortened; accordingly, the data transfer from the CPU 1211 to the GPU 1212, the data transfer between the memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the analog arithmetic unit 1213 may include the above-described product-sum operation circuit.

The memory controller 1214 includes a circuit functioning as a controller of the DRAM 1221 and a circuit functioning as the interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit of a LAN (Local Area Network) or the like. Furthermore, the network circuit 1216 may include a circuit for network security.

The circuits (systems) described above can be formed in the chip 1200 in the same manufacturing process. Thus, even when the number of circuits needed for the chip 1200 is increased, there is no need to increase the number of steps in the manufacturing process; thus, the chip 1200 can be manufactured at a low cost.

The motherboard 1203 provided with the package substrate 1201 on which the chip 1200 including the GPU 1212 is mounted, the DRAM 1221, and the flash memory 1222 can be referred to as a GPU module 1204.

The GPU module 1204 includes the chip 1200 formed using the SoC technology, and thus can have a small size. Furthermore, the GPU module 1204 is excellent in image processing, and thus is suitably used in a portable electronic device such as a smartphone, a tablet terminal, a laptop PC, or a portable (mobile) game console. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 4

Described in this embodiment are examples of an electronic component including the memory device of one embodiment of the present invention.

### [Electronic Component]

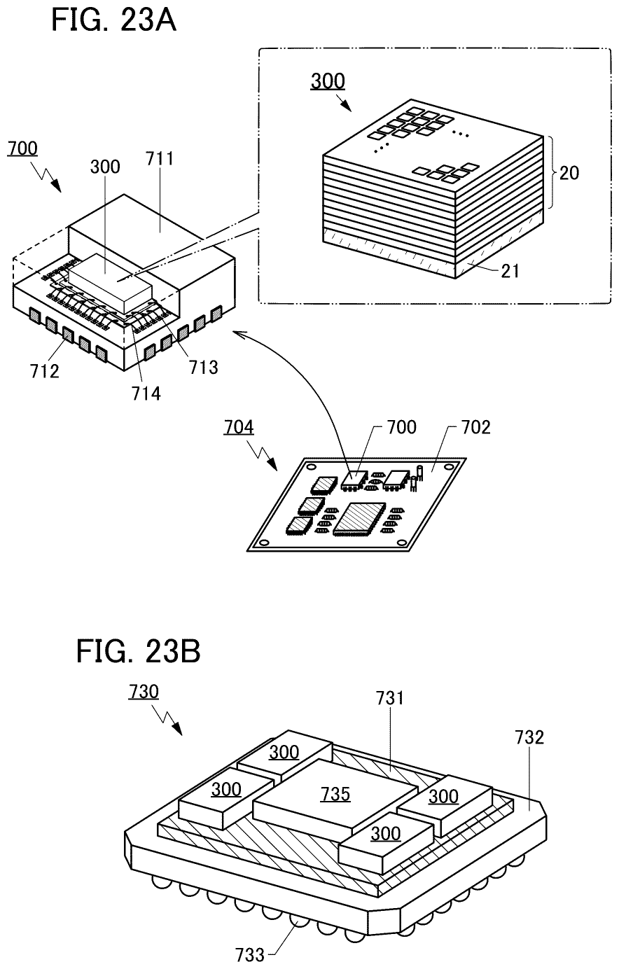

FIG. 23A is a perspective view of an electronic component 700 and a substrate (circuit board 704) on which the electronic component 700 is mounted. The electronic component 700 illustrated in FIG. 23A includes the memory device 300, which is the memory device of one embodiment of the present invention in a mold 711. FIG. 23A omits illustrations of some components to show the inside of the electronic component 700. The electronic component 700 includes a land 712 outside the mold 711. The land 712 is electrically connected to an electrode pad 713, and the electrode pad 713 is electrically connected to the memory device 300 via a wire 714. The electronic component 700 is mounted on a printed circuit board 702, for example. A plurality of such electronic components are combined and electrically connected to each other on the printed circuit board 702, which forms the circuit board 704.

As described in the above embodiments, the memory device 300 includes the driver circuit 21 and the memory array 20.

FIG. 23B is a perspective view of an electronic component 730. The electronic component 730 is an example of a SiP (System in package) or an MCM (Multi Chip Module). In the electronic component 730, an interposer 731 is provided over a package substrate 732 (printed circuit board) and a semiconductor device 735 and a plurality of memory devices 300 are provided over the interposer 731.

The electronic component 730 using the memory device 300 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at a lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth.

Thus, an interposer on which an HBM is mounted requires minute and densely formed wirings. For this reason, a silicon interposer is preferably used as the interposer on which an HBM is mounted.

In an SiP, an MCM, or the like using a silicon interposer, a decrease in reliability due to a difference in expansion coefficient between an integrated circuit and the interposer is unlikely to occur. Furthermore, a surface of a silicon interposer has high planarity; thus, a poor connection between the silicon interposer and an integrated circuit provided on the silicon interposer is unlikely to occur. It is particularly preferable to use a silicon interposer for a 2.5D package (2.5D mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably equal to each other. In the electronic component 730 described in this embodiment, the heights of the memory device 300 and the semiconductor device 735 are preferably equal to each other, for example.

An electrode 733 may be provided on the bottom portion of the package substrate 732 to mount the electronic component 730 on another substrate. FIG. 23B illustrates an example in which the electrode 733 is formed of a solder ball. Solder balls are provided in a matrix on the bottom portion of the package substrate 732, whereby a BGA (Ball Grid Array) can be achieved. Alternatively, the electrode 733 may be formed of a conductive pin. When conductive pins are provided in a matrix on the bottom portion of the package substrate 732, a PGA (Pin Grid Array) can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

This embodiment can be combined with the other embodiments as appropriate.

### Embodiment 5

In this embodiment, application examples of the memory device of one embodiment of the present invention will be described.

The memory device of one embodiment of the present invention can be used as memory devices of a variety of electronic devices (e.g., information terminals, computers, smartphones, e-book readers, digital still cameras, video cameras, video recording/reproducing devices, navigation systems, and game machines). The memory device of one embodiment of the present invention can also be used for image sensors, IoT (Internet of Things), healthcare devices, and the like. This enables electronic devices to achieve low power consumption. Here, the computers refer not only to tablet computers, notebook computers, and desktop computers, but also to large computers such as server systems.

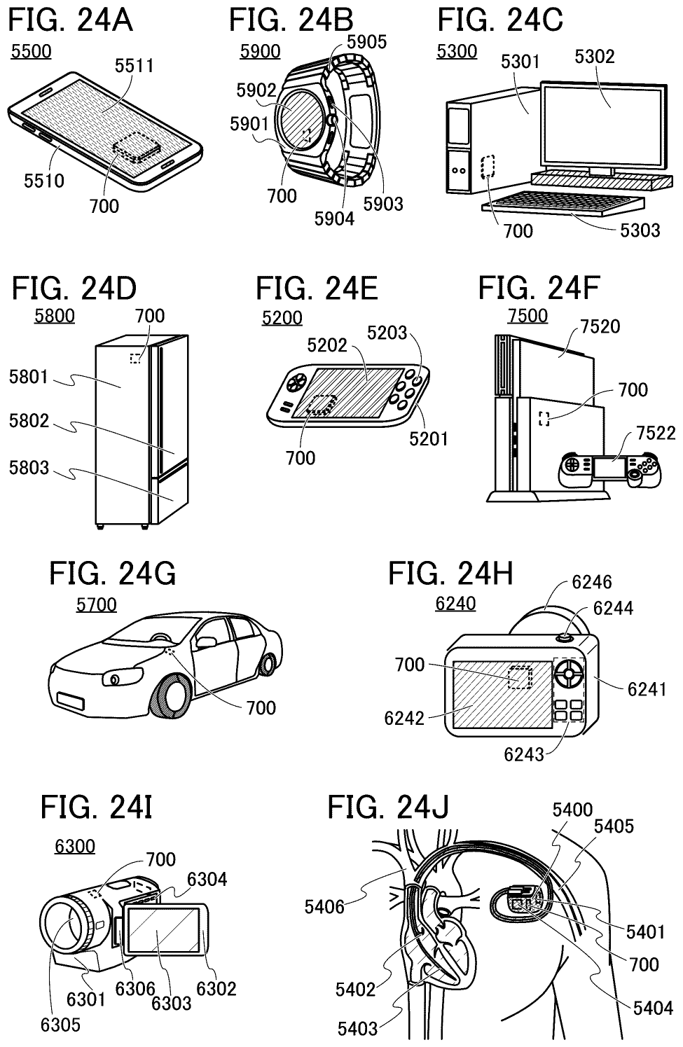

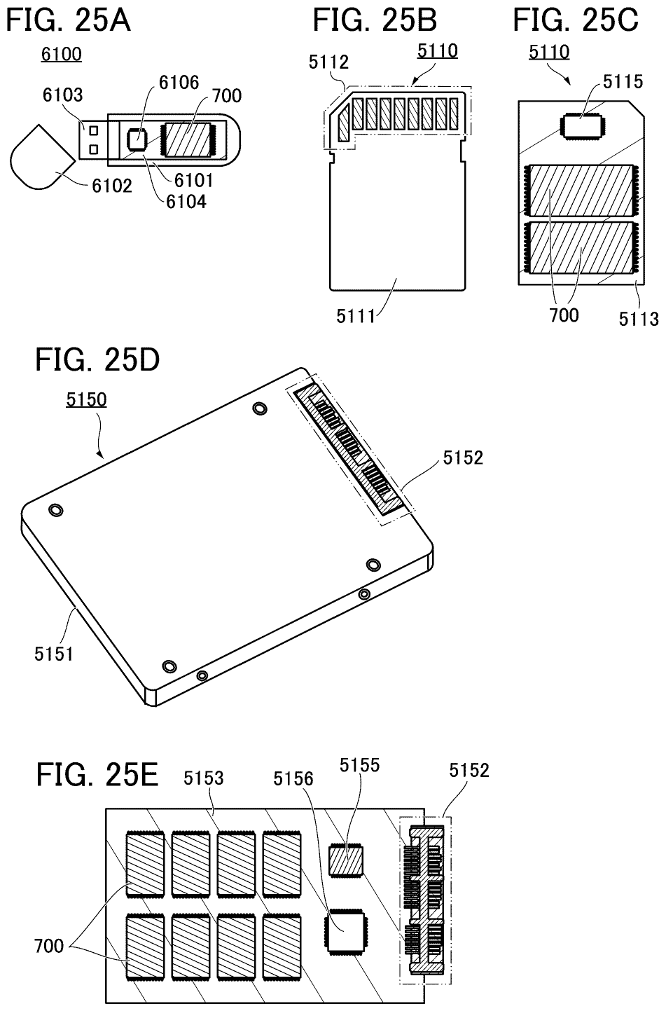

Examples of an electronic device including the memory device of one embodiment of the present invention will be described. FIG. 24A to FIG. 24J and FIG. 25A to FIG. 25E each show that the electronic component 700 or the electronic component 730, each of which includes the memory device described in the above embodiments, is included in an electronic device. [Mobile phone]

An information terminal 5500 illustrated in FIG. 24A is a mobile phone (a smartphone), which is a type of information terminal. The information terminal 5500 includes a housing 5510 and a display portion 5511. As input interfaces, a touch panel and a button are provided in the display portion 5511 and the housing 5510, respectively.

By using the memory device of one embodiment of the present invention, the information terminal 5500 can hold a temporary file generated at the time of executing an application (e.g., a web browser's cache).

### [Wearable Terminal]

FIG. 24B illustrates an information terminal 5900 as an example of a wearable terminal. The information terminal 5900 includes a housing 5901, a display portion 5902, an operation switch 5903, an operation switch 5904, a band 5905, and the like.

Like the aforementioned information terminal 5500, the wearable terminal can retain a temporary file generated at the time of executing an application, by using the memory device of one embodiment of the present invention.

### [Information Terminal]

FIG. 24C illustrates a desktop information terminal 5300. The desktop information terminal 5300 includes a main body 5301 of the information terminal, a display portion 5302, and a keyboard 5303.

Like the information terminal 5500, the desktop information terminal 5300 can retain a temporary file generated at the time of executing an application, by using the memory device of one embodiment of the present invention.

FIG. 24A to FIG. 24C illustrate the smartphone, the wearable terminal, and the desktop information terminal as electronic devices; other examples of information terminals include a PDA (Personal Digital Assistant), a laptop information terminal, and a workstation.

### [Household Appliance]

FIG. 24D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is compatible with IoT (Internet of Things).

The memory device of one embodiment of the present invention can be used in the electric refrigerator-freezer 5800. The electric refrigerator-freezer 5800 can transmit and receive data on food stored in the electric refrigerator-freezer 5800, food expiration dates, and the like to/from an information terminal or the like via the Internet, for example. In the electric refrigerator-freezer 5800, the memory device of one embodiment of the present invention can retain a temporary file generated at the time of transmitting the data.

An electric refrigerator-freezer is described as an example of a household appliance in FIG. 24D; other examples of household appliances include a vacuum, a microwave oven, an electric oven, a rice cooker, a water heater, an IH cooker, a water server, a heating-cooling combination appliance such as an air conditioner, a washing machine, a drying machine, and an audio visual appliance.

### [Game Machine]

FIG. 24E illustrates a portable game machine 5200 as an example of a game machine. The portable game machine 5200 includes a housing 5201, a display portion 5202, a button 5203, and the like.

FIG. 24F illustrates a stationary game machine 7500 as another example of a game machine. The stationary game machine 7500 can be especially referred to as a home-use stationary game machine. The stationary game machine 7500 includes a main body 7520 and a controller 7522. The controller 7522 can be connected to the main body 7520 with or without a wire. Although not illustrated in FIG. 24F, the controller 7522 can include a display portion that displays a game image, and an input interface besides a button, such as a touch panel, a stick, a rotating knob, and a sliding knob, for example. The shape of the controller 7522 is not limited to that in FIG. 24F and may be changed variously in accordance with the genres of games. For example, in a shooting game such as an FPS (First Person Shooter) game, a gun-shaped controller having a trigger button can be used. As another example, in a music game or the like, a controller having a shape of a music instrument, audio equipment, or the like can be used. Furthermore, the stationary game machine may include one or more of a camera, a depth sensor, and a microphone, so that the game player can play a game using a gesture or a voice instead of a controller.

Videos displayed on the game machine can be output with a display device such as a television device, a personal computer display, a game display, or a head-mounted display.

By using the memory device of one embodiment of the present invention in the portable game machine 5200 or the stationary game machine 7500, low power consumption can be achieved. The low power consumption reduces heat generation from a circuit; thus, the influence of heat generation on the circuit itself, the peripheral circuit, and the module can be reduced.

Moreover, with the use of the memory device of one embodiment of the present invention, the portable game machine 5200 or the stationary game machine 7500 can retain a temporary file or the like necessary for arithmetic operation that occurs during game play.

As examples of game machines, FIG. 24E and FIG. 24F illustrate a portable game machine and a home-use stationary game machine; other examples of the game machines include an arcade game machine installed in an entertainment facility (e.g., a game center and an amusement park) and a throwing machine for batting practice, installed in sports facilities.

### [Moving Vehicle]

The memory device of one embodiment of the present invention can be used in an automobile, which is a moving vehicle, and around the driver's seat in an automobile.

FIG. 24G illustrates an automobile 5700 as an example of a moving vehicle.

An instrument panel that provides various kinds of information by displaying a speedometer, a tachometer, a mileage, a fuel meter, a gearshift indicator, air-conditioning settings, and the like is provided around the driver's seat in the automobile 5700. In addition, a memory device showing the above information may be provided around the driver's seat.

In particular, the display device can compensate for the view obstructed by the pillar or the like, the blind areas for the driver's seat, and the like by displaying a video taken by an imaging device (not illustrated) provided for the automobile 5700, thereby providing a high level of safety. That is, display of an image from an imaging device provided on the outside of the automobile 5700 can fill in blind areas and increase safety.

The memory device of one embodiment of the present invention can temporarily retain information; thus, the memory device can be used to retain temporary information necessary in an automatic driving system for the automobile 5700 and a system or the like for navigation and risk prediction, for example. The display device may be configured to display temporary information regarding navigation, risk prediction, or the like. Moreover, the memory device may be configured to retain a video of a driving recorder provided in the automobile 5700. Although an automobile is described above as an example of a moving vehicle, moving vehicles are not limited to an automobile. Other examples of moving vehicles include a train, a monorail train, a ship, and a flying object (a helicopter, an unmanned aircraft (a drone), an airplane, and a rocket).

### [Camera]

The memory device of one embodiment of the present invention can be used in a camera.

FIG. 24H illustrates a digital camera 6240 as an example of an imaging device. The digital camera 6240 includes a housing 6241, a display portion 6242, operation switches 6243, a shutter button 6244, and the like. An attachable lens 6246 is attached to the digital camera 6240.

Note that, here, although the digital camera 6240 is configured such that the lens 6246 is detachable from the housing 6241 for replacement, the lens 6246 may be integrated with the housing 6241. Moreover, the digital camera 6240 may be configured to be additionally equipped with a stroboscope, a viewfinder, or the like.

By using the memory device of one embodiment of the present invention in the digital camera 6240, low power consumption can be achieved. The low power consumption reduces heat generation from a circuit; thus, the influence of heat generation on the circuit, the peripheral circuit, and the module can be reduced.

### [Video Camera]

The memory device of one embodiment of the present invention can be used in a video camera.

FIG. 24I illustrates a video camera 6300 as an example of an imaging device. The video camera 6300 includes a first housing 6301, a second housing 6302, a display portion 6303, an operation switch 6304, a lens 6305, a joint 6306, and the like. The operation switch 6304 and the lens 6305 are provided for the first housing 6301, and the display portion 6303 is provided for the second housing 6302. The first housing 6301 and the second housing 6302 are connected to each other with the joint 6306, and the angle between the first housing 6301 and the second housing 6302 can be changed with the joint 6306. Videos displayed on the display portion 6303 may be switched in accordance with the angle at the joint 6306 between the first housing 6301 and the second housing 6302.

When a video taken by the video camera 6300 is recorded, the video needs to be encoded based on a data recording format. With the use of the memory device of one embodiment of the present invention, the video camera 6300 can retain a temporary file generated in encoding.

### [ICD]

The memory device of one embodiment of the present invention can be used in an implantable cardioverter-defibrillator (ICD).

FIG. 24J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with the end of one of them placed in the right ventricle and the end of the other placed in the right atrium.

The ICD main unit 5400 functions as a pacemaker and paces the heart when the heart rate is not within a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor, the number of times the treatment with pacing is performed, and the time taken for the treatment, for example, can be stored in the electronic component 700.

The antenna 5404 can receive electric power, and the electric power is charged into the battery 5401. When the ICD main unit 5400 includes a plurality of batteries, the safety can be improved. Specifically, even if one of the batteries in the ICD main unit 5400 is dead, the other batteries can work properly; hence, the batteries also function as an auxiliary power source.

In addition to the antenna 5404 that can receive power, an antenna that can transmit a physiological signal may be provided. For example, a system that monitors the cardiac activity and is capable of monitoring physiological signals such as pulses, respiratory rate, heart rate, and body temperature with an external monitoring device may be constructed.

### [Expansion Device for Personal Computer]

The memory device of one embodiment of the present invention can be used in a computer such as a personal computer (PC) and an expansion device for an information terminal.

FIG. 25A illustrates, as an example of the expansion device, a portable expansion device 6100 that is externally attached to a PC and includes a chip capable of storing data. When the expansion device 6100 is connected to a PC with a universal serial bus (USB), for example, data can be stored in the chip. FIG. 25A illustrates the portable expansion device 6100; however, the expansion device of one embodiment of the present invention is not limited to this and may be a relatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the memory device of one embodiment of the present invention, for example. For example, the substrate 6104 is provided with the electronic component 700 and a controller chip 6106. The USB connector 6103 functions as an interface for connection to an external device.

### [SD Card]

The memory device of one embodiment of the present invention can be used in an SD card that can be attached to electronic devices such as an information terminal and a digital camera.

FIG. 25B is a schematic external view of an SD card, and FIG. 25C is a schematic view illustrating the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the substrate 5113 is provided with the electronic component 700 and a controller chip 5115. Note that the circuit structures of the electronic component 700 and the controller chip 5115 are not limited to those described above and can be changed as appropriate depending on circumstances. For example, a write circuit, a row driver, a read circuit, and the like that are provided in an electronic component may be incorporated into the controller chip 5115 instead of the electronic component 700.

When the electronic component 700 is also provided on the back side of the substrate 5113, the capacity of the SD card 5110 can be increased. In addition, a wireless chip with a radio communication function may be provided on the substrate 5113. This enables wireless communication between an external device and the SD card 5110, making it possible to write and read data to and from the electronic component 700.

### [SSD]

The memory device of one embodiment of the present invention can be used in a solid state drive (SSD) that can be attached to electronic devices such as information terminals.

FIG. 25D is a schematic external view of an SSD, and FIG. 25E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the substrate 5153 is provided with the electronic component 700, a memory chip 5155, and a controller chip 5156. When the electronic component 700 is also provided on the back side of the substrate 5153, the capacity of the SSD 5150 can be increased. A work memory is incorporated into the memory chip 5155. For example, a DRAM chip can be used as the memory chip 5155. A processor, an ECC

(Error Check and Correct) circuit, and the like are incorporated into the controller chip 5156. Note that the circuit structures of the electronic component 700, the memory chip 5155, and the controller chip 5115 are not limited to those described above and can be changed as appropriate depending on circumstances. For example, a memory functioning as a work memory may also be provided in the controller chip 5156.

### [Computer]

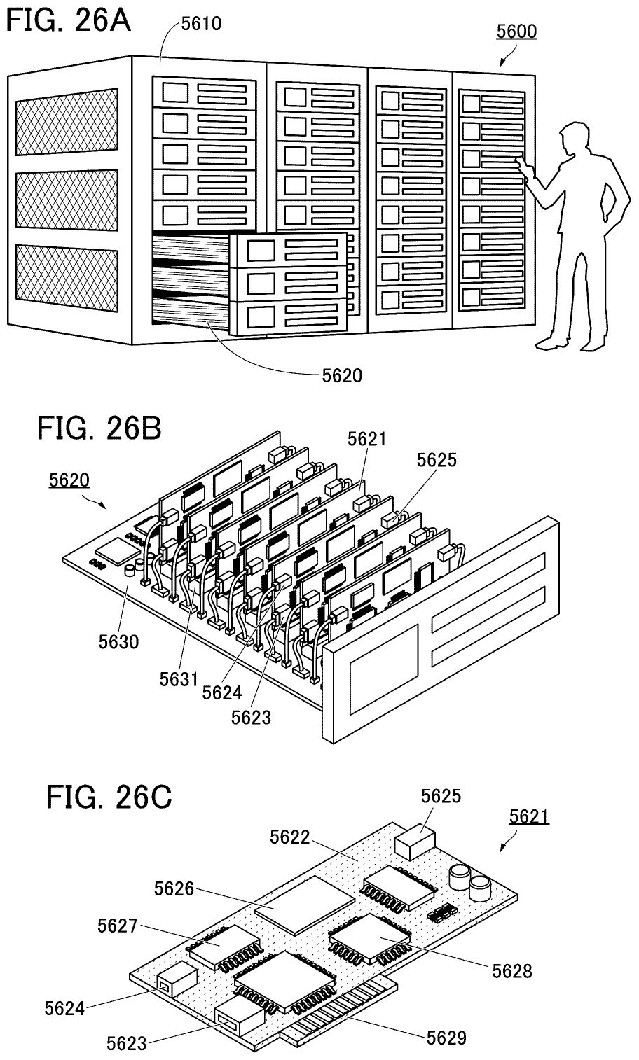

A computer 5600 illustrated in FIG. 26A is an example of a large computer. In the computer 5600, a plurality of rack mount computers 5620 are stored in a rack 5610.

The computer 5620 can have a structure in a perspective view illustrated in FIG. 26B, for example. In FIG. 26B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 26C also illustrates semiconductor devices other than the semiconductor device 5626, the semiconductor device 5627, and the semiconductor device 5628, the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, and the like to the PC card 5621. As another example, they can serve as an interface for outputting a signal calculated by the PC card 5621. Examples of the standard for each of the connection terminal 5623, the connection terminal 5624, and the connection terminal 5625 include universal serial bus (USB), serial ATA (SATA), and small computer system interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include a field programmable gate array (FPGA), a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention is used in a variety of electronic devices or the like described above, so that a reduction in size and a reduction in power consumption of the electronic device can be achieved. The memory device of one embodiment of the present invention has low power consumption, and thus can reduce heat generation from a circuit. Accordingly, the adverse effects of heat generation on the circuit, the peripheral circuit, and the module can be reduced. Furthermore, the use of the memory device of one embodiment of the present invention can achieve an electronic device that operates stably even in a high temperature environment. Thus, the reliability of the electronic device can be improved.

This embodiment can be combined with the other embodiments as appropriate.

### Embodiment 6

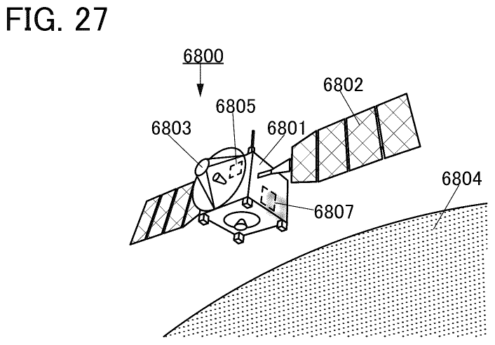

In this embodiment, a specific example of using the semiconductor device of one embodiment of the present invention in a device for space will be described with reference to FIG. 27.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space. Specifically, OS transistors can be used as transistors included in semiconductor devices provided in a space shuttle, an artificial satellite, or a space probe. Examples of radiation include X-rays and a neutron beam. Note that outer space refers to, for example, space at an altitude greater than or equal to 100 km, and outer space in this specification may also include one or more of thermosphere, mesosphere, and stratosphere.

FIG. 27 illustrates an artificial satellite 6800 as an example of a device for space. The artificial satellite 6800 includes a body 6801, a solar panel 6802, an antenna 6803, a secondary battery 6805, and a control device 6807. FIG. 27 illustrates a planet 6804 in outer space, for example.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics of the OS transistor due to radiation irradiation is smaller than a change in electrical characteristics of a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

Alternatively, for example, OS transistors can be used as transistors included in semiconductor devices provided in working robots in a nuclear power plant and a treatment plant or a disposal plant for radioactive wastes. In particular, OS transistors can be suitably used as transistors included in semiconductor devices provided in remote control robots that are controlled remotely in demolishment of a reactor facility, taking out of a nuclear fuel or a fuel debris, a field investigation on a space with a large amount of radioactive substance, and the like.

This embodiment can be combined with the other embodiments as appropriate.

### Example

In this example, results of cross-sectional SEM observation of a fabricated structure body including the oxide 230 illustrated in FIG. 8A to FIG. 8F are described.

In this example, a sample in which a base silicon oxide film, a hafnium oxide film (hereinafter referred to as an HfOx film), a silicon oxide film (hereinafter referred to as a SiOx film), an In—Ga—Zn oxide film (hereinafter referred to as an IGZO film), a stacked film of tantalum nitride and tungsten (hereinafter referred to as a TaNx\W film), a stacked film of silicon nitride and silicon oxide (hereinafter referred to as a SiNx\SiOx film), a tungsten film (hereinafter referred to as a W film), an SOC film, and an SOG film are stacked in this order over a silicon substrate was prepared. A resist mask was provided over the sample, and the etching treatments illustrated in FIG. 8A to FIG. 8F were performed.

Here, the base silicon oxide film corresponds to the insulator 216 illustrated in FIG. 8A to FIG. 8F. The HfOx film corresponds to the insulator 222. The SiOx film corresponds to the insulating film 224f and the insulator 224. The IGZO film corresponds to a stacked film of the oxide film 230af and the oxide film 230bf and a stacked film of the oxide 230a and the oxide 230b. The TaNx\W film corresponds to a stacked film of the conductive film 242_1f and the conductive film 242_2f and a stacked film of the conductor 242_1 and the conductor 242_2. The SiNx\SiOx film corresponds to the insulating film 271f and the insulator 271. The W film corresponds to the hard mask layer 276f and the hard mask layer 276. The SOC film corresponds to the organic coating film 277f and the organic coating film 277. The SOG film corresponds to the organic coating film 278f and the organic coating film 278.

First, the etching conditions necessary in the steps illustrated in FIG. 8A to FIG. 8F were selected. As in FIG. 8C, when the TaNx\W film is etched, the SOC film needs to function as a mask. When the SOC film is removed during the etching of the TaNx\W film, the W film provided under the SOC film is also removed.

In view of this, dry etching treatments were performed on the SOC film and the TaNx film and the W film that constitute the TaNx\W film, so that etching rates of the films were measured. Furthermore, the etching selectivity of the TaNx film with respect to the SOC film (hereinafter referred to as TaNx/SOC selectivity) and the etching selectivity of the W film with respect to the SOC film (hereinafter referred to as W/SOC selectivity) were calculated.

The above-described dry etching treatments were performed using a CCP etching apparatus. The etching was performed under the following conditions: a CHF₃ gas at 35 sccm, a Cl₂ gas at 15 sccm, and an Ar gas at 10 sccm were used as etching gases; the pressure was 0.6 Pa; the distance between electrodes was 80 mm; the electric power of the upper electrode was 1000 W; and the substrate temperature was 60° C. The etching rates were measured under the conditions where the electric power of the lower electrode was set to 10 W, 25 W, 50 W, and 100 W.

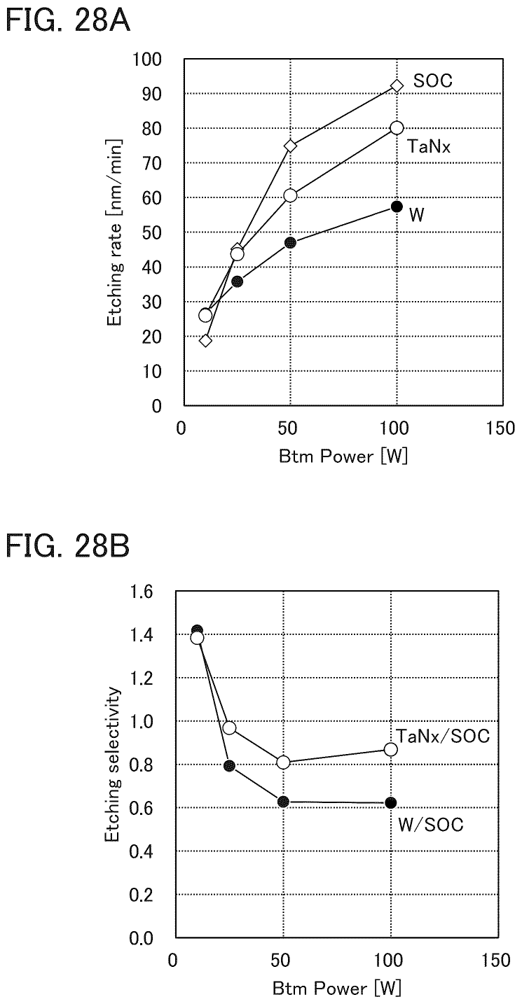

FIG. 28A shows the measurement results of the etching rate, and FIG. 28B shows the etching selectivity. Here, in FIG. 28A, the horizontal axis represents the electric power of the lower electrode (Btm Power [W]) and the vertical axis represents the etching rate [nm/min]. In FIG. 28B, the horizontal axis represents the electric power of the lower electrode (Btm Power [W]) and the vertical axis represents etching selectivity.

As shown in FIG. 28A, the etching rates of the TaNx film and the W film were lower than or equal to the etching rate of the SOC film under the condition where the electric power of the lower electrode was higher than or equal to 25 W. In FIG. 28B, the TaNx/SOC selectivity and the W/SOC selectivity were lower than or equal to 1.0. By contrast, under the condition where the electric power of the lower electrode was 10 W, the etching rates of the TaNx film and the W film were higher than the etching rate of the SOC film. The TaNx/SOC selectivity was 1.38 and the W/SOC selectivity was 1.42 under the condition where the electric power of the lower electrode was 10 W.

Thus, in the etching of the TaNx\W film, the electric power of the lower electrode is at least lower than 25 W, preferably lower than or equal to 10 W. When the TaNx\W film is etched under such a condition, the TaNx\W film can be removed without the SOC film disappearing.

Next, a method for fabricating Sample 1A and Sample 1B in each of which the above-described structure body was formed will be described.

First, a silicon substrate was prepared, and a base silicon oxide film was formed over the silicon substrate by a CVD method. Next, a 20-nm-thick HfOx film was formed over the base silicon oxide film by an ALD method.

Next, a SiOx film was formed over the HfOx film, and then a IGZO film was formed over the SiOx film. The SiOx film and the IGZO film were successively formed without exposure to the air. The SiOx film was formed to have a thickness of 20 nm by a sputtering method using a Si target.

Here, the IGZO film has a stacked-layer structure of a 10-nm-thick IGZO (132) film and a 15-nm-thick IGZO (111) film over the IGZO (132) film. The IGZO (132) film corresponds to the oxide film 230af and the oxide 230a illustrated in FIG. 8A to FIG. 8F. The IGZO (111) film corresponds to the oxide film 230bf and the oxide 230b illustrated in FIG. 8A to FIG. 8F. The IGZO film (132) was formed by a sputtering method using a target with an atomic ratio of In:Ga:Zn=1:3:2, and the IGZO film (111) was formed by a sputtering method using a target with an atomic ratio of In:Ga:Zn=1:1:1.2.

Next, a TaNx\W film was formed over the IGZO film by a sputtering method. The TaNx\W film is a stacked film of a 5-nm-thick TaNx film and a 15-nm-thick W film over the TaNx film. The TaNx film was formed using a tantalum target in an atmosphere including a nitrogen gas. The W film was formed using a tungsten target.

Subsequently, a SiNx\SiOx film was formed over the TaNx\W film by a sputtering method. The SiNx\SiOx film is a stacked film of a 5-nm-thick SiNx film and a 10-nm-thick SiOx film over the SiNx film. The SiNx film was formed using a silicon target in an atmosphere including a nitrogen gas. The SiOx film was formed using a silicon target in an atmosphere including an oxygen gas.

Next, a 15-nm-thick W film was formed over the SiNx\SiOx film by a sputtering method. Then, a SOC film was formed over the W film by a spin coating method. After that, an SOG film was formed over the SOC film by a spin coating method.

As in FIG. 8A, a negative type resist film was formed over the stacked films fabricated in the above-described manner. The resist film was irradiated with an electron beam to form an island-shaped resist mask. Note that in each of Sample 1A and Sample 1B, a region where the island-shaped resist mask had a width of 30 nm and a region where the island-shaped resist mask had a width of 60 nm were formed.

Next, dry etching treatment corresponding to FIG. 8B to FIG. 8F was performed using the island-shaped resist mask. The dry etching treatment was performed using a CCP etching apparatus. Table 1 shows the conditions of the dry etching treatment. Table 1 shows the distance between electrodes (Gap (mm)), the electric power of the upper electrode (Top Power (W)), the electric power of the lower electrode (Btm Power (W)), the pressure (Press (Pa)), the gas flow rate (Gas (sccm)), and the substrate temperature (Tsub (° C.)) in the dry etching of each film.

TABLE 1

| | | Top | Btm | | | |
|---|---|---|---|---|---|---|
| | Gap | Power | Power | Press | Gas | Tsub |
| | (mm) | (W) | (W) | (Pa) | (sccm) | (° C.) |
| SOG | 45 | 800 | 150 | 10.6 | CHF₃ = 67 | 40 |
| | | | | | O₂ = 13 | |
| SOC | 25 | 1000 | 200 | 6.6 | H₂ = 500 | 40 |
| | | | | | N₂ = 150 | |
| W_1 | 80 | 1000 | 25 | 0.6 | CF₄ = 30 | 60 |
| | | | | | Cl₂ = 20 | |
| SiNx\SiOx | 80 | 500 | 50 | 0.6 | CHF₃ = 67 | 60 |
| | | | | | O₂ = 13 | |
| TaNx\W | 80 | 1000 | 10 or 25 | 0.6 | CHF₃ = 35 | 60 |
| | | | | | Cl₂ = 15 | |
| | | | | | Ar = 10 | |
| IGZO | 120 | 1000 | 400 | 1.2 | CH₄ = 18 | 60 |
| | | | | | Ar = 42 | |
| SiOx | 80 | 500 | 50 | 0.6 | CHF₃ = 10 | 60 |
| | | | | | Ar = 70 | |
| W_2 | 120 | 500 | 25 | 1.3 | CF₄ = 22 | 60 |
| | | | | | Cl₂ = 11 | |
| | | | | | O₂ = 22 | |

First, as in FIG. 8B, the SOG film was etched, and then the SOC film was etched under the conditions shown in Table 1.

Next, as in FIG. 8C, the W film was etched (denoted as W_1 in Table 1), the SiNx\SiOx film was etched, and then the TaNx\W film was etched under the conditions shown in Table 1. Here, in the etching of the TaNx\W film of Sample 1A, the electric power of the lower electrode was 10 W, and in the etching of the TaNx\W film of Sample 1B, the electric power of the lower electrode was 25 W.

Next, as in FIG. 8D, the IGZO film was etched under the conditions shown in Table 1. Next, as in FIG. 8E, the SiOx film was etched under the conditions shown in Table 1.

Lastly, as in FIG. 8F, the W film remaining over the SiNx\SiOx film was removed by etching under the conditions shown in Table 1 (denoted as W_2 in Table 1).

Cross-sectional SEM images of Sample 1A and Sample 1B fabricated in the above-described manner were taken. The cross-sectional SEM images were taken at an acceleration voltage of 5 kV using “SU8030” produced by Hitachi High-Tech Corporation.

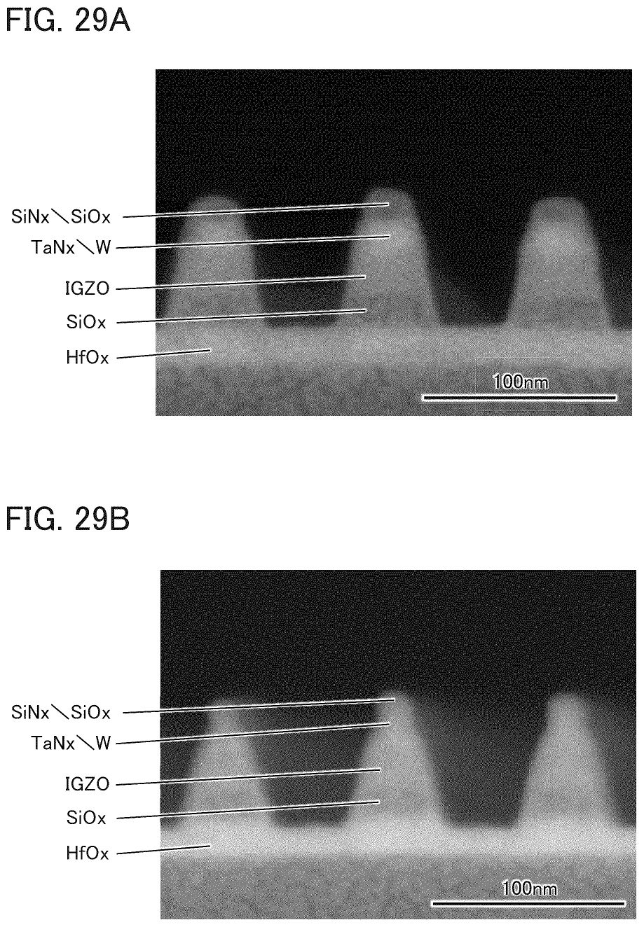

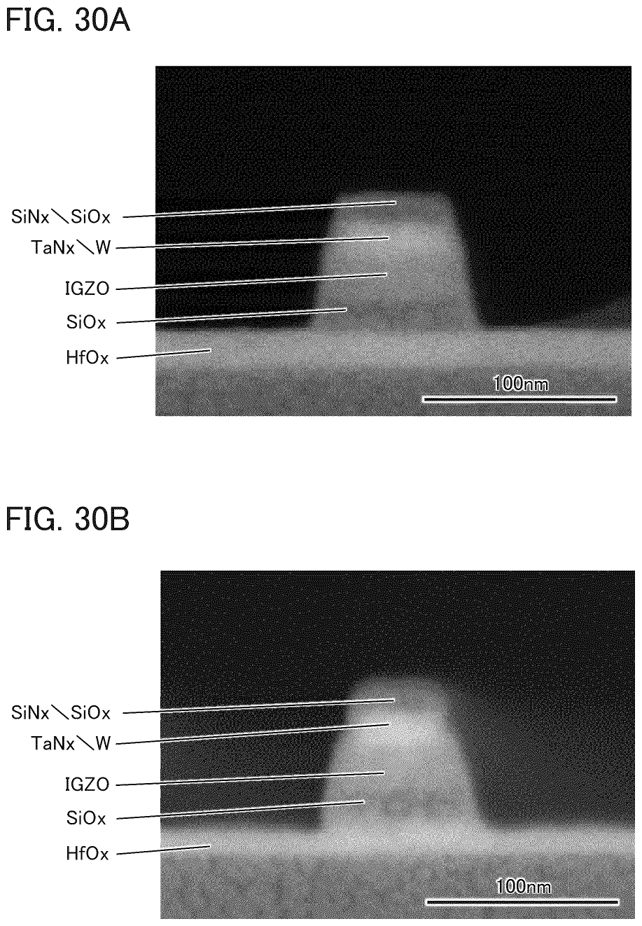

FIG. 29 and FIG. 30 show cross-sectional SEM images of Sample 1A and Sample 1B. Here, FIG. 29A is a cross-sectional SEM image of a region of Sample 1A where the structure body has a width of 30 nm, and FIG. 29B is a cross-sectional SEM image of a region of Sample 1B where the structure body has a width of 30 nm. FIG. 30A is a cross-sectional SEM image of a region of Sample 1A where the structure body has a width of 60 nm, and FIG. 30B is a cross-sectional SEM image of a region of Sample 1B where the structure body has a width of 60 nm.

As shown in FIG. 29A to FIG. 30B, in Sample 1B where the electric power of the lower electrode was 25 W, the recess of the TaNx\W film was more significant and the width of the structure body was narrower than those of Sample 1A where the electric power of the lower electrode was 10 W. That is, as illustrated in FIG. 28A and FIG. 28B, it is suggested that with a low electric power of the lower electrode, the SOC film remained during the etching of the TaNx\W film, and the W film was not etched. Thus, in one embodiment of the present invention, the TaNx\W film and the IGZO film can be collectively processed by the method illustrated in FIG. 8A to FIG. 8F, whereby the productivity of the semiconductor device can be improved.

In particular, the TaNx\W film largely receded in the region where the structure body of Sample 1B has the width of 30 nm, whereas the TaNx\W film was inhibited from receding in the region where the structure body of Sample 1A has the width of 30 nm. Thus, as described in the above embodiment, even in a semiconductor device having a minute structure, processing can be performed as designed under the conditions described in this example.

This example can be combined with any of the other embodiments as appropriate.

### REFERENCE NUMERALS

BL[1]: wiring, BL[j]: wiring, BL[n]: wiring, BL_A: wiring, BL_B: wiring, BL: wiring, BW: signal, CE: signal, CLK: signal, EN_data: signal, GBL_A: wiring, GBL_B: wiring, GBL: wiring, GND: ground potential, GW: signal, MUX: selection signal, PL[1]: wiring, PL[i]: wiring, PL[m]: wiring, PL: wiring, RDA: signal, RE: control signal, T11: period, T12: period, T13: period, T14: period, T15: period, T16: period, VHH: wiring, VLL: wiring, VPC: intermediate potential, WAKE: signal, WDA: signal, WE: control signal, WL[1]: wiring, WL[i]: wiring, WL[m]: wiring, WL: wiring, 10[1,1]: memory cell, 10[i,j]: memory cell, 10[m,n]: memory cell, 10_A: memory cell, 10_B: memory cell, 10: memory cell, 11_1: first layer, 11_2: second layer, 11_3: third layer, 11_m: layer, 11: transistor, 12: capacitor, 20[1]: memory array, 20[2]: memory array, 20[5]: memory array, 20[i]: memory array, 20[m]: memory array, 20: memory array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: functional layer, 51_A: functional circuit, 51_B: functional circuit, 51A: functional circuit, 51B: functional circuit, 51C: functional circuit, 51D: functional circuit, 51: functional circuit, 52_a: transistor, 52_b: transistor, 52: transistor, 53_a: transistor, 53_b: transistor, 53: transistor, 54_a: transistor, 54_b: transistor, 54: transistor, 55_a: transistor, 55_b: transistor, 55: transistor, 70[1]: repeating unit, 70: repeating unit, 71_A: precharge circuit, 71_B: precharge circuit, 72_A: switch circuit, 72_B: switch circuit, 73: write/read circuit, 81_1: transistor, 81_3: transistor, 81_4: transistor, 81_6: transistor, 82_1: transistor, 82_2: transistor, 82_3: transistor, 82_4: transistor, 83_A: switch, 83_B: switch, 83_C: switch, 83_D: switch, 101a: capacitor, 101b: capacitor, 153A: conductive film, 153: conductor, 154A: insulating film, 154: insulator, 160a: conductor, 160A: conductive film, 160b: conductor, 160B: conductive film, 160: conductor, 201a: transistor, 201b: transistor, 202a: transistor, 202b: transistor, 202c: transistor, 202d: transistor, 202e: transistor, 205a: conductor, 205b: conductor, 205: conductor, 207: conductor, 208: insulator, 209: conductor, 210: insulator, 212: insulator, 214: insulator, 216: insulator, 222: insulator, 224f: insulating film, 224: insulator, 230a: oxide, 230af: oxide film, 230b: oxide, 230ba: region, 230bb: region, 230bc: region, 230bf: oxide film, 230: oxide, 240_1: conductor, 240_2: conductor, 240_3: conductor, 240_m: conductor, 240a: conductor, 240am: conductor, 240b: conductor, 240bm: conductor, 240: conductor, 241a: insulator, 241A: insulating film, 241b: insulator, 241: insulator, 242_1: conductor, 242_1f: conductive film, 242_2: conductor, 242_2f: conductive film, 242a: conductor, 242b: conductor, 242: conductor, 250a: insulator, 250b: insulator, 250c: insulator, 250: insulator, 260a: conductor, 260b: conductor, 260: conductor, 261a: conductor, 261b: conductor, 261: conductor, 263: insulator, 271a: insulator, 271b: insulator, 271f: insulating film, 271: insulator, 275: insulator, 276f: hard mask layer, 276: hard mask layer, 277f: organic coating film, 277: organic coating film, 278f: organic coating film, 278: organic coating film, 279: resist mask, 280: insulator, 282: insulator, 283: insulator, 284: insulator, 285: insulator, 286: insulator, 287: insulator, 300A: memory device, 300: memory device, 310: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 700: electronic component, 702: printed circuit board, 704: circuit board, 711: mold, 712: land, 713: electrode pad, 714: wire, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: connection portion, 6800: artificial satellite, 6801: body, 6802: solar panel, 6803: antenna, 6804: planet, 6805: secondary battery, 6807: control device, 7500: stationary game machine, 7520: main body, 7522: controller

1. A semiconductor device comprising:
a first memory cell, a second memory cell over the first memory cell, a first conductor, and a second conductor over the first conductor,
wherein each of the first memory cell and the second memory cell comprises a transistor, a capacitor, and a first insulator over the transistor,
wherein the transistor comprises a metal oxide, a third conductor, a fourth conductor, and a second insulator over the metal oxide, a fifth conductor over the second insulator, a third insulator under the metal oxide, and a sixth conductor under the third insulator,
wherein the capacitor comprises a seventh conductor, a fourth insulator over the seventh conductor, and an eighth conductor over the fourth insulator,
wherein a part of the seventh conductor, a part of the fourth insulator, and a part of the eighth conductor are positioned over the first insulator,
wherein the fourth conductor and the seventh conductor are in contact with each other through an opening provided in the first insulator,
wherein the first conductor comprises a portion in contact with the third conductor included in the first memory cell,
wherein a top surface of the first conductor comprises a portion in contact with a bottom surface of the second conductor,
wherein the second conductor comprises a portion in contact with the third conductor included in the second memory cell,
wherein the sixth conductor included in the second memory cell and the eighth conductor included in the first memory cell comprise the same material,
wherein one side end portion of the third conductor is substantially aligned with one side end portion of the metal oxide in a cross-sectional view of the transistor, and
wherein one side end portion of the fourth conductor is substantially aligned with the other side end portion of the metal oxide in the cross-sectional view of the transistor.

2. The semiconductor device according to claim 1, wherein the first conductor is in contact with a part of a top surface and the one side end portion of the third conductor included in the first memory cell.

3. The semiconductor device according to claim 1, wherein a side end portion of the third insulator is substantially aligned with the one side end portion of the metal oxide.

4. The semiconductor device according to claim 1,
wherein each of the third conductor and the fourth conductor comprises a first layer and a second layer over the first layer,
wherein the first layer comprises a metal nitride, and
wherein the second layer has higher conductivity than the first layer.

5. The semiconductor device according to claim 4,
wherein the first layer comprises tantalum nitride, and
wherein the second layer comprises tungsten.

6. The semiconductor device according to claim 1, further comprising:
a fifth insulator in contact with a top surface of the third conductor; and
a sixth insulator in contact with a top surface of the fourth conductor,
wherein one side end portion of the sixth insulator is substantially aligned with the one side end portion of the fourth conductor.

7. The semiconductor device according to claim 1, further comprising;
a seventh insulator covering the third conductor, the fourth conductor, the metal oxide, and the third insulator,
wherein the seventh insulator comprises a first opening and a second opening,
wherein a region sandwiched between the third conductor and the fourth conductor and the first opening overlap each other,
wherein the opening in the first insulator and the second opening overlap each other,
wherein at least a part of the second insulator and at least a part of the fifth conductor are placed in the first opening, and
wherein at least a part of the seventh conductor, at least a part of the fourth insulator, and at least a part of the eighth conductor are placed in the second opening.

8. The semiconductor device according to claim 7, further comprising:
an eighth insulator over the first insulator,
wherein a part of the fourth insulator is in contact with a top surface of the eighth insulator, and
wherein the eighth insulator comprises an opening overlapping with the opening in the first insulator.

9. The semiconductor device according to claim 8, wherein a thickness of the eighth insulator is greater than or equal to 50 nm and less than or equal to 250 nm.

10. The semiconductor device according to claim 8, further comprising:
a ninth insulator in contact with a bottom surface of the sixth conductor,
wherein the ninth insulator included in the second memory cell is in contact with the top surface of the eighth insulator included in the first memory cell, and
wherein the ninth insulator included in the second memory cell and the fourth insulator included in the first memory cell comprise the same material.

11. The semiconductor device according to claim 7, wherein a side end portion of the seventh conductor is covered with the fourth insulator.

12. The semiconductor device according to claim 7, wherein the fourth insulator comprises zirconium oxide or aluminum oxide, or both of zirconium oxide and aluminum oxide.

13. The semiconductor device according to claim 7, wherein the sixth conductor and the fifth conductor overlap each other with the metal oxide therebetween.

14. The semiconductor device according to claim 7, further comprising:
a tenth insulator in contact with a side surface of the first conductor,
wherein at least a part of the third conductor is exposed from the tenth insulator and is in contact with the first conductor.

15. The semiconductor device according to claim 14, wherein the tenth insulator comprises aluminum oxide or silicon nitride, or both of aluminum oxide and silicon nitride.

16. The semiconductor device according to claim 7, wherein the first insulator comprises aluminum oxide.

17. A method for manufacturing a semiconductor device, the method comprising the steps of:
forming a first insulator, a second insulator, a metal oxide, a second conductor, and a third insulator in this order over a first conductor;
processing the second insulator, the metal oxide, the second conductor, and the third insulator to form an island-shaped second insulator, an island-shaped metal oxide, an island-shaped second conductor, and an island-shaped third insulator;
forming a fourth insulator to cover the first insulator, the island-shaped second insulator, the island-shaped metal oxide, the island-shaped second conductor, and the island-shaped third insulator;
forming a first opening penetrating the fourth insulator and the island-shaped third insulator to form a fifth insulator and a sixth insulator;
forming a second opening penetrating the fourth insulator and the island-shaped second conductor to form a third conductor and a fourth conductor;
forming a seventh insulator and a fifth conductor over the seventh insulator in the second opening;
forming an eighth insulator over the fourth insulator and the fifth conductor;
forming a third opening penetrating the eighth insulator, the fourth insulator, and the fifth insulator to reach the third conductor;
forming a sixth conductor in the third opening;
forming a ninth insulator and a seventh conductor to cover the sixth conductor; and
processing the ninth insulator and the seventh conductor to form a tenth insulator and an eleventh insulator, an eighth conductor over the tenth insulator, and a ninth conductor over the eleventh insulator,
wherein the eighth conductor and each of the tenth insulator and the sixth conductor overlap each other, and
wherein the ninth conductor and each of the metal oxide and the fifth conductor overlap each other.

18. The method for manufacturing a semiconductor device, according to claim 17, the method further comprising the steps of:
forming a fourth opening penetrate penetrating the eighth insulator, the fourth insulator, the sixth insulator, and the first insulator before the second opening is formed; and
forming a tenth conductor in the third opening,
wherein the tenth conductor is in contact with a part of the fourth conductor.

19. The method for manufacturing a semiconductor device, according to claim 17, the method further comprising the step of:
forming a metal film over the third insulator and forming an organic coating film over the metal film before the second insulator, the metal oxide, the second conductor, and the third insulator are processed,
wherein the second insulator, the metal oxide, the second conductor, and the third insulator are processed using a capacitively coupled plasma etching apparatus.

20. The method for manufacturing a semiconductor device, according to claim 19, wherein the island-shaped second conductor is formed before the organic coating film disappears during processing of the second conductor.

21. The method for manufacturing a semiconductor device, according to claim 19, wherein electric power of a lower electrode of a chamber of the capacitively coupled plasma etching apparatus is set to less than or equal to 10 W during processing of the second conductor.

22. The method for manufacturing a semiconductor device, according to claim 17, wherein the first conductor and each of the metal oxide and the fifth conductor overlap each other.

23. The method for manufacturing a semiconductor device, according to claim 17, wherein the first insulator comprises hafnium oxide.

24. The method for manufacturing a semiconductor device, according to claim 17, wherein the second insulator comprises silicon oxide.

25. The method for manufacturing a semiconductor device, according to claim 17, wherein the metal oxide comprises indium, gallium, and zinc.

26. The method for manufacturing a semiconductor device, according to claim 17, wherein the second conductor has a stacked-layer structure of a layer comprising tantalum nitride and a layer comprising tungsten over the layer comprising tantalum nitride.

27. The method for manufacturing a semiconductor device, according to claim 17, wherein a thickness of the eighth insulator is greater than or equal to 50 nm and less than or equal to 250 nm.

28. The method for manufacturing a semiconductor device, according to claim 17,
wherein the tenth insulator and the eleventh insulator comprise the same material, and
wherein the eighth conductor and the ninth conductor comprise the same material.
